(19) United States
(12) Patent Application Publication
(10) Pub. No.: US 2010/0295042 A1
(43) Pub. Date: Nov. 25, 2010

(54) FIELD-EFFECT TRANSISTOR, METHOD FOR MANUFACTURING FIELD-EFFECT TRANSISTOR, DISPLAY DEVICE USING FIELD-EFFECT TRANSISTOR, AND SEMICONDUCTOR DEVICE

(75) Inventors: Koki Yano, Chiba (JP); Kazuyoshi Inoue, Chiba (JP); Hirokazu Kawashima, Chiba (JP); Shigekazu Tomai, Chiba (JP)

Correspondence Address: MILLEN, WHITE, ZELANO & BRANIGAN, P.C., 2200 CLARENDON BLVD., SUITE 1400, ARLINGTON, VA, 22201, US

(73) Assignee: Idemitsu Kosan Co., Ltd., Tokyo (JP)

(21) Appl. No.: 12/864,078

(22) PCT Filed: Jan. 22, 2009
(86) PCT No.: PCT/JP2009/050916

§ 371 Date: Jul. 22, 2010

(30) Foreign Application Priority Data
Jan. 23, 2008 (JP) 2008-013085
Apr. 8, 2008 (JP) 2008-100088

(51) Int. Cl. H01L 29/786; H01L 21/336

(52) U.S. Cl. 257/43; 438/104; 257/E29.273; 257/E21.409; 438/151

(57) ABSTRACT

A field effect transistor which includes an oxide film as a semiconductor layer, the oxide film has a channel part, a source part and a drain part, and the channel part, the source part and the drain part have substantially the same composition except oxygen and an inert gas.

### TECHNICAL FIELD

The invention relates to a field effect transistor and the method for producing the same, and a display using thereof. The invention also relates to a semiconductor device using an oxide semiconductor, in particular to a field effect transistor.

### BACKGROUND ART

A field effect transistor is a device which is widely used as a unit electronic element of a semiconductor memory integrated circuit, a high-frequency signal amplification element, a liquid crystal driving element or the like. It is an electronic device which is most practically used in recent years.

In particular, with a remarkable progress in displays in recent years, a thin film transistor (TFT) is widely used as a switching device for liquid crystal displays (LCD), electroluminescence displays (EL) and field emission displays (FED).

As the material of the above-mentioned thin film transistor, a silicon semiconductor is most widely used. In general, a silicon single crystal is used in a high-frequency amplification element, an integrated circuit element or the like, which require high-speed operation. In a liquid crystal driving element or the like, amorphous silicon is used to meet the requirement for an increase in area.

However, a crystalline silicon-based thin film is required to be heated at a high temperature, for example, 800° C. or higher, for crystallization. Therefore, it is difficult to form a crystalline silicon-based thin film on a glass substrate or on a substrate formed of an organic substance. Therefore, a crystalline silicon-based thin film could be formed only on an expensive substrate having a high thermal resistance such as silicon wafer and quartz. In addition, there was a problem that a large amount of energy and a large number of steps were required in production.

Further, since a crystalline silicon-based thin film is normally restricted to a TFT with a top-gate configuration, a reduction in production cost such as a decrease in number of masks was difficult.

On the other hand, an amorphous silicon-based thin film (amorphous silicon) which can be formed into a film at a relatively low temperature has a lower switching speed as compared with a crystalline silicon semiconductor. Therefore, when used as a switching element for driving a display, a problem may arise that a high-speed animation cannot be displayed.

Today, as a switching element for driving a display, a device using a silicon-based semiconductor layer constitutes the mainstream due to various excellent performances including improved stability and processability of a silicon thin film and a high switching speed. Such a silicon-based thin film is generally produced by the chemical vapor deposition (CVD) method.

Conventional thin film transistors (TFT) have an inverted-staggered structure in which, on a substrate formed of glass or the like, a gate electrode, a gate-insulating layer, a semiconductor layer such as a hydrogenated amorphous silicon (a-Si:H) film, a source electrode and a drain electrode are sequentially stacked. This inverted-staggered type TFT is used, in a field of large-area devices including an image sensor, as a driving element for flat panel displays represented by active matrix-type liquid crystal displays. However, in these applications, with an improvement in function, a further increase in operation speed is demanded even for thin film transistors.

Under such circumstances, Patent Document 1 discloses an oxide semiconductor thin film using a metal oxide, which has more improved stability than silicon-based semiconductor thin films.

However, the transparent semiconductor thin film composed of the metal oxide as mentioned above, in particular, a transparent semiconductor thin film obtained by crystallizing zinc oxide at high temperatures, has defects such as a low field effect mobility (about 1 cm²/V·sec), a small on-off ratio, a large amount of current leakage, unclear pinch-off and tendency of becoming normally-on. For these defects, it was difficult to put it on the practical use. In addition to these defects, the transparent semiconductor thin film composed of a metal oxide has poor chemicals resistance, is hard to be subjected to wet etching, a high pressure is required to be applied at the time of film formation, a high-temperature treatment of 700° C. or more is required, and hence, the production process or the use environment was restricted.

Further, a transparent semiconductor film composed of a metal oxide has a low TFT performance such as field effect mobility. In order to improve the performance, the film thickness was required to be 50 nm or more in a top-gate configuration.

Patent Document 2 discloses producing an amorphous oxide semiconductor film composed of indium oxide, gallium oxide and zinc oxide and an amorphous oxide semiconductor film composed of indium oxide and zinc oxide and driving a thin film transistor using this amorphous oxide film.

However, depending on the composition and production conditions, the transistor properties (Id-Vg properties) of a TFT using an amorphous oxide semiconductor film may vary. Such variation in properties, when a TFT is used in a pixel circuit of a display or the like, causes operation of an organic EL, a liquid crystal or the like which is to be driven by a TFT to vary, and finally, causes image quality of a display to be deteriorated.

Patent Document 3 discloses a transistor in which the concentration of hydrogen or deuterium in a source part and a drain part is larger than the concentration of hydrogen or deuterium in a channel part. However, the above-mentioned transistor has problems that hydrogen ions scatter to cause a lowering in mobility, defects are formed in a gate insulating film to increase current leakage, traps are generated at an interface to increase the threshold voltage and properties are changed due to the move of injected hydrogen ions by the stress of driving. In addition, due to a high hydrogen concentration of a specific portion, the current value may vary, the off current may be increased, the amount of a threshold voltage shift may be large, and so on. Further, a facility for injecting hydrogen to the source part and the drain part is difficult to be increased in size, and the practical application thereof was difficult due to an increase in production cost.

Patent Document 4 discloses an electrode obtained by modifying a semiconductor layer, which is composed of zinc oxide to which impurities other than hydrogen is added, to be conductive. However, due to lowering in performance or the like caused by diffusion of impurities, the practical application thereof was difficult.

Patent Document 5 discloses a transistor using an indium-gallium-zinc oxide film. However this transistor had problems that the electric resistivity of the oxide film is adjusted only by oxygen partial pressure at the time of film formation, the energy width (E₀) on the non-localized level of the semiconductor layer is increased and the transistor properties are poor such as lowing in mobility.

Patent Documents 6 and 7 each disclose a method for producing a semiconductor device which comprises a step of changing the conductivity by varying the oxygen composition ratio of part of the metal oxide film contained in the insulating film. However, neither Patent Document 6 nor Patent Document 7 studies the semiconductor layer and the electrode. Further, since the composition of the semiconductor layer and the composition of the electrode largely differ, problems arise that the contact resistance generates or the production process is complicated.

As the structure of a thin film transistor (TFT), a staggered (top-gate) structure in which a gate insulating film and a gate terminal (gate electrode) are sequentially formed on a semiconductor film (channel layer), or an inverted staggered (bottom-gate) structure in which a gate insulating film and a semiconductor film (channel layer) are sequentially formed on a gate terminal (gate electrode) or the like are known.

When the semiconductor active layer is irradiated with visible rays, it shows conductivity and the properties as a switching element may be deteriorated, for example, current leakage may be generated to cause the transistor to malfunction. Therefore, a method is known in which a light-shielding layer for shielding visible rays is provided. For example, as a light-shielding layer, a metal thin film is used.

However, if a light-shielding layer formed of a thin metal film is provided, not only the production steps are increased but also a problem arises that, since a thin metal film has a floating potential, the light-shielding layer is required to be fixed to a ground level, which results in generation of parasitic capacitance.

Production of a transistor using a silicon thin film is defective in respect of safety or facility cost due to the use of a silane-based gas. Further, an amorphous silicon thin film has a mobility as low as about 0.5 cm²/Vs when used as a TFT. In addition, due to a small band gap, it absorbs visible rays to cause malfunction. A polycrystalline silicon thin film required a relatively high temperature for heating, and hence, it requires a high energy cost and it is difficult to form directly on a large-sized glass substrate.

Under such circumstances, in recent years, a transparent semiconductor thin film composed of a metal oxide as a film which has stability more improved as compared with a silicon-based semiconductor thin film. In general, the electron mobility of oxide crystals increases as the overlapping of the s orbit of metal ions increases. Crystals of an oxide of Zn, In and Sn which has a large atomic number have a large electron mobility of 0.1 to 200 cm²/Vs. Further, in oxides, since oxygen and metal ions are subjected to ionic bond, there is no particular direction of chemical bond. Therefore, if in an amorphous state in which the direction of bonding is not uniform, it becomes possible to have an electron mobility which is close to the mobility in the crystalline state. Therefore, unlike silicon-based semiconductors, metal oxides, even in an amorphous state, are capable of forming a transistor having a high field effect mobility. In view of these advantages, studies have been made on various semiconductor devices made of a crystalline or amorphous metal oxide containing Zn, In and Zn, as well as on circuits or the like using the same.

In recent years, active studies have been made on thin film transistors using organic semiconductor materials. Organic semiconductor materials have a possibility of capable of producing a transistor at a low temperature since it can produce a transistor without using a vacuum process, for example, by printing process. In addition, it has advantages that it can be formed on a flexible plastic substrate or the like.

However, organic semiconductor materials have a significantly low mobility, and tend to deteriorate with time. Therefore, they have not been widely used on the practical base.

On the other hand, since the above-mentioned oxide semiconductor can be produced at low temperatures, there is a high possibility that a transistor using various substrates can be obtained. However, if an oxide semiconductor is used in a channel layer, there is a problem that the contact resistance between the channel layer and the source or drain electrode is increased, and a good transistor cannot be obtained.

Further, there is a problem that the contact resistance changes when a thermal history is applied, whereby transistor properties are deteriorated. The effect of the contact resistance becomes significant especially when the channel length is decreased, whereby properties of a transistor are deteriorated. Therefore, minimization of a transistor cannot be attained easily. Further, drain concentration may tend to occur easily in the channel layer, good transistor may not be obtained.

Under such circumstances, a method is proposed in which source/drain regions are formed which have a resistance lower than the oxide semiconductor thin film layer, thereby to improve contact properties (Patent Document 8). Specifically, a method in which an intervening layer having a higher conductivity than that of a channel layer is provided by varying the amount of oxygen by changing the film-forming conditions is proposed (Patent Document 9), a method in which the surface of the oxide semiconductor thin film layer is reduced by plasma or the like (Patent Document 10 and Non-Patent Document 1), a method in which ion injection is used (Patent Documents 3 and 11) has been proposed.

However, in the method in which a highly conductive intervening layer is provided by changing the amount of oxygen during the film formation or the surface is reduced by a plasma treatment, the oxygen content may be largely deviated from the stoichiometrical ratio, and advantageous effects may be lost due to the thermal history during the process or use or the thickness of a layer to be treated may not be controlled.

In the method in which ion is injected, the production method or material selection may be restricted or stability may be lost by the move of light-weight injected elements such as hydrogen during use.

Patent Document 1: JP-A-2003-86808

Patent Document 2: US-A-2005/0199959

Patent Document 3: JP-A-2007-250983

Patent Document 4: JP-A-2003-050405

Patent Document 5: JP-A-2007-305658

Patent Document 6: JP-A-2007-311817

Patent Document 7: JP-A-2007-073701

Patent Document 8: JP-A-2003-298062

Patent Document 9: JP-A-2007-150158

Patent Document 10: JP-A-2007-220819

Patent Document 11: JP-A-2007-220818

Non-Patent Document 1: Appl. Phys. Lett. 90, 22104 (2007)

Non-Patent Document 2: Hyun-Joong Chung at al., ELECTROCHEMICAL AND SOLID-STATE LETTERS, 11(3), H51 (2008)

An object of the invention is to provide a field effect transistor which suffers a less variation and change with time of transistor properties and has high reliability.

When an oxide semiconductor is used in a field effect transistor, a problem arises that an effective S/D serial resistance between an oxide semiconductor and a source electrode or a drain electrode increases or drain concentration tends to occur easily in an oxide semiconductor.

An object of the invention is to provide a semiconductor device such as a field effect transistor. For example, the invention is aimed at solving the above-mentioned problems to provide an excellent transistor having an oxide semiconductor as the channel layer and the production method thereof.

### DISCLOSURE OF THE INVENTION

As a result of intensive studies, the inventors have found that, by allowing the compositions except an oxygen element or an inert gas of a source part or a drain part and a channel part to be substantially the same, a highly reliable field effect transistor suffering a less variation and change with time of transistor properties can be obtained. In addition, the inventors have found that, by controlling the oxygen concentration in a source part or a drain part to be lower than that in a channel part without adding any special element to a source part and a drain part, a highly reliable field effect transistor suffering a less variation and change with time of transistor properties can be obtained.

Further, the inventors have found that, by allowing an oxide semiconductor which is a non-degenerate semiconductor to be connected with a conductor with an oxide semiconductor which is a degenerate semiconductor therebetween, resistance or carrier injecting properties can be controlled. In addition, the inventors have also found that separate formation of a non-degenerate semiconductor and a degenerate semiconductor can be controlled by changing the composition or the composition ratio.

According to the invention, the following field effect transistor or the like are provided.

1. A field effect transistor which comprises an oxide film as a semiconductor layer,

the oxide film has a channel part, a source part and a drain part, and

the channel part, the source part and the drain part have substantially the same composition except oxygen and an inert gas.

2. The field effect transistor according to 1, wherein the oxygen concentration of each of the source part and the drain part is lower than the oxygen concentration of the channel part.
3. The field effect transistor according to 1 or 2, wherein the source part and the drain part are self-aligned with the gate electrode.
4. The field effect transistor according to any one of 1 to 3, wherein the oxide film comprises an oxide which comprises one or more elements selected from the group consisting of In, Zn, Ga and Sn.
5. The field effect transistor according to any one of 1 to 4, wherein the oxide film is an amorphous film of a composite oxide which comprises In and Zn.
6. The field effect transistor according to any one of 1 to 5, wherein the oxide film is an amorphous film of a composite oxide which comprises In, Zn and Ga or an amorphous film of a composite oxide which comprises In, Zn and Al.
7. The field effect transistor according to any one of 1 to 5, wherein the oxide film is an amorphous film of a composite oxide which comprises one or more elements selected from the group consisting of Zr, Hf, Ge, Si, Ti, Mn, W, Mo, V, Nb, B, Sc, Y and lanthanoid elements, In and Zn.
8. A display using the field effect transistor according to any one of 1 to 7.
9. A method for producing a field effect transistor comprising the steps of:

forming an oxide film and

lowering the resistance of part of the oxide film to form a source part and a drain part, wherein

the oxide film has a channel part and the source part and the drain part.

10. The method for producing a field effect transistor according to 9, wherein the resistance of part of the oxide film is lowered by irradiating light with a short wavelength in a low oxygen partial pressure environment.
11. The method for producing a field effect transistor according to 9, wherein the resistance of part of the oxide film is lowered by an inert gas plasma treatment.
12. A method for producing a field effect transistor comprising the steps of:

forming an oxide film and

increasing the resistance of part of the oxide film to form a channel part, wherein

the oxide film has the channel part and a source part and a drain part.

13. The method for producing a field effect transistor according to 12, wherein the resistance of part of the oxide film is increased by an oxygen plasma treatment or an ozone treatment.
14. A method for producing a field effect transistor comprising the steps of:

forming an oxide film,

coating the oxide film by an insulating film, and

forming a gate electrode on the insulating film and heating the gate electrode to increase the resistance of part of the oxide film, thereby to form a channel part, wherein

the oxide film has the channel part and a source part and a drain part.

15. A semiconductor device wherein an oxide semiconductor, which is a non-degenerate semiconductor, is connected to a conductor with an oxide semiconductor, which is a degenerate semiconductor, therebetween.
16. A field effect transistor comprising a channel part which comprises an oxide semiconductor and a source part and a drain part which each comprises an oxide semiconductor,

the channel part being a non-degenerate semiconductor and at least one of the source part and the drain part being a degenerate semiconductor, and

the channel part being connected to a source electrode and a drain electrode with the source part and the drain part therebetween.

17. The field effect transistor according to 16, wherein at least one of the source part and the drain part has a composition different from the composition of the channel part.
18. The field effect transistor according to 16 or 17, wherein each of the channel part, the source part and the drain part is an oxide which comprises In.
19. The field effect transistor according to any one of 16 to 18, wherein each of the channel part, the source part and the drain part is an oxide which comprises In, Zn and another element X, and

the amount ratio of the element X in all elements except oxygen is higher in the channel part than in the source part and the drain part.

20. The field effect transistor according to any one of 16 to 18, wherein each of the channel part, the source part and the drain part is an oxide which comprises In, Zn and the element X, and the composition of the channel part satisfies the atomic ratio in the following region 1, 2 or 3, and the composition of each of the source part and the drain part satisfies the atomic ratio in the following region 4:

In/(In+Zn+X)=0.20 to 0.55

Zn/(In+Zn+X)=0.00 to 0.80

X/(In+Zn+X)=0.00 to 0.80 Region 1

In/(In+Zn+X)0.55 to 0.90

Zn/(In+Zn+X)=0.00 to 0.35

X/(In +Zn+X)=0.10 to 0.45 Region 2

In/(In+Zn+X)=0.90 to 1.00

Zn/(In +Zn+X)=0.00 to 0.10

X/(In+Zn+X)=0.00 to 0.10 Region 3

In/(In+Zn+X)=0.55 to 0.90

Zn/(In+Zn+X)=0.00 to 0.45

X/(In+Zn+X)=0.00 to 0.10 Region 4

21. The field effect transistor according to 19 or 20, wherein the element X is an element selected from the group consisting of Ga, Al, B, Sc, Y and lanthanoids (La, Ce, Pr, Nd, Sm, Eu, Gd, Tb, Dy, Ho, Er, Tm, Yb, Lu), Zr, Hf, Ge, Si, Ti, Mn, W, Mo, V, Cu, Ni, Co, Fe, Cr and Nb.
22. The field effect transistor according to any one of 16 to 18, wherein the channel part is an oxide which comprises
In, Zn and the element X,

each of the source part and the drain part is an oxide which comprises In, Zn and an element Y, each of the element X and the element Y being an element selected from the group consisting of Ga, Al, B, Sc, Y, lanthanoids (La, Ce, Pr, Nd, Sm, Eu, Gd, Tb, Dy, Ho, Er, Tm, Yb, Lu), Zr, Hf, Ge, Si, Ti, Mn, W, Mo, V, Cu, Ni, Co, Fe, Cr, Nb and Sn, and

the element X and the element Y are different from each other.

23. The field effect transistor according to 16 or 17, wherein the channel part comprises a crystalline oxide which comprises In and one or more positive divalent elements.
24. The field effect transistor according to any one of 16 to 23, wherein an etching selection ratio of the source part and the drain part to the channel part is 5 or more.
25. A field effect transistor according to any one of 16 to 24, wherein at least one of the source electrode, the drain electrode and the gate electrode comprises a metal selected from the group consisting of Ti, Pt, Cr, W, Al, Ni, Cu, Mo, Ta, Au and Nb or an alloy which comprises one or more of these metals.
26. A method for producing a field effect transistor according to any one of 16 to 25, which comprises the steps of:

forming a film as a channel part,

forming a film as a source part and a drain part, and

after the above-mentioned two film-forming steps, conducting a heat treatment at a temperature higher than the film-forming temperature.

27. The method for producing a field effect transistor according to 26, wherein, between the step of forming a channel part and the step of forming a source part and a drain part, an object to be treated is not exposed to air.
28. The method for producing a field effect transistor according to 26 or 27, wherein the channel part, and the source part and drain part are formed by sputtering targets which differ in composition or composition ratio.

According to the invention, a highly reliable field effect transistor suffering a less variation and change with time of transistor properties can be provided.

According to the invention, a semiconductor device with improved properties such as a field effect transistor or a resistance random access memory can be provided. In particular, by providing a source part and a drain part having a composition or composition ratio differing from that of a channel part, an effective S/D serial resistance of a field effect transistor can be decreased, whereby an excellent transistor can be obtained. In addition, according to the invention, it is possible to stabilize an effective S/D serial resistance, whereby, in particular, reliability of transistor properties can be improved even though the channel length is short.

### BRIEF DESCRIPTION OF THE DRAWINGS

FIG. 1 is a schematic cross sectional view of a field effect transistor according to a first aspect of the invention;

FIG. 2 is a view showing steps of one embodiment of the method for producing a field effect transistor (bottom-gate type) according to the first aspect of the invention;

FIG. 3 is a view showing steps of another embodiment of the method for producing a field effect transistor (bottom-gate type) according to the first aspect of the invention;

FIG. 4 is a view showing steps of another embodiment of the method for producing a field effect transistor (bottom-gate type) according to the first aspect of the invention;

FIG. 5 is a view showing steps of another embodiment of the method for producing a field effect transistor (bottom-gate type) according to the first aspect of the invention;

FIG. 6 is a view showing steps of another embodiment of the method for producing a field effect transistor (bottom-gate type) according to the first aspect of the invention;

FIG. 7 is a view showing steps of another embodiment of the method for producing a field effect transistor (top-gate type) according to the first aspect of the invention;

FIG. 8 is a view showing steps of another embodiment of the method for producing a field effect transistor (bottom-gate type) according to the first aspect of the invention;

FIG. 9 is a schematic cross sectional view showing an example of using a field effect transistor according to the first aspect of the invention;

FIG. 10 is a schematic cross sectional view showing another example of using a field effect transistor according to the first aspect of the invention;

FIG. 11 is a schematic cross sectional view showing another embodiment of a field effect transistor according to first aspect of the invention;

FIG. 12 is a schematic cross sectional view showing one embodiment of a field effect transistor according to second aspect of the invention;

FIG. 13 is a schematic cross sectional view showing another embodiment of a field effect transistor according to second aspect of the invention;

FIG. 14 is a schematic cross sectional view showing another embodiment of a field effect transistor according to second aspect of the invention;

FIG. 15 is a schematic cross sectional view showing another embodiment of a field effect transistor according to second aspect of the invention;

FIG. 16 is a view showing a preferable composition range of an oxide semiconductor in the second aspect of the invention;

FIG. 17 is a view showing a relationship between the irradiation time (treatment time) and the resistance when an oxide film with a specific resistance of 10⁴ Ωcm is irradiated with an ultraviolet ray under a low oxygen partial pressure environment to reduce the resistance;

FIG. 18 is a view showing a relationship between the irradiation time and the resistance when an oxide film with a specific resistance of 10⁴ Ωcm is subjected to an argon plasma treatment to reduce the resistance;

FIG. 19 is a view showing a relationship between the treatment time and the resistance when an oxide film with a specific resistance of 10⁻³ Ωcm is subjected to an oxygen plasma treatment to increase the resistance;

FIG. 20 is a view showing a relationship between the treatment time and the resistance when an oxide film with a specific resistance of 10⁻³ Ωcm is subjected to an ozone treatment to increase the resistance;

FIG. 21 is a view showing a hysteresis in a transmission curve of a transistor prepared in Example 1;

FIG. 22 is a view showing a hysteresis in a transmission curve of a transistor prepared in Comparative Example 1; and

FIG. 23 is a view showing a relationship between the temperature and the mobility of an oxide semiconductor.

### BEST MODE FOR CARRYING OUT THE INVENTION

The first aspect of the invention will be explained below in detail

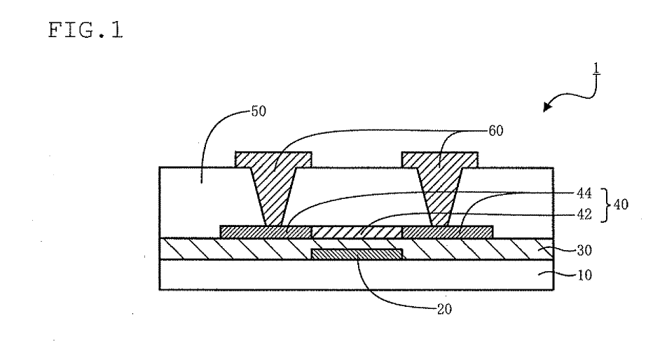

FIG. 1 is a schematic cross sectional view of a field effect transistor (hereinafter often referred to simply as a transistor) according to the first aspect of the invention.

In a field effect transistor 1, on a supporting substrate 10 provided with a gate electrode 20, a gate insulating film 30 is stacked so as to cover the supporting substrate 10 and the gate electrode 20. On the gate insulating film 30, a semiconductor layer 40 is further stacked. The semiconductor layer 40 has, according to a difference in the resistance thereof, a channel part 42 and source/drain parts 44. On the semiconductor layer 40, a protective layer 50 is stacked so as to cover the semiconductor layer 40. Wedge-shaped source/drain electrodes 60 which are in contact with the source/drain parts 44 are formed such that they penetrate the protective layer 50.

The above-mentioned field effect transistor 1 is a bottom gate type transistor. However, the field effect transistor according to the first aspect of the invention is not limited to a bottom gate type transistor. The field effect transistor according to the first aspect of the invention may be a bottom gate type transistor or a top gate type transistor, for example. The field effect transistor according to the first aspect of the invention is preferably a bottom gate type transistor in which the semiconductor layer has a protective film which will be mentioned later.

The field effect transistor according to the first aspect of the invention has an oxide film as the semiconductor layer. The oxide film has a channel part, a source part and a drain part, and the compositions except an oxygen element and an inert gas of the channel part, the source part and the drain part are substantially the same.

If the elements contained in oxide film differ from part to part, and the compositions except an oxygen element and an inert gas are not the same, a problem occurred that transistor properties significantly deteriorated. Specifically, the contained elements scatter to decrease the mobility, defects are generated in the gate insulating film to increase the current leakage, traps are generated at the interface to increase the threshold voltage and different element become movable ions and then move by a stress during driving, thereby to cause transistor properties to vary. As examples of the different elements which cause these problems, hydrogen, sodium, lithium or the like can be given, for example.

In the first aspect of the invention, the “compositions except an oxygen element and an inert gas of the channel part, the source part and the drain part are substantially the same” means that each of the channel part, the source part and the drain part is not doped with a specific element or is not controlled for doping concentration.

It is preferred that an element which is normally used for doping (elements which should be substantially the same as the composition except an oxygen element and an inert gas) be hydrogen (H), sodium (Na), lithium (Li), phosphor (P) and boron (B). Of these, it is preferred that the hydrogen (H) concentration is uniform (almost the same).

In order to allow the compositions to be substantially the same, not only doping with a specific element or control of the doping concentration is not conducted, but also removal of elements which have been mixed in during the process or uniformalization of ununiformity of elements by a heat treatment or the like may be conducted.

The oxide film as the semiconductor layer is preferably composed of an oxide containing one or more elements selected from the group consisting of In, Zn, Ga and Sn. More preferably, the oxide film is an amorphous film of a composite oxide containing In and Zn. Further preferably, the oxide film is an amorphous film of a composite oxide containing In, Zn and Ga, an amorphous film of a composite oxide containing In, Zn and Al, or an amorphous film of a composite oxide containing one or more elements selected from the group consisting of Zr, Hf, Ge, Si, Ti, Mn, W, Mo, V, Nb, B, Sc, Y and lanthanoid elements (for example, La, Ce, Pr, Nd, Sm, Eu, Gd, Tb, Dy, Ho, Er, Tm, Yb and Lu), In and Zn.

The amorphous nature of the oxide film can be confirmed by the fact that no specific peak is found in an X-ray diffraction analysis. In the first aspect of the invention, it is preferred that no clear peak be observed in the X-ray diffraction analysis of the amorphous oxide film and that the amorphous oxide film contain fine crystals of a size which can be observed by a transmission electron microscope (TEM). The average particle size of these fine crystals is preferably 10 nm or less, more preferably 5 nm or less, and particularly preferably 1 nm or less. Due to the fine crystals in the amorphous oxide film, the mobility can be improved. However, if the amorphous oxide film contains fine crystals with an average particle size exceeding 10 nm, if this amorphous oxide film is used in a transistor, variation in properties among transistors may be large.

By allowing the compositions except an oxygen element and an inert gas of the channel part, the source part and the drain part of the oxide film as the semiconductor layer to be substantially the same, move of elements between the source/drain parts and the channel part can be suppressed, whereby generation of a contact resistance and lowering of transistor properties associated with a change in semiconductor properties of the semiconductor layer can be suppressed.

In the first aspect of the invention, the inert gas means nitrogen (N), helium (He), neon (Ne), argon (Ar), krypton (Kr) and xenon (Xe). An inert gas may be mixed in the film as impurities during the formation of the oxide film such as sputtering and a plasma treatment. However, as long as the content of an inert gas in the oxide film is about 100 ppm or less, almost no adverse effects are exerted on semiconductor properties.

The content of an inert gas in the oxide film is preferably 100 ppm or less. If the content of an inert gas exceeds 100 ppm, transistor properties, the mobility of a TFT, for example, may be deteriorated. It is preferred that the channel part, the source part and the drain part of the oxide film have almost the same content of an inert gas, since the uniformity of the oxide film is increased.

The fact that the composition ratios excluding an oxygen element and an inert gas of the channel part, the source part and the drain part of the oxide film are substantially the same can be confirmed by an XRF (X-ray fluorescence) analysis, an ICP (inductively coupled plasma) analysis, a RBS (rutherford backscattering spectrometry) analysis, an AES (Auger Electron Spectroscopy) analysis, an EDX (energy dispersive X-ray spectrometry) analysis, a SIMS (secondary-ion mass spectrometry) analysis, a HFS (hydrogen forward scattering spectrometry) analysis or the like.

It is preferable to set the oxygen concentration of each of the source part and the drain part to a value lower than the oxygen concentration of the channel part. By setting the oxygen concentration of each of the source part and the drain part to a value lower than the oxygen concentration of the channel part, it can be expected that the number of carriers is increased by an oxygen deficiency, whereby the specific resistance is sufficiently lowered.

The oxygen concentration of the source part, the drain part and the channel part can be confirmed by an AES (Auger Electron Spectroscopy) analysis or an EDX (energy dispersive X-ray spectrometry) analysis.

It is particularly preferred that the channel part, the source part and the drain part of the oxide film have substantially the same hydrogen concentration. It is preferred that the hydrogen concentration of part with a high hydrogen concentration be less than 100 times of the hydrogen concentration of part with a low hydrogen concentration. It is particularly preferred that that the hydrogen concentration of part with a high hydrogen concentration is less than 10 times of the hydrogen concentration of part with a low hydrogen concentration.

The hydrogen concentration of the source part, the drain part and the channel part can be measured by a SIMS (secondary-ion mass spectrometry) analysis or a HFS (hydrogen forward scattering spectrometry) analysis.

It is preferred that the source/drain parts be self-aligned with the gate electrode.

If the source part and the drain part are not self-aligned with the gate electrode, the overlapping of the gate electrode and the source part and the drain part may vary due to an error in mask alignment. If a field effect transistor in which the source/drain parts are not self-aligned with the gate electrode is used in a display, the electric capacitance may vary as the overlapping of the gate electrode with the source/drain parts varies, thereby causing uneven display in a display.

The overlapping of the source part or the drain part with the gate electrode is normally 3.0 μm or less, preferably 2.0 μm or less, more preferably 1.0 μm or less, further preferably 0.5 μm or less, and particularly preferably 0.2 μm or less. If the overlapping is larger than 3.0 μm, the parasitic resistance of the transistor is increased to cause the circuit operation to be slow.

It is preferred that, in the field effect transistor according to the first aspect of the invention, the source part and the drain part be self-aligned with the gate electrode and that it have a coplanar structure.

A coplanar transistor means a transistor in which the gate electrode and the source/drain parts are on the same side of the semiconductor layer; the semiconductor layer and the source/drain electrodes are on the same plane; the semiconductor layer and the source/drain electrodes are not in contact with each other on a surface which is in parallel with the substrate.

The inverted type of a transistor is called a staggered transistor. In the case of a staggered transistor, since an electric field is applied in a curved manner, a trap may be generated at the semiconductor interface or in the gate insulating film, whereby the transistor properties such as mobility, threshold voltage and S value may be deteriorated. In addition, contact resistance may be generated at the interface between the semiconductor layer and the source/drain electrode, transistor properties such as mobility, threshold voltage, S value and hysteresis may be lowered.

Hereinbelow, an explanation is made on each member of the field effect transistor according to the first aspect of the invention.

There are no particular restrictions on the supporting substrate to be used, and a known substrate can be used as far as it does not impair the advantageous effects of the invention. Specifically, glass substrates such as those formed of non-alkaline glass, soda-lime glass and quartz glass, resin substrates such as those formed of polyethylene terephthalate (PET), polyamide and polycarbonate (PC), or a metal thin film (foil) substrate can be used. A single crystal substrate such as a Si substrate is difficult to be increased in size, and hence may cause the production cost to be increased.

The thickness of the supporting substrate is normally 0.01 to 10 mm.

There are no particular restrictions on the material for the gate electrode. Known materials can be used as far as they do not impair the advantageous effects of the invention. For example, transparent electrodes such as indium tin oxide (ITO), indium zinc oxide, ZnO and SnO₂, metal electrodes such as Al, Ag, Cr, Ni, Mo, Au, Ti and Ta, or metal electrodes of alloys containing these metals can be used.

If there is a need to heat the gate electrode during the production of a transistor, it is preferable to select a material which has a low reflectance and a high thermal absorption rate in order to facilitate the heating. Of the above-mentioned materials, as the material having such properties, metals or alloys can be given. More preferably, these materials are used after subjecting them to a surface treatment to decrease the reflectance thereof.

The gate electrode preferably has a stack structure of two or more layers. When the gate electrode has a stack structure of two or more layers, the contact resistance can be decreased and the interfacial strength can be improved.

The thickness of the gate electrode is normally 50 to 300 nm.

There are no particular restrictions on the material for forming the gate insulating film. Known insulating films can be arbitrary used as far as they do not impair the advantageous effects of the invention. As materials for the gate insulating film, for example, compounds such as SiO₂, SiNx (it may contain hydrogen), Al₂O₃, Ta₂O₆, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, AlN or the like may be used. Of these; SiO₂, SiNx, Al₂O₃, Y₂O₃, Hf₂O₃ and CaHfO₃ are preferably used, with SiO₂, SiNx, Y₂O₃, Hf₂O₃ and CaHfO₃ being more preferable.

The oxygen number of these compounds may not necessarily coincide with the stoichiometrical ratio (for example, they may be SiO₂ or SiOx).

The gate insulating film may be a stack structure in which two or more insulating films differing in materials are stacked. The gate insulating film may be crystalline, polycrystalline or amorphous. It is preferred that the gate insulating film be polycrystalline or amorphous in respect of productivity.

The gate insulating film may have a stack structure of two or more layers. In particular, if the gate insulating film is a stack of an insulating film composed of SiO₂ and a material having a higher dielectric constant than that of SiO₂ (SiNx, for example), and part nearer to the semiconductor layer is allowed to be an insulating film composed of SiO₂, both a good interface and a high dielectric constant can be attained.

The thickness of the gate insulating film is normally 5 to 500 nm.

It is preferred that the semiconductor layer having the channel part, the source part and the drain part be sealed with a protective film. By sealing the semiconductor layer with a protective film, deterioration of properties caused by a process environment and an environment during use can be prevented.

As the protective film, the same materials as those for the gate insulating film can be used.

It is preferred that the semiconductor layer have a light-shielding structure. If the semiconductor layer has a light-shielding structure (for example, light-shielding layer), carrier electrons may be excited when exposed to light, whereby an increase in off current can be prevented.

As the light-shielding layer, a thin film having a large absorption at a wavelength equal to or smaller than 500 nm can be used. The light-shielding layer may be positioned above or below the semiconductor layer. However, it is preferred that the light-shielding layer be provided both above and below the semiconductor layer. If the light-shielding layer is provided only either above or below, it is preferable to contrive the structure in order not to allow the semiconductor layer to be irradiated with light.

The light-shielding layer may be used also as the gate insulating film, a black matrix or the like.

It is preferred that the semiconductor layer have an electron carrier concentration of 10¹³ to 10¹⁸/cm³. If the electron carrier concentration exceeds 10¹⁸/cm³, a transistor may have a higher off current. If the electron carrier concentration is smaller than 10¹³/cm³, the mobility of a transistor may be lowered.

It is preferred that the specific resistance of the semiconductor layer be 10⁻¹ to 10¹⁰ Ωcm, more preferably 10¹ to 10⁹ Ωcm, and further preferably 10³ to 10⁸ Ωcm. If the specific resistance is smaller than 10⁻¹ Ωcm, a transistor may have a higher off current. If the specific resistance exceeds 10¹⁰ Ωcm, the mobility of a transistor may be lowered.

The resistivity of the source part and the drain part of the semiconductor layer is preferably 10⁻² to 10⁻¹⁰ times, more preferably 10⁻⁴ to 10⁻⁹ times, of the resistivity of the channel part.

The specific resistance of the source part and the drain part of the semiconductor layer is preferably 10⁻⁵ to 10⁻¹ Ωcm, more preferably 10⁻⁴ to 10⁻² Ωcm, and further preferably 10⁻⁴ to 10⁻³ Ωcm. If the specific resistance of the source part and the drain part exceeds 10⁻Ωcm, the contact resistance with the source/drain electrodes is increased, and as a result, when used in a TFT, transistor properties may be deteriorated such as an increase in S value. If the specific resistance of the source part and the drain part is less than 10⁻⁵ Ωcm, industrial application may be difficult due to restricted materials and production methods.

It is preferred that the semiconductor layer have a band gap of 2.0 to 6.0 eV, more preferably 2.8 to 4.8 eV. If the band gap of the semiconductor layer is smaller than 2.0 eV, visible rays may be absorbed to cause a field effect transistor to malfunction. If the band gap exceeds 6.0 eV, a field effect transistor may not function.

It is preferred that the semiconductor layer be a non-degenerate semiconductor which shows thermal activity. If the semiconductor layer is a degenerate semiconductor, the off current/gate leakage current may be increased due to an excessive amount of carriers, or the threshold value may become negative to cause a transistor to be normally-on.

The surface roughness (RMS) of the semiconductor layer is preferably 1 nm or less, more preferably 0.6 nm or less, with 0.3 nm or less being particularly preferable. If the surface roughness is larger than 1 nm, the mobility of a transistor may be lowered.

The energy width (E₀) on the non-localized level of the semiconductor layer is preferably 14 meV or less, more preferably 10 meV or less, further preferably 8 meV or less, and particularly preferably 6 meV or less. If the energy width (E₀) on the non-localized level of the semiconductor layer exceeds 14 meV, the mobility of the transistor may be lowered or the threshold value and the S value may be too large. A large energy width (E₀) on the non-localized level of the semiconductor layer appears to be caused by a poor short range order of the semiconductor layer.

The energy width (E₀) on the non-localized level of the semiconductor layer can be obtained from the relationship between the carrier concentration and the activation energy, measured by using the hall effect while changing the temperature in a range from 4 to 300K.

The thickness of the semiconductor layer is normally 0.5 to 500 nm, preferably 1 to 150 nm, more preferably 3 to 80 nm, and particularly preferably 10 to 60 nm. If the thickness of the semiconductor layer is less than 0.5 nm, it may be difficult to stack the semiconductor layer uniformly on the industrial scale. If the thickness of the semiconductor layer exceeds 500 nm, the time required for stacking the semiconductor layer may be prolonged, leading to a difficulty in commercial production. If the thickness of the semiconductor layer is 3 to 80 nm, the transistor properties such as the mobility and the on-off ratio are particularly preferable.

Although there are no particular restrictions on the material for forming the protective layer, an amorphous oxide or an amorphous nitride is preferable. For example, compounds such as SiO₂, SiNx, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, AlN or the like may be used. Of these, SiO₂, SiNx, Al₂O₃, Y₂O₃, Hf₂O₃ and CaHfO₃ are preferably used, SiO₂, SiNx, Y₂O₃, Hf₂O₃ and CaHfO₃ are more preferably used, with oxides such as SiO₂, Y₂O₃, Hf₂O₃ and CaHfO₃ being particularly preferable. The oxygen number of these oxides may not necessarily coincide with the stoichiometrical ratio (for example, they may be SiO₂ or SiOx). SiNx may contain a hydrogen element.

Such a protective layer may be a stack structure in which two or more different insulating films are stacked.

The protective layer may be crystalline, polycrystalline or amorphous. In respect of easiness in industrial production, the protective layer is preferably polycrystalline or amorphous, and particularly preferably amorphous. If it is an amorphous film, deterioration of the smoothness of an interface which leads to a lowering in mobility and an excessive increase in threshold voltage or S value can be prevented.

If the material for the protective layer is not an oxide, oxygen in the semiconductor moves toward the protective layer, and as a result, the off current may be increased or the threshold voltage may be negative to cause the transistor to be normally-on.

An organic insulating film such as poly(4-vinylphenol)(PVP) or parylene may be used in the protective layer of the semiconductor layer. Further, the protective layer of the semiconductor layer may have a stack structure in which an inorganic insulating film and an organic insulating film are stacked in two or more.

The thickness of the protective layer is normally 5 to 500 nm.

There are no particular restrictions on the material for the source electrode and the drain electrode. For example, transparent electrodes such as indium tin oxide (ITO), indium zinc oxide, ZnO and SnO₂, metal electrodes such as Al, Ag, Cr, Ni, Mo, Au, Ti and Ta, or metal electrodes composed of an alloy of these metals can be used.

The source electrode and the drain electrode are preferably a stack of two or more layers. By allowing the source electrode and the drain electrode to be a stack, it is possible to decrease the contact resistance or improve the interfacial strength. In order to decrease the interfacial resistance of the source electrode and the drain electrode, it is preferable to subject the interface between the semiconductor layer and the electrode to a plasma treatment, an ozone treatment or the like to control the resistance in advance.

The mobility of the field effect transistor is preferably 1 cm²/Vs or more, more preferably 3 cm²/Vs or more, and particularly preferably 8 cm²/Vs or more. If the mobility of the transistor is smaller than 1 cm²/Vs, the switching speed of the transistor may be too slow to be used in a large-area, high-precise display.

The off current of the field effect transistor is preferably 2 pA or less, more preferably 1 pA or less. When the off current of the transistor is larger than 2 pA, when used as a TFT of a display, the contrast may be poor and the uniformity of the screen may be deteriorated.

The threshold voltage of the field effect transistor is preferably 0 to 4 V, more preferably 0 to 3 V, and particularly preferably 0 to 2 V. If the threshold voltage of the transistor is smaller than 0, the transistor may become normally-on, and a voltage may be required to be applied when the transistor is in the off state, which may increase consumption power. If the threshold voltage is larger than 5 V, the driving voltage may be increased, resulting in an increase in consumption power.

The S value of the field effect transistor is preferably 0.8 V/dec or less, more preferably 0.3 V/dec or less, further preferably 0.25 V/dec or less, and particularly preferably 0.2 V/dec or less. If the S value is larger than 0.8 V/dec, the driving voltage may become large to increase the consumption power. In particular, when used in an organic EL display, which is driven by DC, it is particularly preferable to allow the S value to be 0.3 V/dec or less since the consumption power can be significantly decreased.

The shift amount in threshold voltage of the field effect transistor before and after the application of a direct voltage of 3 μA at 60° C. for 100 hours is preferably 1.0 V or less, more preferably 0.5 V or less. If the shift amount exceeds 1 V, the image quality may vary when a transistor with such a shift amount is used in an organic EL display.

It is preferred that hysteresis when the gate voltage is increased or decreased in a transmission curve or a variation in threshold voltage when measured in air (variation in surrounding atmosphere) be small.

The ratio (W/L) of the channel width W and the channel length L of the thin film transistor is normally 0.1 to 100, preferably 1 to 20 and particularly preferably 2 to 8. If the W/L is smaller than 0.1, the field effect mobility of the thin film transistor may be lowered or the pinch off may be unclear. If the W/L exceeds 100, the current leakage of the thin film transistor may be increased or the on-off ratio may be decreased.

The channel length L of the thin film transistor is normally 0.1 to 1000 μm, preferably 1 to 100 μm, more preferably 2 to 10 μm. If the channel length L of the thin film transistor is 0.1 μm or less, it is difficult to produce the transistor on the industrial scale, and the current leakage may be increased. A channel length L exceeding 1000 μm or more is not preferable since it makes the device too large in size.

The on-off ratio of the field effect transistor is preferably 10⁶ or more, more preferably 10⁷ or more, and particularly preferably 10⁸ or more.

The gate leakage current of the field effect transistor is preferably 1 pA or less. When the gate leakage current is larger than 1 pA, the contrast may be poor when used as a TFT of a display.

The field effect transistor of the first aspect of the invention can be produced by the method which comprises any of the following steps (1) to (3).

(1) An oxide film is formed, and the resistance of part of the oxide film is reduced to form a source part and a drain part.
(2) An oxide film is formed, and the resistance of part of the oxide film is increased to form a channel part.
(3) An oxide film is formed, the oxide film is coated with an insulating film, a gate electrode is formed on the insulating film, the gate electrode is heated, and the resistance of part of the oxide film is increased to form a channel part.

Hereinbelow, the method for producing a field effect transistor according to the first aspect of the invention will be explained in detail with reference to the drawing.

### Embodiment 1

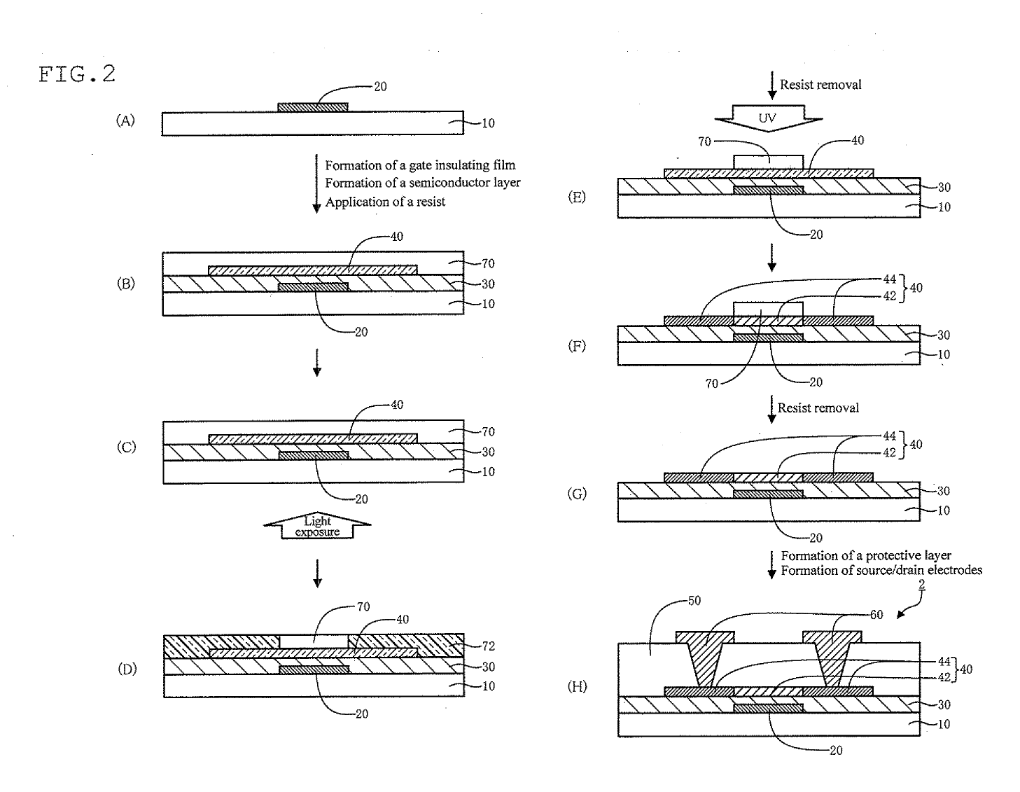

FIG. 2 is a view showing steps of one embodiment of the method for producing a field effect transistor (bottom-gate type) according to the first aspect of the invention.

In this embodiment, at first, a gate electrode 20 is formed on a supporting substrate 10 (FIG. 2(A)). A gate insulating film 30 is formed so as to cover the gate electrode 20. On the gate insulating film 30 thus formed, a semiconductor layer 40 and a resist 70 are stacked (FIG. 2(B)). For this stack, light exposure from the direction of the supporting substrate 10 and removal of the resist are conducted, whereby the resist 70 is patterned into a desired shape (FIG. 2(C), FIG. 2(D) and FIG. 2(E)). A resist 72 after the light exposure is removed; and the stack in which the resist 70 has been patterned is then irradiated with UV rays from the direction of the semiconductor layer to reduce the resistance of part of the semiconductor layer, whereby a channel part 42 and source/drain parts 44 are formed in the semiconductor layer 40 (FIG. 2(F)). After forming the channel part 42 and the source/drain parts 44, the resist 70 which has been patterned is removed (FIG. 2(G)), whereby a protective layer 50 and source/drain electrodes 60 are formed on the semiconductor layer 40 to obtain a field effect transistor 2 (FIG. 2(H)).

The semiconductor layer is preferably stacked by DC sputtering or AC sputtering. As compared with RF sputtering, DC sputtering and AC sputtering are capable of reducing damage exerted on the semiconductor layer during stacking. A field effect transistor in which the semiconductor layer is stacked by DC sputtering or AC sputtering is expected to have a reduced shift in threshold voltage, an improved mobility, a reduced threshold voltage, a decreased S value or the like.

A thermal history of preferably 70 to 350° C. is applied to the stacked semiconductor layer. The thermal history is more preferably 80 to 260° C., further preferably 90 to 180° C., with 100 to 150° C. being particularly preferable. When the thermal history to be applied to the semiconductor layer is less than 70° C., the resulting transistor may have a low thermal stability and thermal resistance, a lowered mobility, an increased S value and an increased threshold voltage. On the other hand, if the thermal history applied to the semiconductor layer exceeds 350° C., not only a supporting substrate having a lower thermal resistance may be unusable, but also the production cost may be increased due to the need of expensive heat treatment equipment.

Of the above-mentioned temperature range, if a thermal history of 180° C. or less is applied, a supporting substrate made of a resin such as PEN (polyethylene terephthalate) can be used.

The thermal history is preferably conducted in an inert gas atmosphere with an oxygen partial pressure of 10⁻³ Pa or less or conducted after forming a protective film on the semiconductor layer. By applying a thermal history to the semiconductor layer under these conditions, reproducibility of advantageous effects can be enhanced.

There are no particular restrictions on the method for forming other layers than the semiconductor layer, e.g. the gate insulating film, known film forming methods such as CVD and sputtering can be used.

In this embodiment, parts of the semiconductor layer (oxide film) of which the resistance is lowered are allowed to be source/drain parts, and part of the semiconductor layer of which the resistance is not lowered is allowed to be a channel part.

As the method for lowering the resistance of part of the semiconductor layer (hereinafter often referred to as the “low-resistance treatment”), irradiation of short-wavelength light under a low oxygen partial pressure, irradiation of short-wavelength light, an inert gas plasma treatment, a heat treatment in a foaming gas and a hydrogen plasma treatment can be used. Of these, irradiation of a short-wavelength light under a low oxygen partial pressure, an inert plasma treatment or a heat treatment in a foaming gas is preferable. An inert gas plasma treatment or a heat treatment in a foaming gas is more preferable. As mentioned above, a low-resistance treatment can be conducted by using a hydrogen plasma treatment. However, when a hydrogen plasma treatment is used, hydrogen is mixed in the source part or the drain part, properties of a transistor may be deteriorated with time, and reliability of a transistor may be lowered.

When irradiation of short-wavelength light in a low partial oxygen pressure environment is conducted in the low-resistance treatment, the oxygen partial pressure is normally 10³ Pa or less, preferably 10 Pa or less, more preferably 10⁻¹ Pa or less, further preferably 10⁻² Pa or less, and particularly preferably 10⁻³ Pa or less. If the oxygen partial pressure exceeds 10³ Pa, the low-resistance treatment may take an excessively long period of time and a sufficient low-resistance treatment may not be conducted.

Irradiation of short-wavelength light can be conducted by means of an ultra high-pressure mercury lamp, a low-pressure mercury lamp and an X ray, for example.

The wavelength of the short-wavelength light to be irradiated is normally 100 to 400 nm, preferably 150 to 350 nm, and more preferably 200 to 320 nm. If the wavelength of the irradiated light is less than 100 nm, each member of a transistor may be deteriorated. If the wavelength of the irradiated light exceeds 400 nm, effects of the low-resistance treatment may be small. As examples of the short-wavelength light having the above-mentioned wavelength, ultraviolet rays mentioned in Embodiment 1 can be given.

When an inert gas plasma is used in the low-resistance treatment, as the inert gas to be used, nitrogen (N), helium (He), neon (Ne), argon (Ar), krypton (Kr) and xenon (Xe) can be used. In respect of easiness in use on the industrial basis, argon is preferable.

When a heat treatment in a foaming gas is used in the low-resistance treatment, as the foaming gas, a mixed gas of hydrogen and nitrogen is preferable. As the composition of the foaming gas, hydrogen (H₂):nitrogen (N₂) is preferably 1:100 to 1:1, with 1:20 to 1:5 being particularly preferable. Although there are no particular restrictions on the heat treatment method, it is preferable to heat by RTA (rapid thermal annealing) for 0.1 to 5 minutes. If the heating time is in the above-mentioned range, the resistance can be lowered uniformly with good reproducibility.

### Embodiment 2

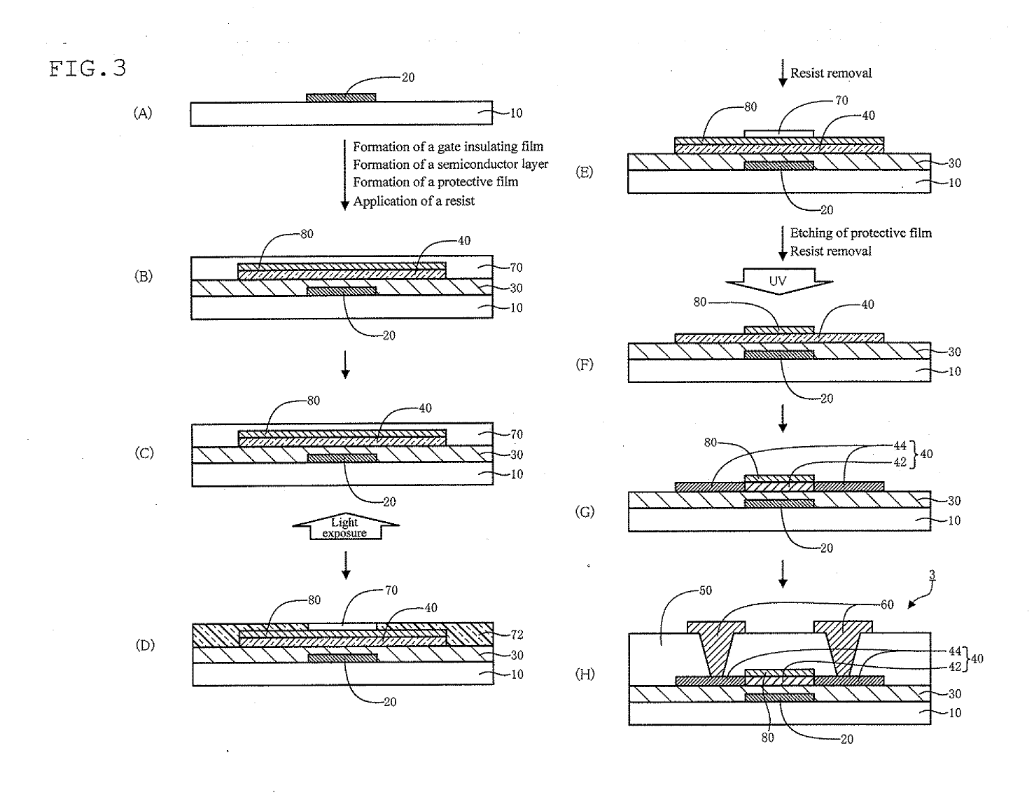

FIG. 3 is a view showing steps of another embodiment of the method for producing a field effect transistor (bottom-gate type) according to the first aspect of the invention.

In this embodiment, at first, the gate electrode 20 is formed on the supporting substrate 10 (FIG. 3(A)). The gate insulating film 30 is formed so as to cover the gate electrode 20. On the gate insulating film 30 thus formed, the semiconductor layer 40, a protective film 80 and the resist 70 are stacked (FIG. 3(B)). For this stack, light exposure from the direction of the supporting substrate 10 and removal of the resist are conducted, whereby the resist 70 is patterned into a desired shape (FIG. 3(C), FIG. 3(D) and FIG. 3(E)). The protective film of the stack in which the resist 70 has been patterned is etched to pattern the protective film into a desired shape. Then, the patterned resist 70 is removed (FIG. 3(F)). The stack having the patterned protective film 80 on the semiconductor layer 40 is irradiated with UV rays from the direction of the semiconductor layer to decrease the resistance of part of the semiconductor layer, whereby the channel part 42 and source/drain parts 44 are formed in the semiconductor layer 40 (FIG. 3(G)). The protective layer 50 and source/drain electrodes 60 are formed on the semiconductor layer 40 to obtain a field effect transistor 3 (FIG. 3(H)).

When the channel part 42 and the source/drain parts 44 are formed in the semiconductor layer 40 (FIG. 3(G)), a low-resistance treatment other than the UV ray irradiation such as an inert gas plasma treatment, a heat treatment in a foaming gas and a hydrogen plasma treatment may be used.

This embodiment is the same as that of Embodiment 1 except for the provision of the protective film on the Semiconductor layer. As mentioned above, by sealing the semiconductor layer with a protective film; deterioration of properties caused by a process environment and an environment during use can be prevented.

### Embodiment 3

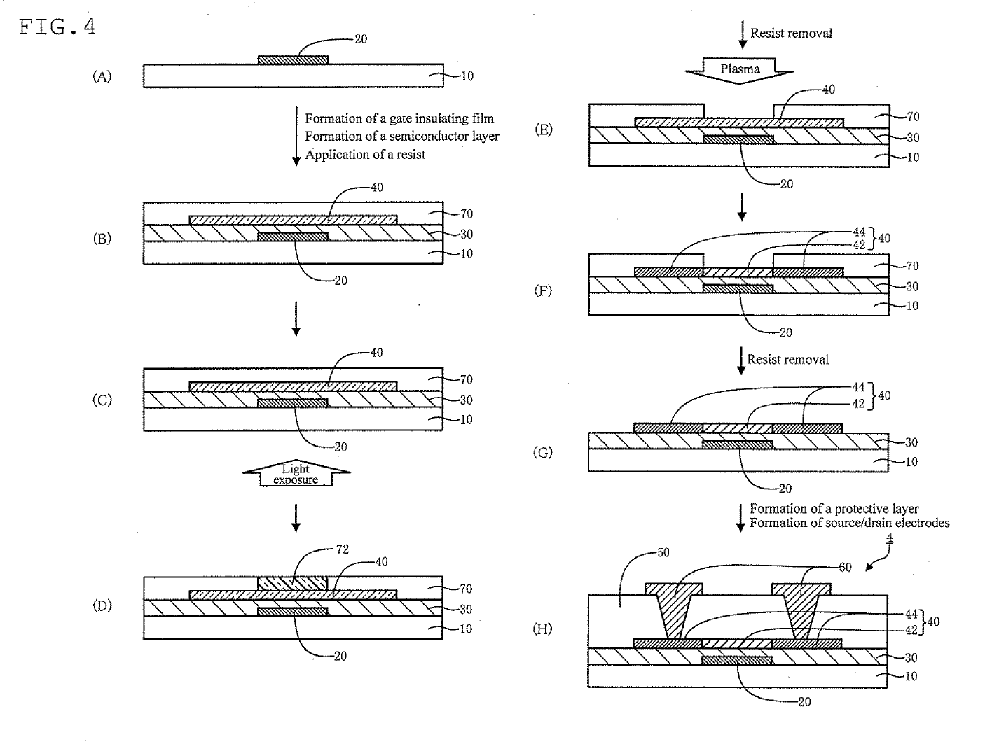

FIG. 4 is a view showing steps of another embodiment of the method for producing a field effect transistor (bottom-gate type) according to the first aspect of the invention.

In this embodiment, at first, the gate electrode 20 is formed on the supporting substrate 10 (FIG. 4(A)). The gate insulating film 30 is formed so as to cover the gate electrode 20. On the gate insulating film 30 thus formed, the semiconductor layer 40 and the resist 70 are stacked (FIG. 4(B)). For this stack, light exposure from the direction of the supporting substrate 10 and removal of the resist are conducted, whereby the resist 70 is patterned into a desired shape (FIG. 4(C), FIG. 4(D) and FIG. 4(E)). The stack in which the resist 70 has been patterned is subjected to an oxygen plasma treatment from the direction of the semiconductor layer to increase the resistance of part of the semiconductor layer, whereby the channel part 42 and source/drain parts 44 are formed in the semiconductor layer 40 (FIG. 4(F)). The pattered resist 70 is removed (FIG. 4(G)), and the protective layer 50 and the source/drain electrodes 60 are formed on the semiconductor layer 40 to obtain a field effect transistor 4 (FIG. 4(H)).

In this embodiment, unlike Embodiment 1, part of the semiconductor layer (oxide film) of which the resistance is increased is allowed to be a channel part, and part of the semiconductor layer of which the resistance is not increased is allowed to be source/drain parts.

As the method for increasing the resistance of part of the semiconductor layer (hereinafter often referred to as the “high-resistance treatment”), low-temperature oxidization methods such as an oxygen plasma treatment (plasma oxidization), an ozone treatment (ozone oxidization) and a high-pressure treatment (high-pressure oxidization), a light treatment (light oxidization), a method in which the semiconductor layer is covered by a protective film composed of an oxide, or the like can be given. Preferably, an oxygen plasma treatment or an ozone treatment is used.

In addition to the above-mentioned method, a high-resistance treatment may be conducted by applying a method for forming an insulating film by oxidizing silicon as described in the “Low-Temperature Poly-Silicon Thin Film-Transistor for System on Panel”-(by Yukiharu Urakawa, CMC Publishing Co., Ltd.), Chapter 5, or the like.

An oxygen plasma treatment (plasma oxidization) can be conducted by allowing a gas containing oxygen to be excited by an arbitrary applied frequency (frequency of an applied voltage, frequency of a power source) to generate oxygen plasma, followed by exposing an oxide film to the oxygen plasma, or by causing a surface wave plasma to be generated.

As for the applied frequency for the oxygen plasma treatment (plasma oxidization), an arbitral frequency can be used such as radio frequency (RF), very high frequency (VHF) and micro waves (μ waves).

The applied frequency is preferably 1 kHz or more and 300 MHz or less, more preferably 1 MHz or more and 30 MHz or less, particularly preferably 13.56 MHz. If the applied frequency is outside the range of 1 kHz or more and 300 MHz or less, an oxygen plasma may not be stable.

The input voltage is preferably 100 W or more, with 300 W or more being still more preferable. The pressure is preferably 5 Pa or more and 0.1 MPa or less. If the pressure is less than 5 Pa, the high-resistance treatment may be insufficient or may take an excessively long period of time. On the other hand, if the pressure exceeds 0.1 MPa, the substrate may be heated.

When micro waves (μ waves) are used in the oxygen plasma treatment, a surface wave plasma can be generated. In the case of surface wave plasma, a high-density plasma is generated in the vicinity of a micro wave-introducing part, and the micro wave does not directly reach the substrate which is distant from the plasma surface. As a result, the resistance of the oxide film can be increased while exerting only a slight damage.

In the ozone treatment (ozone oxidization) and the light treatment (light oxidization), an oxygen gas is excited by UV light or the like to cause ozone dissociation, and the resistance of the oxide film is increased by an oxygen atom, an oxygen ozone and an oxygen radical generated by the dissociation. In particular, if an oxygen atom is generated at the time of the ozone treatment and the light treatment as mentioned above, the oxygen atom has a higher activity than that of an oxygen ozone and an oxygen radical, and is effective.

As the UV light source, an excimer lamp (Xe excimer lamp or the like), a high-pressure mercury lamp, a low-pressure mercury lamp, an excimer laser lamp or the like can be used.

Part of the semiconductor layer is covered by a protective film composed of an oxide, and the protective film is then energized by heating or the like, whereby the part covered by the protective film can be subjected to a high-resistance treatment. In this high-resistance treatment, it is assumed that oxygen is moved from the protective film to the semiconductor layer, whereby the part of the semiconductor layer can have an increased resistance.

In the above-mentioned high-resistance treatment, when heating is conducted, the substrate temperature is preferably 200 to 550° C. If the substrate temperature is less than 200° C., the high-pressure treatment may be insufficient or may take an excessively long time. If the substrate temperature exceeds 550° C., the substrate may be warped, deformed, shrunk or may suffer other problems.

Heating time is preferably 1 to 240 minutes, more preferably 10 to 120 minutes. If the heating time is less than 1 minute, the high-pressure treatment may be insufficient or may take an excessively long time. If the heating time exceeds 240 minutes, the substrate may be warped, deformed, shrunk or may suffer other problems.

### Embodiment 4

FIG. 5 is a view showing steps of another embodiment of the method for producing a field effect transistor (bottom-gate type) according to the first aspect of the invention.

In this embodiment, at first, the gate electrode 20 is formed on the supporting substrate 10 (FIG. 5(A)). The gate insulating film 30 is formed so as to cover the gate electrode 20. On the gate insulating film 30 thus formed, the semiconductor layer 40, the protective film 80 and the resist 70 are stacked (FIG. 5(B)). For this stack, light exposure from the direction of the supporting substrate 10 and removal of the resist are conducted, whereby the resist 70 is patterned into a desired shape (FIG. 5(C), FIG. 5(D) and FIG. 5(E)). After patterning the resist 70, the protective film of the stack is etched to be patterned into a desired shape and the patterned resist 70 is removed (FIG. 5F). The stack having the patterned protective film 80 on the semiconductor layer 40 is then irradiated with UV rays from the direction of the semiconductor layer to reduce the resistance of part of the semiconductor layer, whereby the channel part 42 and the source/drain parts 44 are formed in the semiconductor layer 40 (FIG. 5(G)). The protective film 50 and the source/drain electrodes 60 are formed on the semiconductor layer 40, whereby a field effect transistor 5 is obtained (FIG. 5(H)).

This embodiment is the same as Embodiment 2 except that the resistance of part of the semiconductor layer is increased by the high-resistance treatment, whereby the channel part and the source/drain parts are formed in the semiconductor layer.

### Embodiment 5

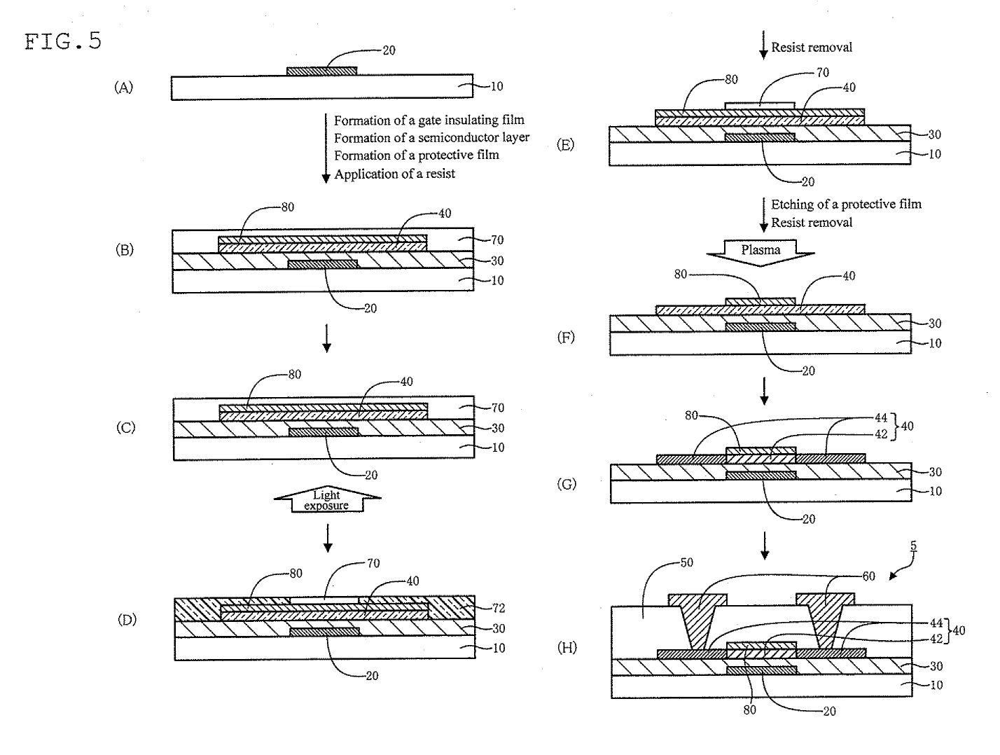

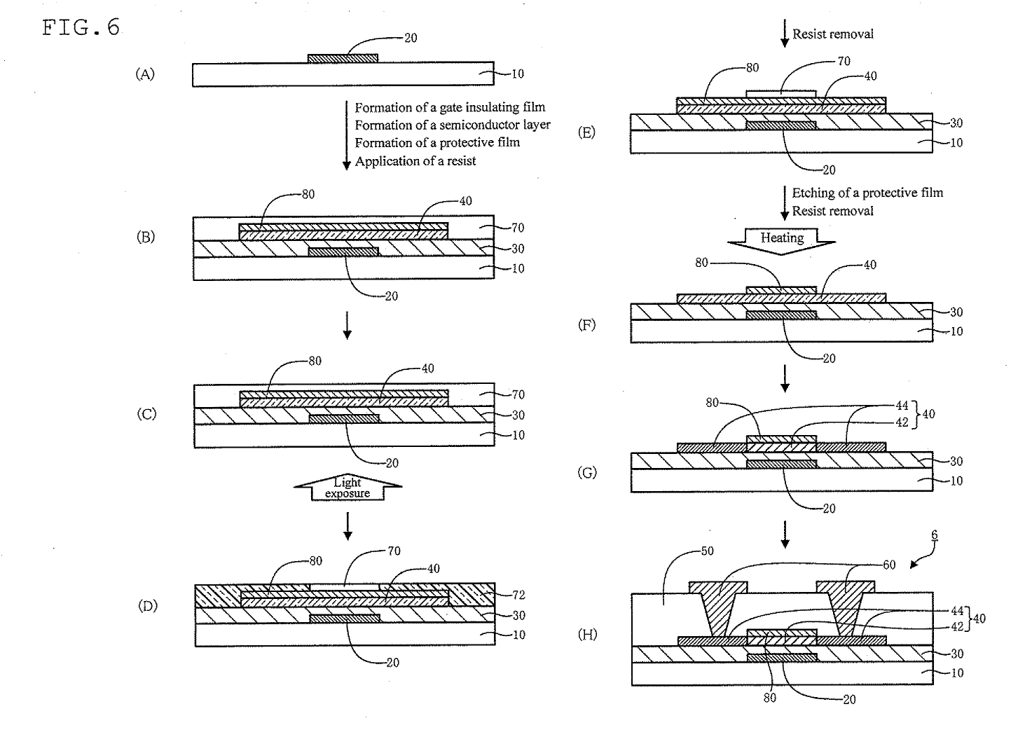

FIG. 6 is a view showing steps of another embodiment of the method for producing a field effect transistor (bottom-gate type) according to the first aspect of the invention.

In this embodiment, at first, the gate electrode 20 is formed on the supporting substrate 10 (FIG. 6(A)). The gate insulating film 30 is formed so as to cover the gate electrode 20. On the gate insulating film 30 thus formed, the semiconductor layer 40, the protective film 80 and the resist 70 are stacked (FIG. 6(B)). For this stack, light exposure from the direction of the supporting substrate 10 and removal of the resist are conducted, whereby the resist 70 is patterned into a desired shape (FIG. 6(C), FIG. 6(D) and FIG. 6(E)). After patterning the resist 70, the protective film of the stack is etched to be patterned into a desired shape. The patterned resist 70 is removed (FIG. 6(F)). The stack having the patterned protective film 80 on the semiconductor layer 40 is subjected to a heat treatment to increase the resistance of part of the semiconductor layer, whereby the channel part 42 and the source/drain parts 44 are formed in the semiconductor layer 40 (FIG. 6(G)). The protective film 50 and the source/drain electrodes 60 are formed on the semiconductor layer 40, whereby a field effect transistor 6 is obtained (FIG. 6(H)).

In the above-mentioned heat treatment, heating temperature is preferably 200 to 550° C., more preferably 250 to 400° C. If the heating time is less than 200° C., the resistance may not be sufficiently increased. When the heating temperature exceeds 550° C., the substrate may be warped, deformed, shrunk or may suffer other problems.

The heat treatment time is preferably 1 to 240 minutes, more preferably 10 to 120 minutes. If the heating time is less than 1 minute, the resistance may not be sufficiently increased. If the heating time exceeds 240 minutes, the substrate may be warped, deformed, shrunk or may suffer other problems. It is preferred that the above-mentioned heat treatment be conducted in an atmosphere of a low oxygen concentration, an inert gas atmosphere or a low-pressure atmosphere, or in a foaming gas, since, if the treatment is conducted in such an atmosphere, the resistance of part of the semiconductor layer which is not covered by the protective film can be lowered. The above-mentioned heating may be conducted by using RTA.

### Embodiment 6

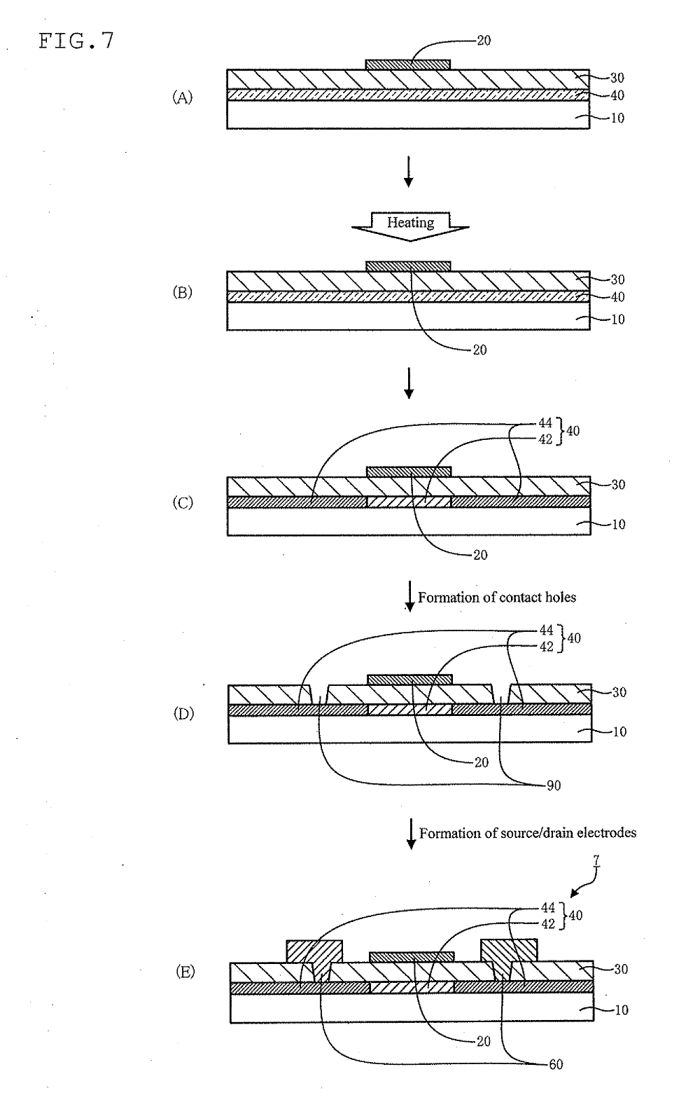

FIG. 7 is a view showing steps of another embodiment of the method for producing a field effect transistor (top-gate type) according to the first aspect of the invention.

In this embodiment, at first, the semiconductor layer 40, the gate insulating film 30 and the gate electrode 20 are stacked sequentially on the supporting substrate 10 (FIG. 7(A)). The gate electrode 20 of this stack is heated (FIG. 7(B)), whereby the channel part 42 and the source/drain parts 44 are formed in the semiconductor layer 40 (FIG. 7(C)). Subsequently, the gate insulating film 30 is etched to form contact holes 90, and the source/drain electrodes 60 are formed such that the contact holes 90 are embedded by these electrodes, whereby a field effect transistor 7 is obtained (FIG. 7(E)).

The surface of the supporting substrate 10 is preferably protected by an SiO₂ film or an SiNx film formed by CVD, sputtering or the like. By protecting the supporting substrate 10, scattering of metal ions or the like from the supporting substrate can be preferably prevented.

In this embodiment, part of the semiconductor layer covered by the protective film or the insulating film, of which the resistance is increased by heating the gate electrode, is allowed to be a channel part, and part of the semiconductor layer of which the resistance is not increased is allowed to be source/drain parts.

The oxide film formed on the supporting substrate is preferably a conductive film. If the oxide film is a conductive film, when the gate electrode is heated to allow part of the oxide film to be semiconductive to form a channel part, the remaining part can easily be a source part and a drain part.

The conductive film is preferably a conductive film having a specific resistance of 10⁻⁵ to 10⁰ Ωcm, more preferably a conductive film having a specific resistance of 10⁻⁴ to 10⁻² Ωcm. If the specific resistance of the conductive film exceeds 10⁰ Ωm, when the conductive film is used as a source part and a drain part, an ohmic contact with wirings may not be attained.

The gate insulating film is preferably composed of an oxide. If the gate insulting film is composed of an oxide and the gate insulating film is in the oxygen excessive state, when the gate electrode is heated, excessive oxygen is supplied to the oxide film, and as a result, the oxide film can be semiconductive easily to form a channel part.

The heating method of the gate electrode is not particularly restricted. For example, known heating methods such as lamp heating, semiconductor laser heating, excimer laser heating, electromagnetic induction heating and plasma jet heating can be used. Of these heating methods, lamp heating and semiconductor laser heating are preferable in respect of uniform heating. Lamp heating is further preferable due to capability of heating a large area.

### Embodiment 7

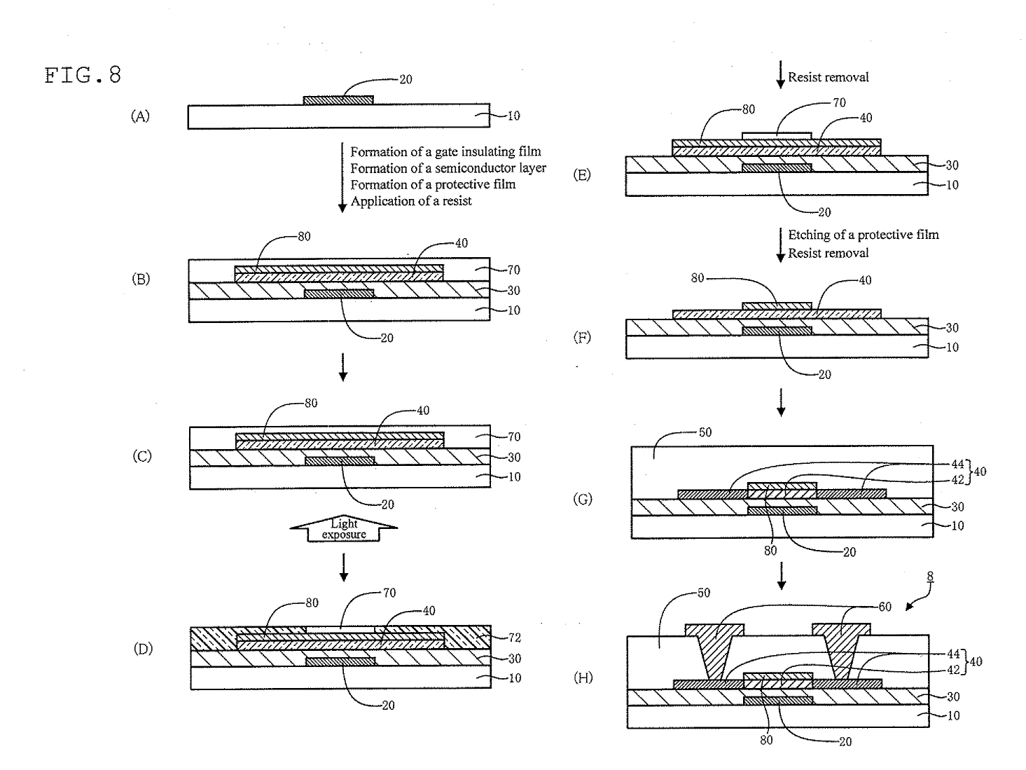

FIG. 8 is a view showing steps of another embodiment of the method for producing a field effect transistor (bottom-gate type) according to the first aspect of the invention.

In this embodiment, at first, the gate electrode 20 is formed on the supporting substrate 10 (FIG. 8(A)). The gate insulating film 30 is formed so as to cover the gate electrode 20. On the gate insulating film 30 thus formed, the semiconductor layer 40, the protective film 80 and the resist 70 are stacked (FIG. 8(B)). For this stack, light exposure from the direction of the supporting substrate 10 and removal of the resist are conducted, whereby the resist 70 is patterned into a desired shape (FIG. 8(C), FIG. 8(D) and FIG. 8(E)). The protective film of the stack in which the resist 70 has been patterned is etched to be patterned into a desired shape. Then, the patterned resist 70 is removed (FIG. 8(F)). The protective film 50 is formed on the stack having the patterned protective film 80 on the semiconductor layer 40, and at the same time, the resistance of part of the semiconductor layer is decreased, whereby the channel part 42 and the source/drain parts 44 are formed in the semiconductor layer 40 (FIG. 8(G)). The source/drain electrodes 60 are formed on the semiconductor layer 40, whereby a field effect transistor 8 is obtained (FIG. 8(H)).

This embodiment is the same as Embodiment 2 except that the protective film 50 is stacked by the plasma chemical vapor deposition (PECVD) method or the like and at the same time the resistance of part of the semiconductor layer is lowered instead of conducting UV irradiation, whereby the channel part 42 and the source/drain parts 44 are formed in the semiconductor layer 40 (FIG. 8(G)).

It is preferred that an oxide film such as SiOx be formed as the protective layer 80 by PECVD and an SiNx:H layer be formed as the protective layer 50 by PECVD. Improvement in moisture proof can be especially expected when an SiNx:H layer is formed as the protective layer 50.

Hereinabove, the method for producing a field effect transistor according to the first aspect of the invention is explained. A field effect transistor may be formed by combining the production methods of Embodiments 1 to 7 to increase the resistance of the channel part of the semiconductor layer, and to decrease the resistance of the source/drain parts.

The field effect transistor according to the first aspect of the invention can be preferably used in a display. Specifically, the source part or the drain part of the semiconductor layer of the field effect transistor according to the first aspect of the invention is electrically connected to the electrode of the display element of the display. The above-mentioned display element is preferably an electroluminescence device or a liquid crystal cell.

In the display according to the first aspect of the invention, preferably, a plurality of these display elements and the field effect transistors according to the first aspect of the invention are two-dimensionally arranged.

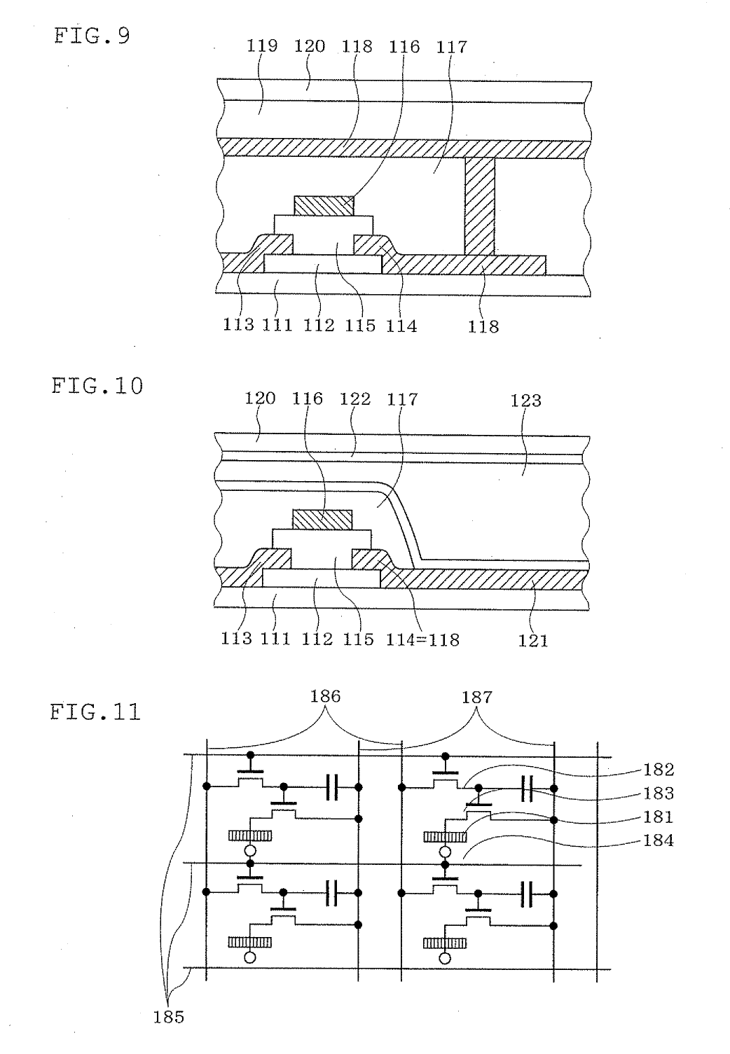

FIG. 9 is a schematic cross sectional view showing an example of using a field effect transistor according to the first aspect of the invention. In FIG. 9, to the drain which is an output terminal of the field effect transistor, an electrode of a display element such as an organic or inorganic electroluminescence (EL) device and a liquid crystal device is connected.

On a base 111, a field effect transistor which is constituted of an oxide film (channel layer) 112, a source electrode 113, a drain electrode 114, a gate insulating film 115 and a gate electrode 116 is formed. The drain electrode 114 is connected to an electrode 118 with an interlayer insulating film 117 being therebetween. The electrode 118 is in contact with an emitting layer 119, and the emitting layer 119 is in contact with an electrode 120. Due to such a configuration, current to be injected to the emitting layer 119 can be controlled by the value of current flown from the source electrode 113 to the drain electrode 114 through a channel formed in the oxide film 112. Therefore, this current can be controlled by a voltage of the gate electrode 116 of the field effect transistor. Here, the electrode 118, the emitting layer 119 and the electrode 120 constitute an organic or inorganic electroluminescence device.

FIG. 10 is a schematic cross sectional view showing another example of using a field effect transistor according to the first aspect of the invention.

In the shown configuration, the drain electrode 114 extends to serve also as the electrode 118, and the electrode 118 applies a voltage to a liquid crystal cell or an electrophoretic particle cell 123 between high-resistance films 121 and 122. The liquid crystal cell or the electrophoretic particle cell 123, high-resistance layers 121 and 122, the electrode 118 and the electrode 120 constitute a display element. A voltage to be applied to these display elements can be controlled by the value of current frown from the Source electrode 113 to the drain electrode 114 through a channel formed in the amorphous oxide semiconductor film 112. Therefore, this can be controlled by a voltage of the gate electrode 116 of a TFT. If a display medium of the display element is a capsule obtained by sealing a fluid and particles in an insulating film, the high-resistance films 121 and 122 are unnecessary.

In the above-mentioned two embodiments, as the field effect transistor, a field effect transistor of a top-gate type coplanar structure is given as a representative example. However, this embodiment is not limited to this configuration. For example, the field effect transistor may have a staggered type structure or other structures if the connection of the drain electrode, which is an output terminal of the field effect transistor, to the display element is the topologically same.

In the above-mentioned two embodiments, an example is shown in which a pair of electrodes driving a display element are provided such that they are in parallel with the base. However, this embodiment is not limited to this configuration. For example, if the connection of the drain electrode, which is an output terminal of the field effect transistor, to the display element is the topologically same, one or both of the electrodes may be provided perpendicularly to the base.

Further, in the above-mentioned two embodiments, only one field effect transistor connected to the display element is shown. However, the display according to the first aspect of the invention is not limited to this configuration. For example, the field effect transistor shown in the figure may be connected to another field effect transistor, and the field effect transistor in the figure may be the final stage of a circuit composed of these field effect transistors.

When a pair of electrodes for driving the display element are provided such that they are parallel to the base, if the display element is a reflective type display element like an EL device or a reflective type liquid crystal device, one of the electrodes is required to be transparent for an emission wavelength or a wavelength of reflected light. In the case of a transmitting type display element such as a transmitting liquid crystal device, both electrodes are required to be transparent for transmitted light.

Further, in the field effect transistor according to the first aspect of the invention, it is possible to allow all of the constituting members to be transparent, whereby a transparent display element can be formed. In addition, such a display element can be provided on a substrate with a low heat resistance such as a resin-made plastic substrate which is light in weight, flexible and transparent.

FIG. 11 is a schematic cross sectional view showing another embodiment of a field effect transistor according to first aspect of the invention. Specifically, FIG. 11 is a schematic cross sectional view of a display in which pixels comprising an EL device (here, an organic EL device) and the field effect transistor are two-dimensionally arranged.

In FIG. 11, 181 is a transistor for driving an organic EL layer 184, and 182 is a transistor for selecting a pixel. A condenser 183 serves to keep the selected state, and stores carriers between a common electrode 187 and the source part of the transistor 182, thereby to keep gate signals of the transistor 181. Pixel selection is conducted by a scanning electrode line 185 and a signal electrode line 186.

An image signal is applied in the form of a pulse signal to the gate electrode from a drive circuit (not shown) through the scanning electrode 185. Simultaneously, another image signal is applied also in the form of a pulse signal to the transistor 182 from another driver circuit (not shown) through a signal electrode 186, whereby a pixel is selected. At this time, the transistor 182 is turned ON, and charges are stored in a condenser 183 between the signal electrode line 186 and the source of the transistor 182. As a result, the gate electrode of the transistor 181 is kept at a desired voltage to turn the transistor 181 ON. This stage is kept until other signals are received. During the period of time while the transistor 181 is ON, a voltage and a current are kept on being supplied to the organic EL layer 184, whereby the emission is retained.

In the configuration of FIG. 11, one pixel contains two transistors and one condenser. However, in order to improve the performance, a larger number of transistors or the like may be incorporated. Essentially, by using the field effect transistor according to the first aspect of the invention in a transistor part, an effective EL device can be obtained.

Hereinbelow, a display using the field effect transistor shown in FIG. 10 is explained. In this field effect transistor, the short side of the island of an In₂O₃—ZnO film constituting the drain electrode is extended to 100 μm. The extended 90-μm part is remained, and after wirings for the source electrode and the gate electrode are ensured, the TFT is coated with an insulating layer. A polyimide film is applied thereon, followed by a rubbing treatment. On the other hand, similarly, an In₂O₃—ZnO film as a transparent conductive film and a polyimide film are formed on a glass substrate, followed by a rubbing treatment. The resulting glass substrate is opposed to the above-mentioned substrate on which the field effect transistor is formed while providing a space of 5 μm therebetween. A nematic liquid crystal is injected into this space. Further, on the both sides of this structural body, a pair of deflection plates are provided. When a voltage is applied to the source electrode of the field effect transistor to allow the voltage to be applied to the gate electrode to change, the light transmittance of only a region of 30 μm×90 μm, which is part of the island of an In₂O₃—ZnO film extended from the drain electrode is changed. The light transmittance can be changed continuously by the source-drain voltage under a gate voltage at which the field effect transistor is turned ON. In this way, a display element shown in FIG. 10 having a liquid crystal cell as a display element is prepared.

As the substrate forming a TFT, a white plastic substrate is used, and gold is used for each electrode of a TFT, whereby a configuration is attained in which a polyimide film and deflection plates are not used. Further, in a gap between a white plastic substrate and a transparent substrate, capsules obtained by coating particles and fluids with an insulating film are filled. In the case of a display element with such a configuration, a voltage between the drain electrode which is extended according to this field effect transistor and the In₂O₃—ZnO film above the drain electrode is controlled, whereby particles in the capsule move upward and downward. As a result, by controlling the reflectance of the drain electrode region which is extended as viewed from the transparent substrate, display can be conducted.

Further, for example, a normal current control circuit having a 4-transistor/1-capacitor configuration can be formed from adjacent field effect transistors and a TFT shown in FIG. 9 can be used as one of the transistors on the final stages for driving an EL device. For example, a field effect transistor having the above-mentioned In₂O₃—ZnO film as the drain electrode is used. In a region of 30 μm×90 μm, which is part of the island of an In₂O₃—ZnO film extended from the drain electrode, an organic electroluminescence device comprising a charge-injecting layer and an emitting layer is formed. In this way, a display element, using an EL device can be formed.

The above-mentioned display element and the field effect transistor are two-dimensionally arranged. The following example can be given. The above mentioned display elements such as a liquid crystal cell and EL device and the field effect transistors form pixels which have an area of about 30 μm×115 μm. The pixels are arranged in a rectangle shape; 7425 pixels are arranged at a 40 μm-pitch in the short side and 1790 pixels are arranged at a 120 μm-pitch in the long side. 1790 gate wirings passing through the gate electrodes of 7425 field effect transistors in the long side direction are provided and 7425 signal wirings passing through, in the short side direction, extensions of the source electrodes of the 1790 TFTs projecting from the islands of the amorphous oxide semiconductor films by 5 μm are provided. Each of these is connected to a gate driver circuit or a source driver circuit. Further, in the case of a liquid crystal display element, if a color filter which is positioned with the same size as that of the liquid crystal display element and RGB is repeated in the long-side direction is provided on the surface, an A4-size active matrix color display can be constituted with about 211 ppi.

In an EL device, of the two field effect transistors contained in one EL device, the gate electrode of a first field effect transistor is connected to a gate line and the source electrode of a second field effect transistor is connected to a signal line, and the emission wavelength of an EL device is changed between RGB in the long-side direction. In this way, a light-emitting color display can be constituted with the same dissolution.

Here, the circuit for driving an active matrix may be composed of a TFT of this embodiment which is the same as that of the field effect transistor of the pixel, or may be a known IC chip.

Hereinbelow, the second aspect of the invention will be explained in detail.

The semiconductor device according to the second aspect of the invention is characterized in that an oxide semiconductor, which is a non-degenerate semiconductor, is connected to a conductor with an oxide semiconductor, which is a degenerate semiconductor, therebetween.

As examples of the above-mentioned structure, connection of the channel layer (oxide semiconductor) and the source/drain electrodes (conductor) in a field effect transistor or a high-resistance layer and a low-resistance layer in a resistance random access memory.

By using the structure in the second aspect of the invention in the connection part, the resistance or carrier injection properties of the connection part can be controlled, whereby a semiconductor device with excellent properties can be prepared.

In the second aspect of the invention, an oxide semiconductor which is a non-degenerate semiconductor means a semiconductor of which the temperature characteristics of the conductivity shows thermal activation type behavior and the conductivity has a large temperature dependence.

On the other hand, an oxide semiconductor which is a degenerate semiconductor means a semiconductor of which the temperature characteristics of the conductivity does not show thermal activation type behavior and the conductivity is less dependent on the temperature.

Whether the oxide semiconductor is a non-degenerate semiconductor or a degenerate semiconductor can be judged by judging the temperature dependency of the mobility or the electrical conductivity. In the second aspect of the invention, one having an activation energy of 25 meV or more is referred to as a non-degenerate semiconductor and one having an activation energy of less than 25 meV is referred to as a degenerate semiconductor.

Here, the activation energy means an activation energy of an oxide semiconductor film obtained from an Arrhenius plot of the electric conductivity.

The oxide semiconductor is composed of a composite oxide satisfying a predetermined composition ratio, and can be formed into a thin film by sputtering using a composite oxide target, for example.

A composite oxide target is made of, as a raw material, a mixed powder which contains an oxide such as indium oxide at a specific elemental ratio. A composite target can be prepared by a process, in which, after the raw material powder is finely pulverized by means of a ball mill or the like, the resulting fine powder is molded into a target-like shape, followed by firing. The details will be explained with reference to the example of a field effect transistor, given below.

As the method for the separate preparation of the non-degenerate semiconductor and the degenerate semiconductor, the following methods can be given, for example.

(1) The non-degenerate semiconductor and the degenerate semiconductor are allowed to have a different composition or composition ratio.
(2) The oxygen partial pressure is adjusted during film formation.
(3) Ion injection is conducted.

By using the method in (1) above, the oxide semiconductor can be a non-degenerate semiconductor easily when the composition of the channel part is a composition in the following region 1, 2 or 3. By using the method in (2) above, the oxide semiconductor can be a non-degenerate semiconductor easily when the oxygen partial pressure at the time of film formation is allowed to be 10⁻² Pa or less. By using the method in (3) above, the oxide semiconductor can be a non-degenerate semiconductor easily by irradiating hydrogen ions of 1×10¹⁵ (1/cm²) or more.

In addition, by using the high-resistance method in the first aspect of the invention, the oxide semiconductor can be a non-degenerate semiconductor, or by using the low-resistance method, the oxide semiconductor can be a degenerate semiconductor.

Of these methods, the method (1) or (2) is preferable, with the method (1) being particularly preferable. By this method, a highly stable semiconductor can be prepared easily. If formation is conducted by controlling the oxygen partial pressure during formation or by injecting ions, stability may be deteriorated since the composition is largely deviated from the chemical stoichiometric ratio.

In the second aspect, there are no particular restrictions on the conductor. Metals or alloys which are used in electrodes, wirings or the like of a semiconductor device can be used. Specifically, Ti, Pt, Cr, W, Al, Ni, Cu, Mo, Ta, Au and Nb or alloys or stacks containing these can be used.

Hereinbelow, as the specific examples of the semiconductor device according to the second aspect of the invention, an example of the field effect transistor will be explained.

The field effect transistor according to the second aspect of the invention comprises a channel part comprising an oxide semiconductor, a source part and a drain part each comprises an oxide semiconductor having a composition different from that of the channel part. The field effect transistor is characterized in that the channel part is connected to a source electrode and a drain electrode with the source part and the drain part being therebetween.

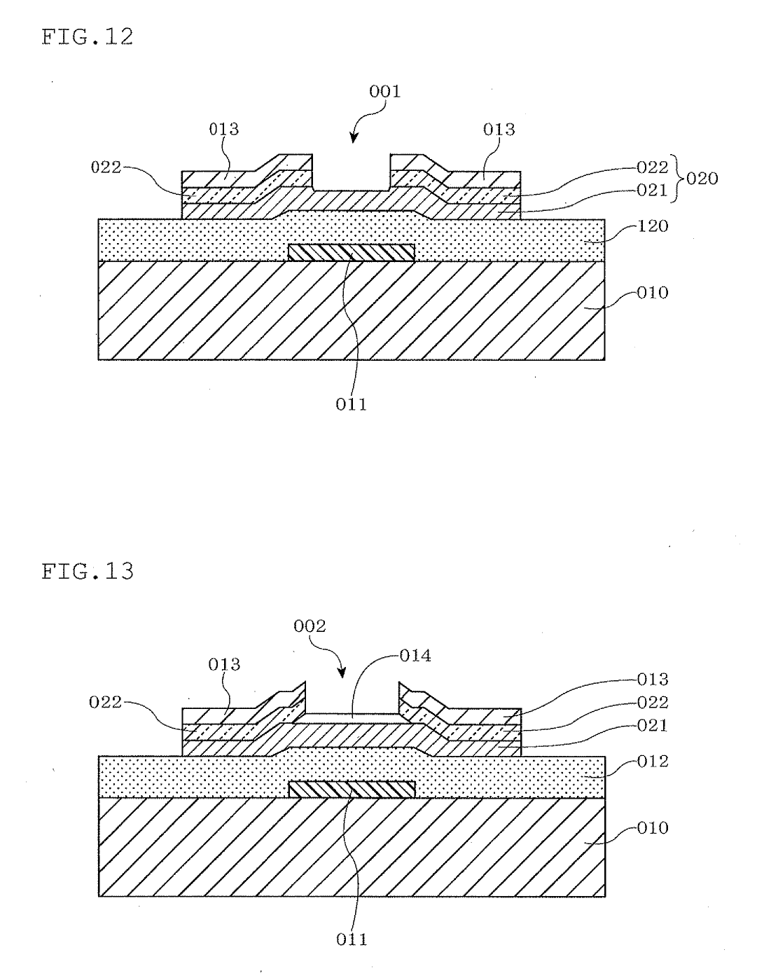

FIG. 12 is a schematic cross sectional view showing one embodiment of a field effect transistor according to second aspect of the invention.

In a field effect transistor 001, on a substrate 010, a gate electrode 011 is formed in the shape of a stripe. A gate insulating film 012 is formed so as to cover the gate electrode 011, and a channel part 021 is formed on this gate insulating film 021 above the gate electrode 011.

On the both sides of the channel part 021, in the direction orthogonally crossing the gate electrode 012, source/drain parts 022 are formed. On the source/drain parts 022, source/drain electrodes 013 are formed.

In this embodiment, the channel part 021, and the source/drain parts 022 are the oxide semiconductor 020. The channel part 021 is composed of a non-degenerate semiconductor and each of the source/drain parts 022 is composed of a degenerate semiconductor. The channel part 021 is connected to the source/drain electrodes 013 which are conductors with the source/drain parts 022 therebetween.

Due to such a configuration, the effective S/D serial resistance between the oxide semiconductor and the source electrode or the drain electrode can be small, and the drain concentration in the oxide semiconductor can be suppressed.

In the transistor according to second aspect of the invention, the channel part is a non-degenerate semiconductor and at least one of the above-mentioned source part and the drain part is a degenerate semiconductor. If the channel part is not a non-degenerate semiconductor, the off current may become high when used as a transistor or the transistor may become normally-on. Moreover, when the source part and the drain part are not a degenerate semiconductor, when used as a transistor, transistor properties may be deteriorated; specifically, resistance with the electrode becomes high to lower the mobility or the on-off ratio or the threshold voltage becomes large.

In the second aspect of the invention, it is preferred that the composition of the oxide semiconductor which constitutes the channel part differ from the composition of the oxide semiconductor which constitutes the source part and the drain part.

The activation energy of the oxide semiconductor which constitutes the channel part is preferably 30 meV or more, more preferably 40 meV or more, further preferably 50 meV or more, with 100 meV or more being particularly preferable. If the activation energy is smaller than 30 meV, the off current may become high or the transistor may become normally-on.

The activation energy of the oxide semiconductor which constitutes the source part and/or drain part is preferably less than 20 meV, more preferably less than 10 meV, with less than 5 meV being particularly preferable. When the activation energy is 20 meV or more, the effective S/D serial resistance becomes high, whereby the transistor properties are deteriorated, e.g. the mobility or the on-off ratio is lowered, the threshold voltage is increased or the like.

The configuration of the field effect transistor according to the second aspect of the invention is not limited to that of the field effect transistor 001 shown in FIG. 12. For example, the configurations shown by the following FIGS. 13 to 15 can be given.

FIG. 13 is a schematic cross sectional view showing another embodiment of a field effect transistor according to second aspect of the invention. The field effect transistor 002 has a configuration in which an etching stopper (protective film) 014 is stacked in a gap between the source part and the drain part on the channel part 021. Other configurations are similar to those of the above-mentioned field effect transistor 001.

Due to the formation of the etching stopper 014, deterioration of properties by an external atmosphere can be suppressed.

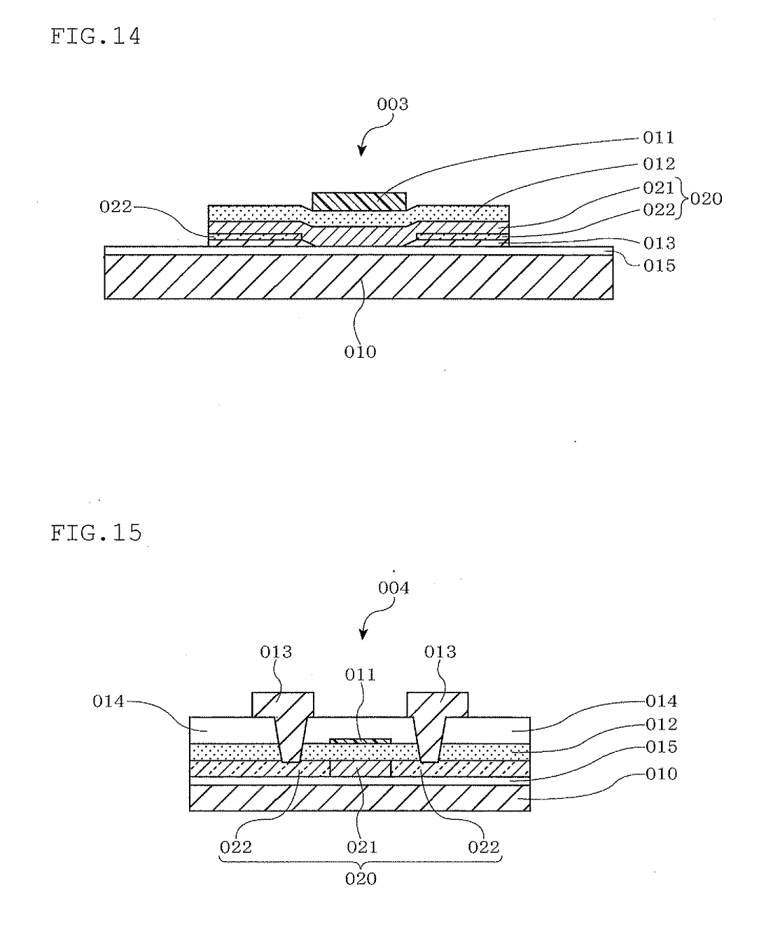

FIG. 14 is a schematic cross sectional view showing an example of a top-gate type field effect transistor.

In the field effect type transistor 003, a protective film 015 is provided on a substrate 010, and source/drain electrodes 013 are formed thereon. On the source/drain electrodes 013, the source/drain parts 022 are stacked. Furthermore, the channel part 021 is formed on the source/drain parts 022 and in a gap therebetween, whereby a gate insulating film 012 is formed on the channel part 021. The gate electrode 011 is provided on the gate insulating film 012 at a place which corresponds to the gap of the source/drain electrodes 013.

FIG. 15 is a schematic cross sectional view showing a top-gate type field effect transistor. The field effect transistor 004 is a transistor of a coplanar structure, and the channel part and the source/drain parts are on the same plane. Specifically, on the protective film 015 of the substrate 010, the source/drain parts 022 are formed with a gap therebetween, and the channel part 021 is formed in this gap. On the channel part 021 and the source/drain parts 022, the gate insulating film 012 and the protective film 014 are sequentially stacked. The source/drain parts 022 are connected to the source/drain electrodes 013 through contact holes which penetrate them.

The transistor in each of the above embodiments has both the source part and the drain part. In the invention, it suffices that at least one of the source part and the drain part is provided.

However, it is preferred that both the source part and the drain part be provided.

The composition of the oxide semiconductor constituting the source part and that of the drain part may be the same or different.

As in the case of the transistor 004 shown in FIG. 15, the source part and the drain part may be formed in line or may be stacked one on another as shown in FIGS. 12 to 14. It is preferred that the source part and the drain part be stacked above or below the channel part. If the source part and the drain part are not stacked above or below the channel part, the channel part may not be connected to the source part and the drain part with a high degree of accuracy.

Each constituting element of the field effect transistor according to the second aspect of the invention will be explained below.

### 1. Substrate

There are no particular restrictions, and known substrates in the art can be used. For example, glass substrates such as alkali silicate glass, non-alkali glass and quartz glass, silicon substrates, resin substrates such as acryl, polycarbonate and polyethylene naphthalate (PEN) and high-molecular film bases such as polyethylene terephthalate (PET) and polyamides cam be used.

The thickness of the substrate or the base is normally 0.1 to 10 mm, preferably 0.3 to 5 mm. In the case of a glass substrate, it is preferable to use a glass substrate which is chemically or thermally reinforced.

If transparency or smoothness is required, a glass substrate and a resin substrate are preferable, with a glass substrate being particularly preferable. If a substrate is required to be light in weight, it is preferable to use a resin substrate or a high-molecular base.

2. Oxide semiconductor

The oxide semiconductor is composed of a composite oxide satisfying the specific composition ratio. The oxide semiconductor (the channel part, the source part and the drain part) can be used by using a composite oxide target, for example.

The composite oxide target is formed of, as a raw material, powder mixture containing indium oxide, zinc oxide and an oxide of the element X in such an amount that satisfies the element ratio, given later, for example. The target can be prepared by pulverizing the raw material powder by means of a ball mill or the like, molded into a target-like form, followed by firing.

Part of the raw material powder used may be one which is prepared from a scrap containing high-purity indium oxide such as remaining target materials or used targets. In particular, indium oxide collected from an ITO target is preferable since it contains an appropriate amount of Sn (tin) as impurities. Collection of indium oxide can be conducted by a known method such as one disclosed in JP-A-2002-069544.

The element X is preferably an element selected from Ga, Al, B, Sc, Y, lanthanoids (La, Ce, Pr, Nd, Sm, Eu, Gd, Tb, Dy, Ho, Er, Tm, Yb and Lu), Zr, Hf, Ge, Si, Ti, Mn, W, Mo, V, Cu, Ni, Co, Fe, Cr and Nb. In particular, Ga, Al, Zr, Hf and Cu are preferable, with Ga, Al and Zr being particularly preferable.

If the element X is Zr, Hf, Ge, Si, Ti, V and Nb, a target with a good appearance and has a high transverse rupture strength can be produced easily.

The purity of each raw material powder is normally 99.9% (3N) or more, preferably 99.99% (4N) or more further preferably 99.995% or more, and particularly preferably 99.999% (5N) or more. If the purity of each raw material power is less than 99.9% (3N), semiconductor properties may be lowered by impurities, uneven color or formation of dots may occur to deteriorate external appearance, reliability may be lowered or the like.

As for the raw material powder, it is preferred that the specific surface area of indium oxide powder be 8 to 10 m²/g, the specific surface area of zinc oxide powder be 2 to 4 m²/g and the specific surface area of an oxide of the element X be 8 to 10 m²/g. It is preferred that the median diameter of indium oxide powder be 0.2 to 2 μm and the median diameter of zinc oxide powder be 0.8 to 1.6 μm.

The powder mixture is pulverized and mixed by means of a wet medium stirring mill. At, this time, it is preferable to conduct pulverization such that the specific surface area after the pulverization be increased in an amount of 1.5 to 2.5 m²/g as compared with the specific surface area of the raw material powder, or such that the average median diameter after the pulverization become 0.6 to 1 μm. By using the raw material powder which has been adjusted in this way, it is possible to obtain a high-density oxide sintered body without the need of pre-firing process. A reduction process will also be unnecessary.

If an increase in specific surface area of the raw material powder mixture is less than 1.0 m²/g or the average median diameter of the raw material powder mixture after pulverization exceeds 1 μm, the sintering density may not be sufficiently large. On the other hand, if an increase in specific surface area of the raw material powder mixture exceeds 3.0 m²/g or if the average median diameter after the pulverization is less than 0.6 μm, the amount of contaminants (the amount of impurities which have been mixed in) from a pulverizer or the like during the pulverization may be increased.

Here, the specific surface area of each powder is a value measured by the BET method. The median diameter of each powder is a value measured by a particle size distribution analyzer. These values can be adjusted by pulverizing powder by a dry pulverization method, a wet pulverization method or the like.

The raw material after the pulverization is molded after drying by means of a spray dryer or the like. For the molding, a known molding method such as pressure molding and cold isostatic molding can be used, for example.

Subsequently, the resulting molded product is sintered to obtain a sintered body. It is preferred that sintering be conducted at 1350 to 1600° C. for 2 to 20 hours. If the sintering temperature is less than 1350° C., the density may not be increased. A sintering temperature exceeding 1600° C. may result in problems that zinc evaporates to cause the composition of the sintered body to vary or voids are generated by evaporation in the sintered body.

As for the sintering, it is preferable to conduct sintering in an oxygen atmosphere by circulating oxygen or conduct sintering under pressure. In this way, evaporation of zinc can be suppressed, whereby a sintered body having no voids can be obtained.

The sintered body produced by the above-mentioned method has a high density, and hence, it can produce an oxide semiconductor film improved in film properties since it generates a less amount of nodules or particles during use.

An oxide sintered body becomes a target by subjecting it to a processing such as polishing. Specifically, for example, a sintered body is ground by means of a surface grinder to allow it to have a surface roughness Ra of 5 μm or less. Further, the sputtering surface of the target is subjected to mirror polishing to allow an average surface roughness Ra to be 1000 Å or less. This mirror polishing can be conducted by a known polishing technology such as mechanical polishing, chemical polishing and mechanochemical polishing (combination of mechanical polishing and chemical polishing). For example, polishing may be conducted by using a fixed abrasive polisher (polishing solution: water) to allow a target to have a roughness of #2000 or more, or, polishing may be conducted by lapping by means of a free abrasive lap (abrasive: SiC paste or the like) and then lapping by using diamond paste instead of the abrasive. There are no particular restrictions on such polishing method.

By bonding to a backing plate, the resulting sputtering target can be installed in various film-forming apparatuses. As examples of the film-forming method, the sputtering method, the PLD (pulse laser deposition) method, the vacuum vapor deposition method, the ion plating method or the like can be given.

For cleaning the target, air blowing, washing with running water or the like can be used. If removal of foreign matters is performed by air blowing, foreign matters can be effectively removed by absorbing the air by means of a dust collector facing the nozzle.

In addition to air blowing or washing with running water, it is possible to conduct ultrasonic cleaning or the like. In the ultrasonic cleaning, it is effective to conduct the ultrasonic cleaning by generating multiple oscillation within a frequency of 25 to 300 KHz. For example, ultrasonic cleaning may be performed by generating multiple oscillation of 12 kinds of frequencies of from 25 to 300 KHz every 25 KHz.

The particle size of each compound in the oxide sintered body is preferably 20 μm or less, further preferably 10 μm or less, with 5 μm or less being particularly preferable. The particle size is an average particle size measured by an electron probe micro-analyzer (EPMA). The preferable crystal particle size is obtained by adjusting, for example, the amount ratio of each powder of indium oxide, an oxide of the element X and zinc oxide as raw materials or the particle size, the purity, the heating time, the sintering temperature, the sintering time, the sintering atmosphere and the cooling time of the raw material powder. If the particle size of the compound is larger than 20 μm, nodules may be generated furing sputtering.

It is preferred that the density of the target be 95% or more, more preferably 98% or more, and particularly preferably 99% or more, of the theoretical density. If the density of the target is smaller than 95%, the strength may become insufficient to cause the target to be broken during the film formation. In addition, when a transistor is prepared, its performance may become non-uniform.

Here, the theoretical relative density of the target is measured by the following method. That is, the density is calculated from the specific gravity of each oxide and the amount ratio of oxides (for example, ZnO is 5.66 g/cm³, In₂O₃ is 7.12 g/cm³, ZrO₂ is 5.98 g/cm³), the ratio of the density thus obtained with a density obtained by the Archimedian method is calculated to obtain a theoretical relative density.

It is preferred that the bulk resistance of the target be 20 mΩ or less, more preferably 10 mΩ or less, and particularly preferably 5 mΩ or less. If the bulk resistance is 20 mΩ or more, when DC sputtering is conducted, the target may be broken and spark is generated due to abnormal discharge to cause the target to be cracked or the properties of the resulting film as an oxide semiconductor film may be deteriorated due to the adhesion of particles which have jumped out from the target by the spark to a formed film on a substrate. In addition, the target may be cracked during discharge.

The bulk resistance is a value measured by the four probe method using a resistivity meter.

The transverse rupture strength of the target of the second aspect of the invention is preferably 8 kg/mm², more preferably 10 kg/mm², and particularly preferably 12 kg/mm². For the reason that a load may be applied during transportation and attachment to cause the target to be broken, a target is required to have a transverse rupture strength which is equal to or larger than a predetermined level. If the transverse rupture strength is less than 8 kg/mm², it may not be used as a target. The transverse rupture strength of a target can be measured according to JIS R 1601.

In the second aspect of the invention, the oxide semiconductor is required to be formed separately into a non-degenerate semiconductor and a degenerate semiconductor. As mentioned above, for the separate formation, it is preferable to use a method in which the composition or composition ratio is differed between the non-degenerate semiconductor and the degenerate semiconductor.

In the above-mentioned method, for example, it is preferred that the channel part, the source part and the drain part be an oxide containing In. Also it is preferred that the ratio of In in all elements except oxygen in the channel part be smaller than the ratio of In in all elements except oxygen of the source part and the drain part.

When the channel part, the source part and the drain part each comprises an oxide containing In, the channel part has an electron structure similar to that of the source part and the drain part, and hence, generation of resistance at the contact surface can be easily prevented. The channel part, the source part and the drain part contain In in an amount of 20 at % or more, more preferably 30 at % or more, of the all elements except oxygen. If the amount of In is less than 20 at %, the mobility of the transistor may be lowered.

If the content of In is large, carriers are generated easily due to oxygen deficiency, and the oxide semiconductor tends to be a degenerate semiconductor easily. It the content of In in all elements except oxygen of the channel part is larger than the content of In in all elements except oxygen of the source part and the drain part, the channel part may also become a degenerate semiconductor, and the off current of the transistor may be increased or the transistor may become normally-on.

It is preferred that the composition or composition ratio except oxygen, hydrogen and deuterium be different. It is preferred that the content of oxygen, hydrogen and deuterium be substantially the same. If the content of oxygen, hydrogen and deuterium is different, when a thermal history is applied, oxygen, hydrogen and deutrium may move between the two layers to cause the properties to vary.

The composition of the source part and the composition of the drain part may be the same or different.

It is preferred that the channel part, the source part and the drain part be oxides containing In, Zn and the element X, and the ratio of the element X in all elements except oxygen of the channel part be larger than the ratio of the element X in all elements of the source part and the drain part.

If the ratio of the element X is small, carriers may be generated easily due to oxygen deficiency to cause the oxide semiconductor to be a degenerate semiconductor easily. If the ratio of the element X of all elements except oxygen of the channel part is smaller than the ratio of the element X of all elements of the source part and the drain part, the channel part may also be a degenerate semiconductor, and the off current of the transistor may be increased or the transistor may become normally-on.

It is preferred that each of the channel part, the source part and the drain part be composed of an oxide containing In, Zn and the element X, that the composition of the channel part satisfy the atomic ratio in any of the region 1, region 2 and region 3, given below, and that the composition of the each of the source part and the drain part satisfy the atomic ratio in the region 4, given below.

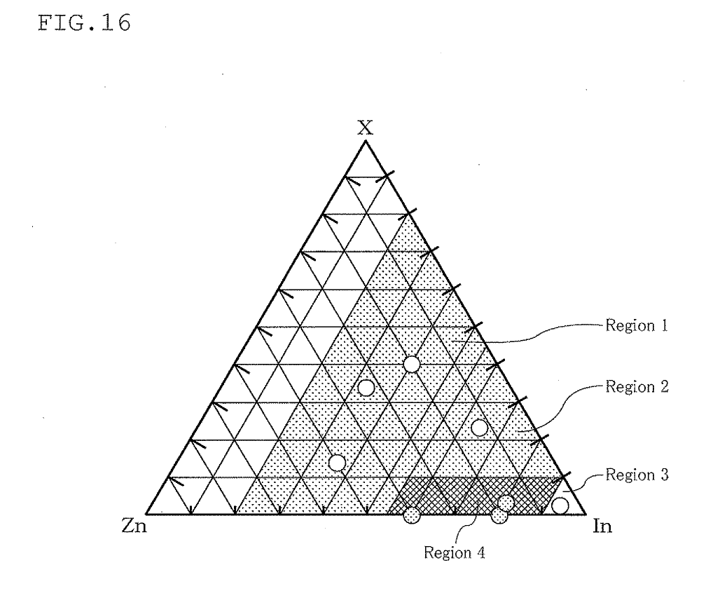

The preferable composition range of the oxide semiconductor according to the second aspect of the invention is shown in FIG. 16. The dot line in FIG. 16 indicates the composition of the oxide semiconductor in Examples given later.

In/(In +Zn+X)=0.20 to 0.55

Zn/(In+Zn+X)=0.00 to 0.80

X/(In+Zn+X)=0.00 to 0.80 Region 1

In/(In +Zn+X)=0.55 to 0.90

Zn/(In+Zn+X)=0.00 to 0.35

X/(In +Zn+X)=0.10 to 0.45 Region 2

In/(In+Zn+X)=0.90 to 1.00

Zn/(In+Zn+X)=0.00 to 0.10

X/(In+Zn+X)=0.00 to 0.10 Region 3

In/(In+Zn+X)=0.55 to 0.90

Zn/(In+Zn+X)=0.00 to 0.45

X/(In+Zn+X)=0.00 to 0.10 Region 4

Of the regions 1 to 3, the region 1 or the region 3 is preferable, with the region 1 being particularly preferable. The atomic ratio of the region 1 or the region 3 is preferable, since the off current is low and the on-off ratio is high.

In the region 1, it is preferred that the In/(In+Zn+X) be 0.25 to 0.45. If the In/(In+Zn+X) is smaller than 0.20, the mobility may be lowered. If the In/(In+Zn+X) is larger than 0.55, the off current may be increased or the transistor may become normally-on.

If the Zn/(In+Zn+X) is larger than 0.80, the mobility may be lowered or the chemicals resistance may be lowered.

If the X/(In+Zn+X) is larger than 0.80, the mobility may be lowered, the S value may be increased or the etching rate may be lowered.

In the region 4, the In/(In+Zn+X) is more preferably 0.57 to 0.85, with 0.6 to 0.8 being further preferable.

The Zn/(In+Zn+X) is more preferably 0.15 to 0.43, with 0.20 to 0.40 being further preferable.

The X/(In+Zn+X) is more preferably 0.01 to 0.09, with 0.02 to 0.08 being further preferable.

In the second aspect of the invention, the channel part is an oxide which comprises In, Zn and the element X, each of the source part and the drain part is an oxide which comprises In, Zn and an element Y, each of the element X and the element Y being an element selected from the group consisting of Ga, Al, B, Sc, Y, lanthanoids (La, Ce, Pr, Nd, Sm, Eu, Gd, Tb, Dy, Ho, Er, Tm, Yb, Lu), Zr, Hf, Ge, Si, Ti, Mn, W, Mo, V, Cu, Ni, Co, Fe, Cr, Nb and Sn, and the element X and the element Y are different from each other.

As the element X, Ga, AI, Zr, Hf and Cu are more preferable, with Ga, Al and Zr being particularly preferable.

As the element Y, Ga, Al, Zr, Hf, Cu and Sn are preferable, with Ga, Al and Zr being particularly preferable.

If the element X and the element Y differ from each other in this way, properties such as the etching selection ratio can be controlled.

An etching selection ratio of the source part and the drain part to the channel part is preferably 5 or more, more preferably 10 or more. If the etching selection ratio is smaller than 5, when the source/drain parts are etched, the channel part may also be etched, which leads to the need of increasing the thickness of the channel part.

The etching selection ratio is a value calculated from the etching speed when etching is conducted in a PAN etching solution of 30° C.

In the conventional a-Si channel etching type production process, the etching selection ratio of the channel part (a-Si) to the source part and the drain part (n+a-Si, a-Si doped with P) is about 3, and hence, the thickness of the channel part is required to be about 300 nm. However, in the second aspect of the invention, by changing the composition or the composition ratio, the etching selection ratio of the source part and the drain part to the channel part can be increased, and as a result, in the channel etching production process, the thickness of the channel part can be reduced, whereby both high productivity and good transistor properties can be attained.

The channel part may comprise a crystalline oxide containing indium and one or more positive divalent elements. As the positive divalent element, Zn, Cu, Co, Ni, Mn, Mg, Ca or Sr is preferable, with Zn, Cu, Co, Ni, Mn and Mg being particularly preferable.

The crystalline oxide may be monocrystalline, polycrystalline or microcrystalline. The crystalline oxide is preferably polycrystalline.

It is preferred that the crystalline oxide may have a bixbyite structure of In₂O₃. Further, the crystalline oxide may contain a positive trivalent element and a positive tetravalent element.

In the second aspect of an invention, the channel part may be amorphous or crystalline. The amorphous may include microcrystalline.

Even though the source part and the drain part may be amorphous or crystalline, it is preferred that the nature of amorphous be included. If the quality of amorphous is not included, the work function may become small and the contact resistance with the electrode may become large.

It is preferred that the channel part, and one of the source part and the drain part be amorphous and the other of the source part and the drain part be crystalline in respect of a large etching selection ratio. It is particularly preferable if the channel part is crystalline, and the source/drain parts are amorphous, an etching selection ratio is large, and there is no fear of increasing the contact resistance. Whether parts are crystalline or amorphous can be confirmed by an XRD analysis, and inclusion of microcrystals can be confirmed by a TEM observation of the cross section.

It is preferred that the specific resistance of the channel part be 10⁻¹ to 10⁹ Ωcm, and that the specific resistance of the source part and the drain part be 10⁻⁵ to 10⁻¹ Ωcm. It is more preferred that the specific resistance of the channel part be 10¹ to 10⁸ Ωcm and that the specific resistance of the source part and the drain part be 5×10⁻⁵ to 5×10⁻¹ Ωcm. It is particularly preferred that the specific resistance of the channel part be 10² to 10⁷ Ωcm and the specific resistance of the source part and the drain part be 10⁻⁴ to 10⁻² Ωcm. If the specific resistance of the channel part is smaller than 10⁻¹ Ωcm, the off current may be increased. If the specific resistance of the channel part is larger than 10⁹ Ωcm, the mobility may be lowered or the threshold voltage may become high. If the specific resistance of the source part and the drain part is smaller than 10⁻⁵ Ωcm, the contact resistance may be generated between the channel part and the source part and the drain part. If the specific resistance is larger than 10⁻¹ Ωcm, the contact resistance may be increased.

It is preferred that the carrier density of the channel part be 10¹² to 10¹⁸ cm⁻³ and that the carrier density of the source part and the drain part be 10¹⁸ cm⁻³ to 10²¹ cm⁻³. It is preferred that the carrier density of the channel part be smaller than 2×10¹⁷ cm⁻³. The carrier density of the source/drain parts is more preferably 2×10¹⁸ cm⁻³ to 10²¹ cm⁻³, with 4×10¹⁸ cm⁻³ to 10²¹ cm⁻³ being particularly preferable. If the carrier density of the channel part is larger than 10¹⁸ cm⁻³, the off current may become high or the transistor may become normally-on. If the carrier density of the channel part is smaller than 10¹² cm⁻³, the mobility may be lowered. When the carrier density of the source part and the drain part is smaller than 10¹⁸ cm⁻³, contact resistance may be increased and transistor properties may be deteriorated. When the carrier density of the channel part is larger than 10²¹ cm⁻³, contact resistance may be generated at the contact surface of the channel part, the source part and the drain part.

It is preferred that the work function or the electron affinity of the source/drain parts be 3.0 to 6.0V. The work function can be measured by photoelectric effects or the like. If the work function or the electron affinity is outside the above-mentioned range, the contact resistance with the electrode may be increased.

Normally, the effective S/D serial resistance refers to the total of source or drain contact resistance and the bulk resistance relating to the access region between the contact and the conduction channel, and exerts a large influence on the properties of a transistor. In particular, when the thickness of the semiconductor layer increases, the influence of the effective S/D serial resistance becomes large. In the second aspect of the invention, the reason that the effective S/D serial resistance is decreased is assumed to be a reduction in contact resistance due to improvement in contact with the electrode or is assumed to be a reduction in bulk resistance.

It is preferred that the band gap of the channel part be 2.0 to 6.0 eV, with 2.8 to 5.0 eV being more preferable. If the band gap is smaller than 2.0 eV, the semiconductor layer absorbs visible light to cause a field effect transistor to malfunction. On the other hand, if the band gap is larger than 6.0 eV, the carriers may not be supplied easily, and hence, the field effect transistor may not function.

The surface roughness (RMS) of the channel part is preferably 1 nm or less, further preferably 0.6 nm or less, and particularly preferably 0.3 nm or less. If the surface roughness is larger than 1 nm, the mobility may be lowered.

It is preferred that the channel part be an amorphous film which retains at least part of the edge-sharing structure of the bixbyite structure of indium oxide. Whether the amorphous film containing indium oxide keeps at least part of the edge-sharing structure of the bixbyite structure of indium oxide can be confirmed by the presence of a peak derived from In—X (X is In, Zn) between 0.30 to 0.36 nm by using a radial distribution function (RDF) obtained by grazing incidence X-ray scattering (GIXS) conducted by using high-luminance synchrotron radiation or the like. For details, reference can be made to the following documents.

F. Utsuno, et al., Thin Solid Films, Volume 496, 2006, Pages 95 to 98.

Further, if the maximum value of RDF with an interatomic distance of 0.30 to 0.36 nm is taken as A and the maximum value of RDF with an interatomic distance of 0.36 to 0.42 is taken as B, it is preferred that the relationship A/B>0.70 be satisfied. The A/B>0.85 is more preferable, and A/B>1 is still more preferable, with the A/B>1.2 being particularly preferable. If the A/B is 0.70 or less, when the semiconductor oxide is used as the channel part of a transistor, the mobility may be lowered, the threshold value or the S value may be too large. A small A/B appears to be caused by a poor short range order of the amorphous film.

It is preferred that the average In—In bonding distance be 0.300 to 0.322 nm, with 0.310 to 0.320 nm being particularly preferable. The average In—In bonding distance can be obtained by an X-ray absorption spectroscopy. In the measurement by an X-ray absorption spectroscopy, an extended X-ray absorption fine structure (EXAFS) extending to an energy higher by several hundreds eV from the rising edge is shown. The EXAFS is caused by backward scattering of electrons by atoms surrounding excited atoms. An interference of a wave of electrons which are jumped out and a wave of electrons which are scattered backwardly occurs. The interference depends on the wavelength in an electron state and the light path in which electrons move to surrounding atoms. A radial distribution function (RDF) can be obtained by Fourier transforming EXAFS. The average bonding distance can be estimated from the peak of RDF.

In the second aspect of the invention, it is preferred that the channel part be an amorphous film and have an energy width (E₀) on the non-localized level of 14 meV or less. The energy width (E₀) on the non-localized level of the channel part is more preferably 10 meV or less, further preferably 8 meV or less, and particularly preferably 6 meV or less.

If the energy width (E₀) on the non-localized level of the channel part exceeds 14 meV, the mobility may be lowered or the threshold value and the S value may be too large when the oxide semiconductor is used as the channel part of a transistor. A large energy width (E₀) on the non-localized level of the channel part appears to be caused by a poor short range order of the amorphous film.

The thickness of the channel part is normally 1 to 500 nm, preferably 5 to 200 nm, more preferably 10 to 150 nm, and particularly preferably 20 to 120 nm. If the thickness is smaller than 1 nm, it is difficult to conduct film formation uniformly on the industrial scale. If the thickness is larger than 500 nm, the mobility may be lowered and the film forming time is prolonged, resulting in difficulty in industrial application. If the thickness is within a range of 20 to 120 nm, TFT properties such as mobility and on-off ratio are particularly excellent.

The thickness of the source or drain part is normally 1 to 300 nm, preferably 3 to 150 nm, more preferably 5 to 100 nm, and particularly preferably 10 to 80 nm. If the thickness is smaller than 1 nm, the effective S/D serial resistance may be increased. If the thickness is larger than 300 nm, the mobility may be lowered.

### 3. Protective Layer of the Channel Part

It is preferred that the field effect transistor have a protective layer for the channel part. If the channel part has no protective layer, oxygen in the surface layer of the semiconductor layer may be withdrawn in vacuum or at a lower pressure, resulting in a higher off current and a negative threshold voltage. Without the protective layer, even in the air, transistor properties such as threshold voltage may vary largely due to the influence caused by the surrounding environment such as moisture. The protective film may also serve as an etching stopper.

There are no particular restrictions on the material for forming the protective film. Materials which are commonly used can be selected arbitrarily as far as the advantageous effects of the invention are not impaired For example, SiO₂, SiNx, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, AlN or the like may be used. Of these, SiO₂, SiNx, Al₂O₃, Y₂O₃, Hf₂O₃ and CaHfO₃ are preferably used, with SiO₂, SiNx, Y₂O₃, Hf₂O₃ and CaHfO₃ being more preferable. Oxides such as SiO₂, Y₂O₃, Hf₂O₃ and CaHfO₃ are particularly preferable. The oxide number of these oxides and the nitrogen number of these nitrides may not necessarily coincide with the stoichiometrical ratio (for example, they may be SiO₂ or SiOx, and x is larger than 0.1 and smaller than 10). SiNx may contain a hydrogen element.

Such a protective film may be a stack structure in which two or more different insulating films are stacked.

The protective layer may be crystalline, polycrystalline or amorphous. It is preferred that the layer be polycrystalline or amorphous since it can be produced easily on the industrial scale. In particular, it is preferred that the protective layer be amorphous. If it is not an amorphous film, the smoothness of an interface may be poor, and hence, the mobility may be lowered, the threshold voltage or the S value may be too large.

It is preferred that the protective layer of the channel part be an amorphous oxide or an amorphous nitride, with an amorphous oxide being particularly preferable. If the protective layer is not an oxide, oxygen in the semiconductor moves toward the protective layer, and as a result, the off current may be increased or the threshold voltage may be negative to cause the transistor to be normally-on.

An organic insulating film such as poly(4-vinylphenol)(PVP) or parylene may be used in the protective layer of the channel part. Further, the protective layer may have a stack structure in which an inorganic insulating film and an organic insulating film are stacked in two or more.

### 4. Gate Insulating Film

There are no particular restrictions on the material for forming the gate insulating film. Materials which are commonly used can be selected arbitrarily as far as the advantageous effects of the invention are not impaired. For example, SiO₂, SiNx, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆, SrTiO₃, AlN or the like may be used. Of these, it is preferable to use SiO₂, SiNx, Al₂O₃, Y₂O₃, Hf₂O₃, CaHfO₃, with SiO₂, SiNx, Y₂O₃, Hf₂O₃ and CaHfO₃ being more preferable. The oxide number of these oxides or the nitrogen number of these nitrides may not necessarily coincide with the stoichiometrical ratio (for example, they may be SiO₂ or SiOx, or SiN or SiNx, x is larger than 0.1 and smaller than 10). SiNx may contain a hydrogen element.

The gate insulating film may be a stack structure in which two or more different insulating films are stacked. The gate insulating film, may be crystalline, polycrystalline or amorphous. It is preferred that the gate insulating film be polycrystalline or amorphous since it can be produced easily on the industrial scale.

An organic insulating film such as poly(4-vinylphenol)(PVP) or parylene may be used in the gate insulating film. Further, the gate insulating film may have a stack structure in which an inorganic insulating film and an organic insulating film are stacked in two or more.

### 5. Electrode

There are no particular restrictions on the material for forming each of the gate electrode, the source electrode and the drain electrode. Materials which are commonly used can be selected arbitrarily as far as the advantageous effects of the invention are not impaired, for example, one selected from Ti, Pt, Cr, W, Al, Ni, Cu, Mo, Ta, Au and Nb, and alloys containing these.

Two or more of these layers may be stacked. It is preferable to decrease the contact resistance or to improve the interfacial strength by stacking these layers.

The contact resistance of the source part and the source electrode and/or the drain part and the drain electrode (R_{SD}W) is preferably 180 Ωcm or less, more preferably 100 Ωcm or less, and further preferably 50 Ωcm and particularly preferably 20 Ωcm. If the contact resistance is larger than 200 Ωcm, the mobility or the on-off ratio may be lowered, resulting in an increase in S value or threshold voltage. The contact resistance (R_{SD}W) can be measured by a method described in Non-Patent Document 2 or the like.

The mobility of the field effect transistor of the invention preferably is 1 cm²/Vs or more, more preferably 3 cm²/Vs or more and particularly preferably 8 cm²/Vs or more. If the mobility is smaller than 1 cm²/Vs, the switching speed may be too slow to be used in a large-area, high-precision display.

The on-off ratio is preferably 10⁶ or more, more preferably 10⁷ or more and particularly preferably 10⁸ or more.

The off current is preferably 2 pA or less, more preferably 1 pA or less. If the off current is larger than 2 pA, if used as a TFT in a display, contrast may be poor or the uniformity of the screen may be deteriorated.

The gate leakage current is preferably 1 pA or less. If the gate leakage current is larger than 1 pA, if used as a TFT in a display, contrast may be poor.

The threshold voltage is normally −2 to 10 V, preferably −1 to 4 V, more preferably −0.5 to 3 V, with 0 to 2 V being particularly preferable. If the threshold voltage is smaller than −2 V, the transistor may become normally-on, and as result, it may be required to apply a voltage when the transistor is in the off state, resulting in an increased consumption power. If the threshold voltage is larger than 10 V, the driving voltage may be increased, and as a result, the consumption power may be increased or a high mobility may be required.

The S value is preferably 8 V/dec or less, more preferably 0.3 V/dec or less, further preferably 0.25 V/dec or less and particularly preferably 0.2 V/dec or less. If the S value is larger than 0.8 V/dec, the driving voltage may be increased, resulting in an increase in consumption power. In particular, when used in an organic EL display which is driven by DC current, it is preferable to suppress the S value to 0.3 V/dec or less since the consumption power can be significantly decreased.

The S value (Swing Factor) is a value indicating the sharpness of the rising of the drain current from the off-state to the on-state when the gate voltage is increased from the off-state. As shown by the following formula, the S value is an increase in gate voltage when the drain current is increase by one digit (10 times).

S value=dVg/d log(Ids)

A smaller S value means a sharp rising (“Thin Film Transistor Technology”, by Ukai Yasuhiro, 2007, published by Kogyo Chosakai Publishing, Inc.)

When the S value is large, a high gate voltage is required to be applied when switching from the on-state to the off-state, which may result in an increased consumption power.

The shift amount in threshold voltage before and after the application of a direct voltage of 10 μA at 50° C. for 100 hours is preferably 1.0 V or less, more preferably 0.5 V or less. If the shift amount exceeds 1 V, the image quality may be deteriorated when used in a transistor of an organic EL display.

It is preferred that hysteresis when the gate voltage is increased or decreased in a transmission curve be small.

The ratio (W/L) of the channel width W and the channel length L is normally 0.1 to 100, preferably 0.5 to 20 and particularly preferably 1 to 8. If the W/L exceeds 100, the current leakage may be increased or the on-off ratio may be decreased. If the W/L is smaller than 0.1, the field effect mobility may be lowered or the pinch off may be unclear.

Further, the channel length L is normally 0.1 to 1000 μm, preferably 0.2 to 100 μm, further preferably 0.5 to 10 μm, with 1 to 5 μm being particularly preferable. If the channel length is less than 0.1 μm, it is difficult to produce the transistor on the industrial scale, and the current leakage may be increased. A channel length exceeding 1000 μm is not preferable since it makes the device too large in size.

It is preferred that the field effect transistor according to the second aspect of the invention have a structure capable of shielding the channel part from light. If it does not have a structure capable of shielding the channel part from light (light-shielding layer), carrier electrons may be excited when light is incident on the channel part, resulting in an increased off current. The light-shielding layer may be a thin film having a large absorption at a wavelength of 300 to 800 nm. The light-shielding layer may be positioned above or below the channel part. However, it is preferred that the light-shielding layer be provided both above and below the channel part. The gate insulating film, a black matrix or the like may be used as the light-shielding layer. If the light-shielding layer is provided on only either above or below, it is preferable to contrive the structure in order not to allow light to be incident on the channel part from the side on which no light-shielding layer is provided.

In the field effect transistor according to the second aspect of the invention, it is preferred that an oxide resistant layer having a higher resistance than that of the channel part be formed between the channel part and the gate insulating film and/or between the channel part and the protective layer. Without an oxide resistant layer, an off current may be generated, the threshold voltage may become negative to allow the transistor to be normally on, or the channel part may be denatured during the formation of the protective film or during post treatments such as etching.

The following can be exemplified as the oxide resistant layer:

An amorphous oxide film having the same composition as that of the channel part which is formed at an oxygen partial pressure which is higher than that during the formation of a channel part

An amorphous oxide film having the same composition as that of the channel part but having a different composition ratio

An amorphous oxide film containing In and Zn, and an element X different from that contained in the channel part

A polycrystalline oxide film comprising indium as a main component

A polycrystalline oxide film comprising indium oxide as a main component which is doped with one or more positive divalent elements such as Zn, Cu, Co, Ni, Mn and Mg

In the case of the amorphous oxide film having the same composition as that of the channel part but having a different composition ratio or the amorphous oxide film containing In and Zn, and an element X different from that contained in the channel part, it is preferred that the In composition ratio be smaller than that in the channel part. Also it is preferred that the composition ratio of the element X be larger than that in the channel part.

It is preferred that the oxide resistant layer be an oxide which contains each of In and Zn: If the oxide resistant layer does not contain In and Zn, move of elements may occur between the oxide-resistant layer and the channel part, and a shift in threshold voltage may be increased when a stress test or the like is conducted.

Next, an explanation is made on the method for producing the field effect transistor according to the second aspect of the invention.

The method for producing the field effect transistor according to the second aspect of the invention is characterized in that a film as a channel part is formed, a film as a source part and a drain part is formed, and after the above-mentioned two film-forming steps, a heat treatment is conducted at a temperature higher than the film-forming temperature.

By conducting a heat treatment at a temperature higher than the film-forming temperature after the film-forming steps, the high-resistant layer formed between the channel part and the source/drain parts by absorption of moisture, oxygen or the like disappears, whereby transistor properties are improved.

In the second aspect of the invention, it is preferred that, between the step of forming the channel part and the step of forming the source part and the drain part, an object to be treated be not exposed to air.

If an object to be treated is exposed to air between the step of forming the channel part and the step of forming the source part and the drain part, moisture, oxygen, organic substances or the like are absorbed on the channel part or the surface of the source part and the drain part, a high-resistant layer is formed, thereby to deteriorate the transistor properties.

It is preferred that the channel part, the source part and drain part be formed by sputtering targets which differ in composition or composition ratio.

In order to allow the channel part, the source part and the drain part to have different compositions, the following methods can be used. The channel part and the source part and the drain part may be formed by co-sputtering or reactive sputtering using the same target. The channel part, the source part and the drain part may be separately formed by using targets differing in composition or composition ratio. In order to attain uniform film formation of a large area, it is preferable to form separately a channel part and a source and a drain part using a sputtering target differing in composition or composition ratio.

Each of the constituting elements (layer) of the above-mentioned field effect transistor can be formed by a technique which is known in the art.

Specifically, as the film forming method, chemical film forming methods such as the spray method, the dipping method and the CVD method, or physical film forming methods such as the vacuum vapor deposition method, the ion plating method and the pulse laser deposition method can be used. In respect of easiness in controlling the carrier density and easiness in improving film quality, it is preferable to use a physical film forming method. More preferably, the sputtering method is used due to its high productivity.

In the sputtering, it is possible to use a method in which a sintered target of a composite oxide is used, a method in which co-sputtering is conducted by using a plurality of sintered targets and a method in which reactive sputtering is conducted by using an alloy target. In the method where co-sputtering is conducted by using a plurality of sintered targets or in the method where reactive sputtering is conducted by using an alloy target, problems such as deterioration of uniformity or reproducibility and an increased energy width (E₀) on the non-localized level may occur, and as a result, deterioration of transistor properties such as a decrease in mobility or an increase in threshold voltage may occur. Preferably, a sintered target formed of a composite oxide is used.

The source part and the drain part may be formed separately from the channel part, or the source part and the drain part may be formed by adding elements or the like to the channel part, thereby to change the composition of thereof. The channel may be formed separately from the source part and the drain part. The channel part may be formed by adding elements or the like to the source/drain parts, thereby to change the composition thereof.

The films thus formed can be patterned by various etching methods.

As for etching, dry etching and wet etching may be used freely. In respect of productivity, wet etching is preferable.

In the wet etching, it is preferable to use an etchant based on oxalic acid, PAN, CAN or the like.

Dry etching can be conducted in an atmosphere of a gas containing a fluorine-based gas or hydrocarbon. It is preferable to conduct dry etching in a gas atmosphere containing hydrocarbon since the etching speed can be increased.

In the second aspect of the invention, it is preferable to form an oxide semiconductor by RF, DC or AC sputtering. By using DC or AC sputtering, as compared with the case of RF sputtering, damage during film formation can be decreased. Therefore, in the field effect transistor, advantageous effects such as suppression in threshold voltage shift, improvement in mobility, a decrease in threshold voltage, a reduction in S value can be expected.

In the second aspect of the invention, after the formation of the source part, the drain part and the channel part, a heat treatment is conducted at a temperature higher than the film forming temperature. The film forming temperature is normally 150° C. or less. In the invention, a heat treatment is conducted at 70 to 350° C. If the heat treatment temperature is lower than 70° C., stability or resistance to heat of the resulting transistor may be lowered, the mobility may be lowered, the S value may be increased and the threshold voltage may be increased. On the other hand, if the heat treatment temperature is higher than 350° C., a substrate which does not have heat resistance may not be used or the equipment cost for the heat treatment may be incurred.

The heat treatment temperature is preferably 80 to 260° C., more preferably 90 to 180° C., and particularly preferably 100 to 150° C. In particular, a heat treatment temperature of equal to or lower than 180° C. is preferable, since a resin substrate with a low heat resistance such as PEN can be used as a substrate.

Although a heat treatment is conducted preferably normally for 1 second to 24 hours, it is preferable to adjust the heat treatment time according to the treatment temperature. For example, at a heat treatment temperature of 70 to 180° C., the heat treatment time is preferably 10 minutes to 24 hours, more preferably 20 minutes to 6 hours, and particularly preferably 30 minutes to 3 hours. At a heat treatment temperature of 180 to 260° C., the heat treatment time is more preferably 6 minutes to 4 hours, further preferably 15 minutes to 2 hours. At a heat treatment temperature of 260 to 300° C., the heat treatment time is more preferably 30 seconds to 4 hours, and particularly preferably 1 minute to 2 hours. At a heat treatment temperature of 300 to 350° C., the heat treatment time is more preferably 1 second to 1 hour, particularly preferably 2 seconds to 30 minutes.

It is preferred that the heat treatment be conducted in an environment where an oxygen partial pressure is 10⁻³ Pa or less in an inert gas or be conducted after the channel part is covered by the protective layer. By this, the reproducibility of the production is improved.

### EXAMPLES

### Experimental Example 1

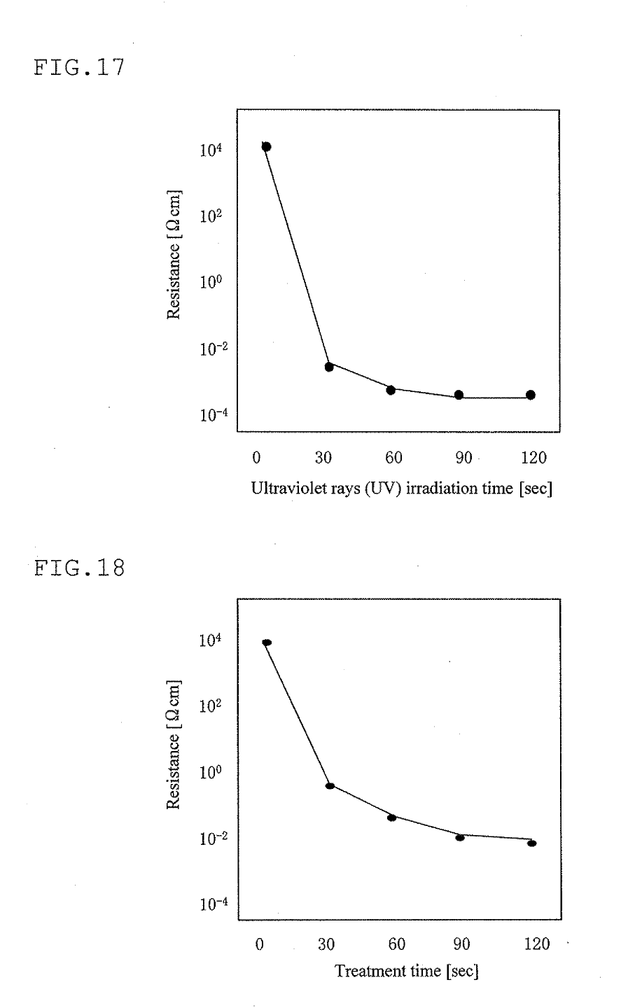

An oxide film with a specific resistance of 10⁴ Ωcm was irradiated with UV rays in a low oxygen partial pressure environment (total pressure: 10⁻⁵ Pa, oxygen partial pressure <10⁻⁶ Pa), thereby to lower the resistance thereof. The relationship between the irradiation time (treatment time) and the resistance was evaluated. The measurement results are shown in FIG. 17. By AES, it was confirmed that the oxygen concentration was decreased by the irradiation of UV rays.

### Experimental Example 2

An oxide film with a specific resistance of 10⁴ Ωcm was subjected to an argon plasma treatment, thereby to lower the resistance thereof. The relationship between the irradiation time (treatment time) and the resistance was evaluated. The measurement results are shown in FIG. 18. By AES, it was confirmed that the oxygen concentration was decreased by the argon plasma treatment.

### Experimental Example 3

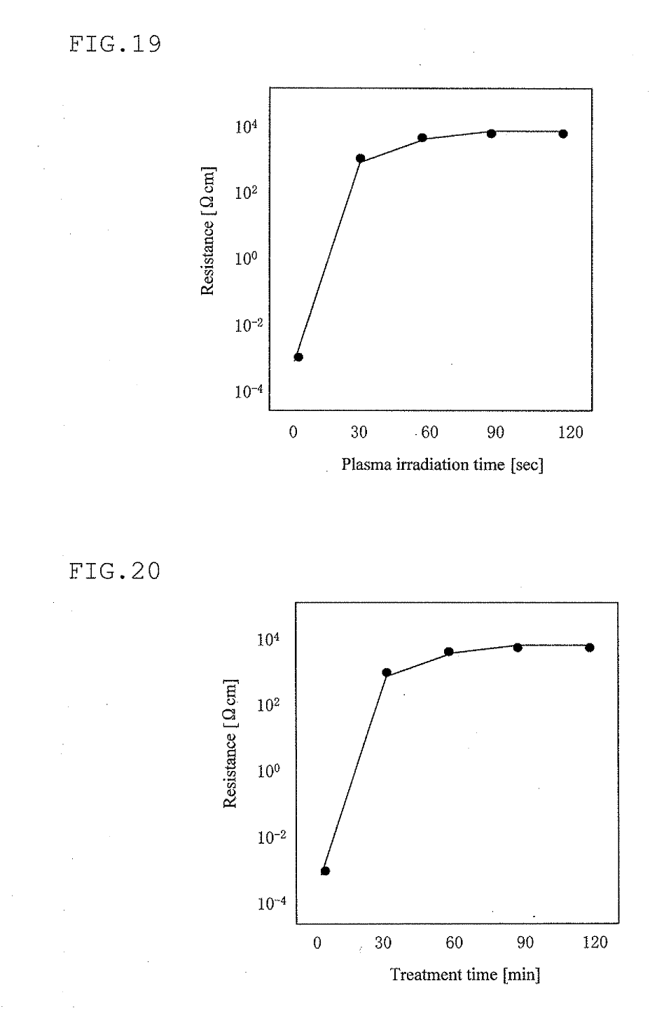

An oxide film with a specific resistance of 10⁻³ Ωcm was subjected to an oxygen plasma treatment, thereby to increase the resistance thereof. The relationship between the irradiation time (treatment time) and the resistance was evaluated. The measurement results are shown in FIG. 19. By AES, it was confirmed that the oxygen concentration was increased by the oxygen plasma treatment.

### Experimental Example 4

An oxide film with a specific resistance of 10⁻³ cm was subjected to an ozone treatment (oxygen partial pressure: 7.5×10⁴ Pa), thereby to increase the resistance thereof. The relationship between the irradiation time (treatment time) and the resistance was evaluated. The measurement results are shown in FIG. 20. By AES, it was confirmed that the oxygen concentration was increased by the ozone treatment

### Example 1

The powder of indium oxide, zinc oxide and zirconium oxide were mixed such that the atomic ratio [In/(In+Zn+Zr)] became 0.48, the atomic ratio [Zn/(In+Zn+Zr)] became 0.50 and the atomic ratio [Zr/(In+Zn+Zr)] became 0.02. The mixture was supplied to a wet type ball mill and pulverized and mixed for 72 hours to obtain raw material fine powder.

The resulting raw material fine powder was granulated, and press-molded into a size of 10 cm in diameter and 5 mm in thickness. The molded product was put in a firing furnace, and fired at 1500° C. for 12 hours, whereby a sintered body (target) was obtained.

The bulk resistance of the resulting target was 3 mΩ and the density was 0.99. The target thus formed had uniform appearance with no unevenness in color.

The sputtering target thus obtained was installed in a DC magnetron sputtering film forming apparatus, and a transparent conductive film (oxide film) was formed on a glass substrate (Corning 1737) in a thickness of 70 nm.

The composition of the resulting film was analyzed by the ICP method, and it was found that the atomic ratio [In/(In+Zn+Zr)] was 0.49, the atomic ratio [Zn/(In+Zn+Zr)] was 0.49 and the atomic ratio [Zr/(In+Zn+Zr)] was 0.02.

The sputtering conditions of this oxide film were as follows:

Substrate temperature: 25° C.

Ultimate pressure: about 1×10⁻⁶ Pa

Atmospheric gas: Ar 99.5% and oxygen 0.5%

Sputtering pressure (total pressure): about 2×10⁻¹ Pa

Input power: 100 W

Film forming time: 7 minutes

S-T distance 1: 90 mm

The oxide film was heat treated at 270° C. for 2 hours in a nitrogen environment, thereby forming a transparent semiconductor thin film.

The carrier concentration and the hall mobility of the resulting semiconductor thin film were measured by means of a hall measurement apparatus. As a result, it was found that the transparent semiconductor thin film was of n-type, had a carrier concentration of 4×10¹⁷ cm⁻³, a hall mobility of 2 cm²/Vs and an energy band gap of 3.7 eV, which were sufficiently large.

The hall measurement apparatus and the measurement conditions thereof were as follows.

### [Hall Measurement Apparatus]

Resi Test 8310, manufactured by Toyo Technica Co., Ltd.

### [Measurement Conditions]

Room temperature (25° C.)

0.5 [T]

10⁻⁴ A to 10⁻¹²

AC magnetic field hall measurement

The resulting transparent semiconductor thin film was subjected to an X-ray crystal structure analysis, and it was confirmed that the transparent semiconductor thin film was amorphous. The surface roughness RMS of the resulting transparent semiconductor thin film measured by AMF (Atomic Force Microscope) was 0.2 nm. The band gap optically obtained of the resulting transparent semiconductor thin film was 3.8 eV.

Further, for the transparent semiconductor thin film thus obtained, the hall effect was measured by changing the measurement temperature in a range of 77 to 300K. As a result, it was found that film was a non-degenerate semiconductor showing a thermal activation-type behavior. From the relationship between the activation energy and the carrier concentration measured by using hall effect while changing the temperature, the energy width (E₀) on the non-localized level was found to be 6 meV or less.

Further, a radial distribution function (RDF) was obtained for the resulting semiconductor thin film was measured by an X-ray scattering measurement, a peak showing In—In was observed at around 0.35 nm, and it was confirmed that the edge-sharing structure of the bixbyite structure of indium oxide remained. The A/B when the maximum RDF value with an interatomic distance of 0.30 to 0.36 nm was taken as A and the maximum value of RDF with an interatomic distance of 0.36 to 0.42 was taken as B was found to be 1.3. The average In—In bonding distance obtained by the X-ray absorption spectroscopy was 0.318 nm.

Using this transparent semiconductor thin film, a transistor (channel width W=20 μm, channel length L=10 μm) was produced in the method according to the following embodiment 1.

On the supporting substrate 10, the gate electrode 20 formed of Mo was formed in a thickness of 100 nm (FIG. 2(A)). The gate insulating film 30 composed of SiNx:H was formed in a thickness of 200 nm so as to cover the gate electrode 20. On the gate insulating film 30 the thus formed, the semiconductor layer 40 with a thickness of 70 nm and the resist 70 were stacked by the above-mentioned method (FIG. 2(B)). For this stack, light exposure from the direction of the supporting substrate 10 and removal of the resist were conducted, whereby the resist 70 was patterned into a desired shape (FIG. 2(C), FIG. 2(D) and FIG. 2(E)). The stack in which the resist 70 had been patterned was then irradiated with UV rays for 60 minutes by means of a ultra high-pressure mercury lamp in a nitrogen atmosphere with an oxygen partial pressure of 10⁻³ Pa or less from the direction of the semiconductor layer to reduce the resistance of part of the semiconductor layer, whereby the channel part 42 and the source/drain parts 44 were formed in the semiconductor layer 40 (FIG. 2(F)). After forming the channel part 42 and the source/drain parts 44, the resist 70 which had been patterned was removed (FIG. 2(G)), whereby the protective layer 50 and the source/drain electrodes 60 were formed on the semiconductor layer 40 to obtain the field effect transistor 2 (FIG. 2(H)).

The resulting transistor was analyzed by XRF (X-ray fluorescence) and ICP (inductively coupled plasma), and it was confirmed that the channel part and the source part and the drain part had the same composition ratio except oxygen and an inert gas. Further, by RBS (rutherford backscattering spectrometry) and Auger electron spectroscopy, it was confirmed that the oxygen content in the channel part was larger than that in the source part and the drain part.

### Example 2

The powder of indium oxide, zinc oxide and aluminum oxide were mixed such that the atomic ratio [In/(In+Zn+Al)] became 0.58, the atomic ratio [Zn/(In+Zn+Al)] became 0.40 and the atomic ratio [Al/(In+Zn+Al)] became 0.02. The mixture was supplied to a wet type ball mill and pulverized and mixed for 72 hours to obtain raw material fine powder.

The resulting raw material fine powder was granulated, and press-molded into a size of 10 cm in diameter and 5 mm in thickness. The molded product was put in a firing furnace, and fired at 1500° C. for 12 hours, whereby a sintered body (target) was obtained.

The bulk resistance of the resulting target was 2 mΩ and the density was 0.99. The target thus formed had uniform appearance with no unevenness in color.

The sputtering target thus obtained was installed in a DC magnetron sputtering film forming apparatus, and a transparent conductive film (oxide film) was formed on a glass substrate (Corning 1737) in a thickness of 70 nm.

The composition of the resulting oxide film was analyzed by the ICP method, and it was found that the atomic ratio [In/(In+Zn+Al)] was 0.59, the atomic ratio [Zn/(In+Zn+Al)] was 0.39 and the atomic ratio [Zr/(In+Zn+Al)] was 0.02.

The sputtering conditions of this oxide film were as follows:

Substrate temperature: 25° C.

Ultimate pressure: 1×10⁻⁶ Pa

Atmospheric gas: Ar 100%

Sputtering pressure (total pressure): 1×10⁻¹ Pa

Input power: 100 W

Film forming time: 7 minutes

S-T distance 1: 90 mm

The resulting conductive film (oxide film) was analyzed by XRD, and it was confirmed that the conductive film was amorphous. The carrier concentration and the hall mobility of this conductive film were measured by the hall measurement apparatus. As a result, it was found that the conductive film was of n-type, had a carrier concentration of 2×20²⁰ cm⁻³, a hall mobility of 40 cm²/Vs and an energy band gap of 3.6 eV, which was sufficiently large.

Using this conductive film, a transistor (channel width W=20 μm, channel length L=10 μm) was produced by the method according to the following embodiment 3.

On the supporting substrate 10, the gate electrode 20 formed of Mo was formed in a thickness of 100 nm (FIG. 4(A)). The gate insulating film 30 composed of SiNx:H was formed in a thickness of 200 nm so as to cover the gate electrode 20. On the gate insulating film 30 thus formed, the above-mentioned conductive film (oxide film) layer 40 with a thickness of 70 nm and the resist 70 were stacked (FIG. 4(B)). For this stack, light exposure from the direction of the supporting substrate 10 and removal of the resist are conducted, whereby the resist 70 was patterned into a desired shape (FIG. 4(C), FIG. 4(D) and FIG. 4(E)). The stack in which the resist 70 has been patterned was then subjected to an oxygen plasma treatment by exposing for 10 minutes to an oxygen plasma generated at a wavelength of 13.56 MHz, an amplification power of 500 W and an oxygen pressure of 330 Pa from the direction of the conductive film (oxide film) to increase the resistance of part of the transparent conductive film (oxide film) of the stack, whereby the channel part 42 and the source/drain parts 44 were formed in the conductive film (oxide film) 40 (FIG. 4(F)). The patterned resist 70 was removed (FIG. 4(G)), the protective layer 50 and the source/drain electrodes 60 were formed on the semiconductor layer 40 to form a field effect transistor 4 (FIG. 4(H)).

The resulting transistor was analyzed by XRF (X-ray fluorescence) and ICP (inductively coupled plasma), and it was confirmed that the channel part and the source part and the drain part had the same composition ratio except oxygen and an inert gas.

Further, by RBS (rutherford backscattering spectrometry) and Auger electron spectroscopy, it was confirmed that the oxygen content in the channel part was larger than that in the source part and the drain part.

### Example 3

A transistor was formed in the same manner as in Example 1, except that a protective film made of SiO₂ (film thickness: 50 nm) was formed on the semiconductor layer.

The resulting transistor was analyzed by XRF (X-ray fluorescence) and ICP (inductively coupled plasma), and it was confirmed that the channel part and the source/drain parts had the same composition ratio except oxygen and an inert gas.

Further, by RBS (rutherford backscattering spectrometry) and Auger electron spectroscopy, it was confirmed that the oxygen content in the channel part was larger than that in the source part and the drain part.

### Example 4

A transistor (channel width W=20 μm, channel length L=10 μm) was produced by the method according to Embodiment 6 using the conductive film (oxide film) formed by the same method as in Example 2.

On the supporting substrate 10 composed of a glass substrate which was protected by an SiO₂ film formed by CVD, the same conductive film (oxide film) 40 as in Example 2, the gate insulating film 30 formed of SiO₂ and the gate electrode 20 formed of Mo were sequentially stacked (FIG. 7(A)). The gate electrode 20 of this stack was heated by means of an infrared lamp (FIG. 7(B)), whereby the channel part 42 and the source part and the drain part 44 were formed in the semiconductor layer 40 (FIG. 7(C)). Subsequently, the gate insulating film 30 was etched to form the contact holes 90, and the source/drain electrodes 60 were formed so that the contact holes 90 were embedded by these electrodes, whereby a field effect transistor 7 was obtained (FIG. 7(E)).

### Example 5

A field effect transistor was prepared in the same manner as in Example 4, except that an Xe lamp was used instead of an infrared lamp for heating the gate electrode.

### Example 6

A field effect transistor was prepared in the same manner as in Example 4, except that a semiconductor laser was used instead of an infrared lamp for heating the gate electrode.

### Example 7

A sputtering target with an atomic ratio [In/(In+Zn+Ga)] of 0.46, an atomic ratio [Zn/(In+Zn+Ga)] of 0.48 and an atomic ratio [Ga/(In+Zn+Ga)] of 0.06 was prepared in the same manner as in Example 1, and a conductive film (oxide film) was formed in the same manner as in Example 1. Using this conductive film (oxide film), a field effect transistor was prepared in the same manner as in Example 1.

### Example 8

A sputtering target with an atomic ratio [In/(In+Zn+Ga)] of 0.50, an atomic ratio [Zn/(In+Zn+Ga)] of 0.25 and an atomic ratio [Ga/(In+Zn+Ga)] of 0.25 was prepared in the same manner as in Example 1, and a conductive film (oxide film) was formed in the same manner as in Example 1. Using this conductive film (oxide film), a field effect transistor was prepared in the same manner as in Example 1.

### Example 9

A sputtering target with an atomic ratio [In/(In+Zn+Ga)] of 0.50, an atomic ratio [Zn/(In+Zn+Ga)] of 0.25 and an atomic ratio [Ga/(In+Zn+Ga)] of 0.25 was prepared in the same manner as in Example 1, and a conductive film was formed in the same manner as in Example 1.

A transistor (channel width W=20 μm, channel length L=10 μm) was produced by the method according to the following Embodiment 7 using the conductive film (oxide film).

On the supporting substrate 10, the gate electrode 20 formed of Mo was formed in a thickness of 100 nm (FIG. 8(A)). Then, the gate insulating film 30 formed of SiO₂ was formed in a thickness of 200 nm so as to cover the gate electrode 20. On the gate insulating film 30 thus formed, the above-mentioned semiconductor layer 40 with a thickness of 70 nm, the protective film 80 formed of SiO₂ and the resist 70 were stacked by the above-mentioned method (FIG. 8(B)). For this stack, light exposure from the direction of the supporting substrate 10 and removal of the resist were conducted, whereby the resist 70 was patterned into a desired shape (FIG. 8(C), FIG. 8(D) and FIG. 2(E)). The protective film 80 was etched in a desired shape and the resist 70 was removed (FIG. 8(F)). On the etched protective film 80, the protective layer 50 composed of SiNx:H was stacked by PECVD and, simultaneously, the resistance of part of the semiconductor layer was reduced, whereby the channel part 42 and the source/drain parts 44 were formed in the semiconductor layer 40 (FIG. 8(G)). On the source/drain parts 44, the source/drain electrodes 60 were formed through the contact holes to obtain the field effect transistor 8 (FIG. 8(H)).

### Comparative Example 1

A transistor was formed in the same manner as in Example 1, except that hydrogen ion injection was conducted instead of UV irradiation.

### Comparative Example 2

A transistor was formed in the same manner as in Example 1, except that UV irradiation was not conducted.

For the transistors produced in Examples 1 to 9 and Comparative Examples 1 and 2, the following evaluations were conducted. The results are shown in Tables 1 and 2.

### (1) Mobility and Off Current

Using a semiconductor parameter analyzer (Keithley 4200), the mobility, the hysteresis of the transmission curve and the off current were measured at room temperature and in the light-shielded environment.

### (2) Variation in Current Value

A variation in on current Ion (σ/average value of Ion) of adjacent 16 transistors was measured at plural points of the substrate by a semiconductor parameter analyzer, and the average was taken as the variation of the current value.

### (3) Shift Amount in Threshold Voltage

A voltage of 15V was applied to a gate electrode, and a change in threshold voltage when the transistor was driven for 24 hours at 50° C. was measured by a semiconductor parameter analyzer and taken as the shift amount in threshold voltage.

### (4) Hydrogen Concentration

The hydrogen concentration of the channel part and the source/drain parts of the semiconductor layer were measured by SIMS. As a result of the measurement, the semiconductor layer of which the high-oxygen-concentration part has a hydrogen concentration of less than 10 times that in the low-oxygen-concentration part was evaluated as “uniform” (almost the same), and the semiconductor layer of which the high-oxygen-concentration part has a hydrogen concentration of equal to or larger than 10 times that in the low-oxygen-concentration part was evaluated as “non-uniform” (not almost the same).

In the measurement of hydrogen concentration by SIMS, the measurement accuracy was enhanced by preparing a hydrogen standard sample. This hydrogen standard sample was a hydrogen standard sample in an ultrathin silicon insulating film, and was prepared as an ultrathin oxide film containing deutrium at a known concentration. This method has advantages that deutrium with a fixed concentration can be mixed in an ultrathin silicon oxide film by conducting wet oxidization of silicon crystals using a raw material gas containing an isotope of hydrogen (deutrium) which has the same chemical properties as hydrogen, and determination of the deutrium concentration of an ultrathin silicon oxide film can be conducted without the fear of contaminating the surface of a sample containing hydrogen (deutrium) by utilizing an elastic recoil detection analysis (ERDA) of a high-speed ion beam or a nuclear reaction technology of an isotope of helium with a mass number of 3 (³He), or the like. As a result, as a hydrogen standard sample in an ultrathin silicon insulating film, an ultrathin oxide film containing deutrium with a known concentration could be prepared.

The measurement of the hydrogen concentration was also conducted by HFS (hydrogen forward scattering spectrometry), the same results were obtained for uniformity and un-uniformity.

### (5) State of the Channel Part and the Source/Drain Part

The oxide semiconductor which is a non-degenerate semiconductor refers to an oxide semiconductor of which the temperature characteristics of conductivity show thermal activation type behavior and the conductivity has a large dependency on temperature. On the other hand, an oxide semiconductor which is a degenerate semiconductor refers to an oxide semiconductor of which the temperature characteristics of mobility or conductivity does not show thermal activation type behavior and the mobility or conductivity has a small dependency of temperature.

Whether an oxide semiconductor is a non-degenerated semiconductor or a degenerate semiconductor can be judged by measuring the temperature dependency of mobility or conductivity. An oxide semiconductor having an activation energy obtained from the temperature dependency of the mobility or conductivity of 25 meV or more was judged as the non-degenerate semiconductor, and one with an activation energy of less than 25 meV was judged as the degenerate semiconductor.

Here, the activation energy is the activation energy of the oxide semiconductor film obtained from the slope of the straight line of the Arrhenius plot of conductivity.

The temperature dependency of the mobility was measured by the hall measurement apparatus. The hall measurement apparatus and the measurement conditions thereof were as follows.

Hall Measurement Apparatus

Resi Test 8310, manufactured by Toyo Technica Co., Ltd.

Measurement Conditions

Measurement temperature: Room temperature (77 to 300K)

Magnetic field for measurement: 0.5 T

Current for measurement: 10⁻¹² to 10⁻⁴ A

Measurement mode: AC magnetic field hall measurement

TABLE 1

| | Examples | | | | | |
|---|---|---|---|---|---|---|
| | 1 | 2 | 3 | 4 | 5 | 6 |
| W (μm) | 20 | 20 | 20 | 20 | 20 | 20 |
| L (μm) | 20 | 20 | 20 | 20 | 20 | 20 |
| Overlapping of source/drain | <0.2 | <0.2 | <0.2 | <0.2 | <0.2 | <0.2 |
| parts and gate electrode | | | | | | |
| (μm) | | | | | | |
| Mobility (cm²/Vs) | 12 | 14 | 12 | 12 | 12 | 12 |
| Variation of current | 1.6 | 1.4 | 1.6 | 1.6 | 1.6 | 1.6 |
| value (%) | | | | | | |
| Off current (pA) | 0.1 | 1 | 0.5 | 2 | 2 | 2 |
| Shift amount in | 0.8 | 0.1 | 0.8 | 0.8 | 0.8 | 0.8 |
| threshold voltage (V) | | | | | | |
| State of channel part | Non-degenerate | Non-degenerate | Non-degenerate | Non-degenerate | Non-degenerate | Non-degenerate |
| State of source/drain | Degenerate | Degenerate | Degenerate | Degenerate | Degenerate | Degenerate |
| parts | | | | | | |

| | Examples | | | Comparative Examples | |
|---|---|---|---|---|---|
| | 7 | 8 | 9 | 1 | 2 |
| W (μm) | 20 | 20 | 20 | 20 | 20 |
| L (μm) | 20 | 20 | 20 | 20 | 20 |
| Overlapping of source/drain | <0.2 | <0.2 | <0.2 | <0.2 | <0.2 |
| parts and gate electrode | | | | | |
| (μm) | | | | | |
| Mobility (cm²/Vs) | 10 | 8 | 12 | 8 | 2 |
| Variation of current | 1.8 | 1.9 | 1.8 | 2.7 | 7.3 |
| value (%) | | | | | |
| Off current (pA) | 0.3 | 1 | 2 | 10 | 10 |
| Shift amount in | 0.8 | 0.8 | 0.6 | 1.2 | 2.3 |
| threshold voltage (V) | | | | | |
| State of channel part | Non-degenerate | Non-degenerate | Non-degenerate | Non-degenerate | Non-degenerate |
| State of source/drain | Degenerate | Degenerate | Degenerate | Degenerate | Non-degenerate |
| parts | | | | | |

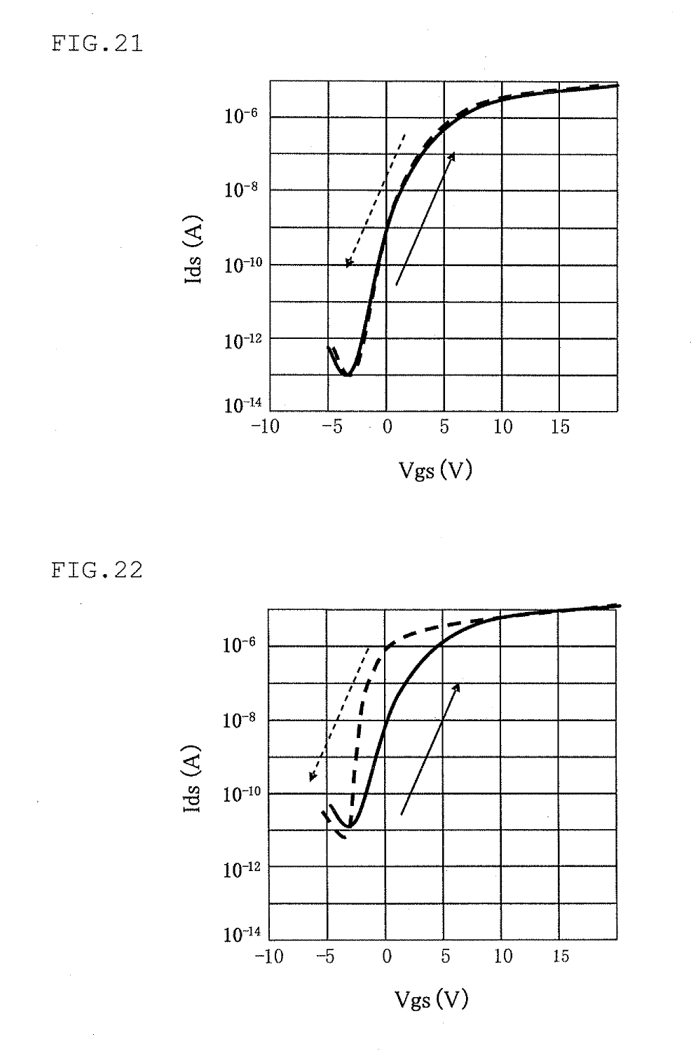

From Table 1, it is understood that the hysteresis of the transmission curve was slight the transistors in Examples 1 to 9, and that the hysteresis of the transmission curve was medium in transistors in Comparative Example 1 and Comparative Example 2. The hysteresis of the transmission curve of the transistor in Example 1 is shown in FIG. 21 and the hysteresis of the transmission curve of the transistor in Comparative Example 1 is shown in FIG. 22.

TABLE 2

| | | Exampels | | | | | | | | | Comparative Examples | |
|---|---|---|---|---|---|---|---|---|---|---|---|---|
| | | 1 | 2 | 3 | 4 | 5 | 6 | 7 | 8 | 9 | 1 | 2 |
| Hydrogen | Channel part | <10⁷ | <10⁷ | <10⁷ | <10⁷ | <10⁷ | <10⁷ | <10⁷ | <10⁷ | <10⁷ | <10⁷ | <10⁷ |
| concentration | Source/drain | <10⁷ | <10⁷ | <10⁷ | <10⁷ | <10⁷ | <10⁷ | <10⁷ | <10⁷ | <10⁷ | 10¹⁴ | <10⁷ |
| [/m³] | parts | | | | | | | | | | | |
| | Evaluation | Uni- | Uni- | Uni- | Uni- | Uni- | Uni- | Uni- | Uni- | Uni- | Non- | Uni- |
| | | form | form | form | form | form | form | form | form | form | uniform | form |

In Comparative Example 1, it was assumed that, since the hydrogen concentration was non-uniform due to ion injection, the mobility was low, the variation in current value was large and the off current was increased. In Comparative Example 2, since no low-resistant treatment was conducted, the source/drain parts became a non-degenerate semiconductor and had a low mobility, suffered a large variation in current value and had a high off current.

### Example 10

### (1) Production of Sputtering Target A for the Channel Part

As the raw material, powder of indium oxide, zinc oxide and gallium oxide were mixed such that the atomic ratio [In/(In+Zn+Ga)] became 0.32, the atomic ratio [Zn/(In+Zn+Ga)] became 0.36 and the atomic ratio [Ga/(In+Zn+Ga)] became 0.32. The mixture was supplied to a wet type ball mill and pulverized and mixed for 72 hours to obtain raw material fine powder.

The resulting raw material fine powder was granulated, and press-molded into a size of 10 cm in diameter and 5 mm in thickness. The molded product was put in a firing furnace, and fired at 1500° C. for 12 hours, whereby a sintered body (target) was obtained.

The bulk resistance of the target was 3 mΩ and the theoretical relative density was 0.99. Here, the theoretical relative density of the target was measured by calculating the ratio of the density calculated from the specific gravity of each oxide and the amount ratio of oxides to the density obtained by the Archimedian method.

### (2) Production of Sputtering Target B for the Source/Drain Parts

As the raw material, powder of indium oxide, zinc oxide and gallium oxide were mixed such that the atomic ratio [in/(In+Zn+Ga)] became 0.75, the atomic ratio [Zn/(In+Zn+Ga)] became 0.23 and the atomic ratio [Ga/(In+Zn+Ga)] became 0.02. The mixture was supplied to a wet type ball mill and pulverized and mixed for 72 hours to obtain raw material fine powder.

The resulting raw material fine powder was granulated, and press-molded into a size of 10 cm in diameter and 5 mm in thickness. The molded product was put in a firing furnace, and fired at 1500° C. for 12 hours, whereby a sintered body (target) was obtained.

The bulk resistance of the target was 4 mΩ and the theoretical relative density was 0.99. Here, the theoretical relative density of the target was measured by calculating the ratio of the density calculated from the specific gravity of each oxide and the amount ratio of oxides to the density obtained by the Archimedian method.

### (3) Preparation of a Field Effect Transistor

A field effect transistor with a structure shown in FIG. 13 was prepared.

On a glass substrate, metal molybdenum was formed in a thickness of 200 nm by RF sputtering at room temperature, followed by patterning by wet etching to prepare a gate electrode.

Subsequently, on the substrate on which the gate electrode was prepared, SiNx was formed into a film (thickness: 200 nm) at 300° C. by a plasma-enhanced chemical vapor deposition (PECVD) apparatus to form a gate insulating film.

Next, the target A for the channel part produced in (1) was installed in a film forming equipment of the DC magnetron sputtering method which is one of the DC sputtering methods. A film was formed on the gate insulating film, followed by patterning to form the channel part (film thickness: 100 nm).

The sputtering conditions were as follows. Substrate temperature; 25° C., Ultimate pressure; 1×10⁻⁶ Pa, Atmospheric gas; Ar 99.5% and oxygen 0.5%, Sputtering pressure (total pressure); 2×10⁻¹ Pa, Input power; 100 W, Film forming time; 6 minutes, and S-T distance; 110 mm.

After the film formation, the channel part was patterned by a photolithographic process.

Next, as an etching stopper (protective film) layer, an SiO₂ layer was formed and patterned.

Subsequently, using the target B for the source/drain parts produced in (2), the source/drain parts (film thickness: 30 nm) were formed by the DC magnetron sputtering method under the same sputtering conditions as those for the channel part. Further, the source/drain electrodes formed of metal molybdenum were formed. After the film formation, patterning was conducted by a photolithographic process.

Thereafter, under a nitrogen environment, a heat treatment was conducted at 300° C. for 1 hour, whereby an etching stopper, bottom-gate type field effect transistor of W=20 μm and L=4 μm was produced.

### (4) Evaluation of the Thin Film

On the glass substrate (Corning 1737), by using the targets A and B produced in (1) and (2) above, a film corresponding to the channel part and the source part and the drain part was formed and evaluated.

The resulting film corresponding to the channel part and the source part and the drain part was analyzed by the emission spectral analysis method (ICP).

As a result, it was found that the film corresponding to the channel part had an atomic ratio [In/(In+Zn+Ga)] of 0.34, an atomic ratio [Zn/(In+Zn+Ga)] of 0.33 and an atomic ratio [Ga/(In+Zn+Ga)] of 0.33.

Further, the film corresponding to the source part and the drain parts had an atomic ratio [In/(In+Zn+Ga)] of 0.78, an atomic ratio [Zn/(In+Zn+Ga)] of 0.2 and an atomic ratio [Ga/(In+Zn+Ga)] of 0.02.

In this way, it could be confirmed that the composition of the target and the composition of the film coincided.

In a nitrogen environment, the above-mentioned oxide semiconductor films were subjected to a heat treatment at 300° C. for 1 hour. By the X-ray crystalline structure analysis, a hallow pattern was observed in both films, and these films were confirmed to be amorphous.

The carrier concentration and the hall mobility of the semiconductor film which was heat-treated were measured by a hall measurement apparatus. As a result, the film corresponding to the channel part had a carrier concentration of 5×10¹⁵ cm⁻³ and a specific resistance of 5×10³ Ωcm and the film corresponding to the source part and the drain part had a carrier concentration of 9×10¹⁹ cm⁻³ and a specific resistance of 1.5×10⁻³ Ωcm.

The hall measurement apparatus and the measurement conditions thereof were as follows.

Hall Measurement Apparatus

Resi Test 8310, manufactured by Toyo Technica Co., Ltd.

Measurement Conditions

Measurement temperature: Room temperature (25° C.)

Magnetic field for measurement: 0.5 T

Current for measurement: 10⁻¹² to 10⁻⁴ A

Measurement mode: AC magnetic field hall measurement

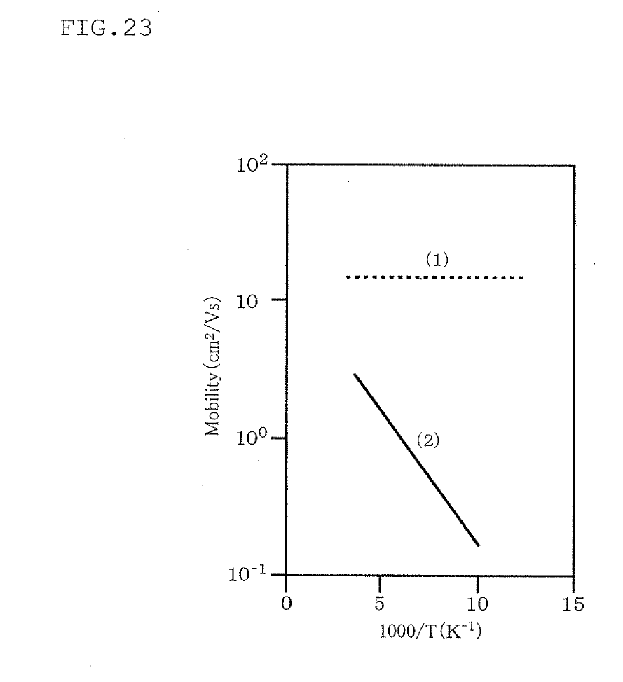

Further, similarly, the temperature dependency of the mobility was evaluated. FIG. 23 shows the relationship between the temperature and the mobility of the oxide semiconductor. From the slope of the straight line, an activation energy can be calculated. In the figure, (1) corresponds to the source part and the drain part, and (2) corresponds to the channel part. It could be confirmed that the film corresponding to the channel part was a non-degenerate semiconductor which had an activation energy of about 35 meV and showed a thermal activation type behavior, and that the film corresponding to the source part and the drain part was a degenerate semiconductor with an activation energy of less than 3 meV.

### (5) Evaluation of a Transistor

For the field effect transistor, the following evaluation was conducted.

(a) Field effect mobility (μ), on-off ratio, off current, gate leakage current, S value, and threshold voltage (Vth)

Using a semiconductor parameter analyzer (Keithley 4200), measurement was conducted at room temperature, in air (10⁻³ Pa) and in the light-shielded environment.

### (b) Hysteresis

Using a semiconductor parameter analyzer, a transmission curve at the time of increasing the voltage (I-V characteristics) and a transmission curve at the time of decreasing the voltage (I-V characteristics) were obtained, and a difference in voltage between when the voltage was increased and when the voltage was decreased was taken as ΔVg. A transistor having a maximum ΔVg value of 0.5 V or less was evaluated as “slight”, a transistor having a maximum ΔVg value of 0.5 to 3 V was evaluated as “medium” and a transistor having a maximum ΔVg value of 3 V or more was evaluated as “significant”.

(c) Stress test

As the stress conditions, a 10 μA-DC voltage was applied at a gate voltage of 15 Vat 50° C. for 100 hours. The Vth values before and after the application of a stress were compared to measure an amount of shift in threshold voltage (ΔVth).

### Example 11

A field effect transistor having a structure shown in FIG. 12 was prepared.

A field effect transistor was prepared in the same manner as in Example 10, except that no etching stopper (protective film) was provided, and the source electrode and the drain electrode and the source part and the drain part were etched simultaneously.

The etching selection ratio of the source/drain parts to the channel part was 5 or more.

The etching selection ratio was obtained from the ratio of the etching speed measured by using a PAN etching solution of 30° C.

### Example 12

A field effect transistor having a structure shown in FIG. 14 was prepared.

On a glass substrate provided with an SiOx protective film, source/drain electrodes (200 nm) and source/drain parts each composed of molybdenum were formed and patterned. After forming and patterning a channel part (30 nm) and a gate insulating film (200 nm) composed of SiOx, a gate electrode (300 nm) composed of molybdenum was formed.

### Example 13

A field effect transistor having a structure shown in FIG. 15 was prepared.

On a glass substrate provided with an SiOx protective film, an oxide semiconductor film (30 nm) was formed, and by conducting a post treatment, part thereof was allowed to be a channel part and part thereof was allowed to be source/drain parts. After forming a gate insulating film (200 nm) composed of SiOx and a gate electrode (100 nm), a protective film (300 nm) composed of SiNx was formed. After forming contact holes by dry etching, source/drain electrodes were formed.

### Examples 14 to 20 and Comparative Examples 3 to 7

Field effect transistors were prepared in the same manner as in Example 10, except that the composition of the target for the channel part and the composition of the target for the source part and the drain part were changed.

### Example 21

A field effect transistor was prepared in the same manner as in Example 10, except that the composition of the target of the channel part and the composition of the target of the source part and the drain part and the atmospheric gas were changed and RF magnetron sputtering was used as the sputtering method.

### Examples 22 to 28

Field effect transistors were prepared in the same manner as in Example 10, except that, as the gate insulating film, an SiOx film (thickness: 200 nm) obtained by using a plasma-enhanced chemical vapor deposition (PECVD) apparatus, and the composition of the target for the channel part and the composition of the target for the source part and the drain part were changed.

Tables 3 to 5 showed the evaluation results of the field effect transistors prepared in Examples and Comparative Examples, and the composition and properties of the channel part and the source/drain parts.

TABLE 3

| | | Examples | | | | | |
|---|---|---|---|---|---|---|---|
| | | 10 | 11 | 12 | 13 | 14 | 15 |
| Method and conditions for | Sputtering method | DC | DC | DC | DC | DC | DC |
| forming | Total pressure (Pa) | 0.2 | 0.2 | 0.2 | 0.2 | 0.2 | 0.2 |
| channel part | Atmospheric gas | Ar: 99.5% | Ar: 99.5% | Ar: 99.5% | Ar: 99.5% | Ar: 99.5% | Ar: 99.5% |
| | | O₂: 0.5% | O₂: 0.5% | O₂: 0.5% | O₂: 0.5% | O₂: 0.5% | O₂: 0.5% |
| Composition (atomic ratio) of | In/(In + Zn + X) | 0.34 | 0.34 | 0.34 | 0.34 | 0.34 | 0.34 |
| channel part | Zn/(In + Zn + X) | 0.33 | 0.33 | 0.33 | 0.33 | 0.33 | 0.33 |
| | X/(In + Zn + X) | 0.33 | 0.33 | 0.33 | 0.33 | 0.33 | 0.33 |
| | Element X | Ga | Ga | Ga | Ga | Ga | Ga |
| State of channel part | Temperature | Non- | Non- | Non- | Non- | Non- | Non- |
| | characteristics of | degenerate | degenerate | degenerate | degenerate | degenerate | degenerate |
| | conductivity | | | | | | |
| | Carrier density (cm⁻³) | 5 × 10¹⁵ | 5 × 10¹⁵ | 5 × 10¹⁵ | 5 × 10¹⁵ | 5 × 10¹⁵ | 5 × 10¹⁵ |
| | Specific resistance (Ω cm) | 5 × 10³ | 5 × 10³ | 5 × 10³ | 5 × 10³ | 5 × 10³ | 5 × 10³ |
| | XRD | Amorphous | Amorphous | Amorphous | Amorphous | Amorphous | Amorphous |
| Method and conditions for | Sputtering method | DC | DC | DC | DC | DC | DC |
| forming source/drain parts | Total Pressure (Pa) | 0.2 | 0.2 | 0.2 | 0.2 | 0.2 | 0.2 |
| | Atmospheric gas | Ar: 99.5% | Ar: 99.5% | Ar: 99.5% | Ar: 99.5% | Ar: 99.5% | Ar: 99.5% |
| | | O₂: 0.5% | O₂: 0.5% | O₂: 0.5% | O₂: 0.5% | O₂: 0.5% | O₂: 0.5% |
| Composition (atomic ratio) of | In/(In + Zn + X) | 0.78 | 0.78 | 0.78 | 0.78 | 0.80 | 0.60 |
| source/drain parts | Zn/(In + Zn + X) | 0.20 | 0.20 | 0.20 | 0.20 | 0.20 | 0.40 |
| | X/(In + Zn + X) | 0.02 | 0.02 | 0.02 | 0.02 | 0.00 | 0.00 |
| | Element X | Ga | Ga | Ga | Ga | — | — |
| State of source/drain parts | Temperature | Degenerate | Degenerate | Degenerate | Degenerate | Degenerate | Degenerate |
| | characteristics of | | | | | | |
| | conductivity | | | | | | |
| | Carrier density (cm⁻³) | 9 × 10¹⁹ | 9 × 10¹⁹ | 9 × 10¹⁹ | 9 × 10¹⁹ | 3 × 10²⁰ | 5 × 10¹⁸ |
| | Specific resistance (Ω cm) | 1.5 × 10⁻³ | 1.5 × 10⁻³ | 1.5 × 10⁻³ | 1.5 × 10⁻³ | 6 × 10⁻⁴ | 5 × 10⁻² |
| | XRD | Amorphous | Amorphous | Amorphous | Amorphous | Amorphous | Amorphous |
| Heat treatment | | Under N₂ | Under N₂ | Under N₂ | Under N₂ | Under N₂ | Under N₂ |
| | | 300° C. 1 Hr | 300° C. 1 Hr | 300° C. 1 Hr | 300° C. 1 Hr | 300° C. 1 Hr | 300° C. 1 Hr |
| Transistor properties | Mobility (cm²/Vs) | 22 | 20 | 20 | 22 | 22 | 22 |
| | On off ratio | 10¹⁰ | 10⁹ | 10⁹ | 10¹⁰ | 10¹⁰ | 10¹⁰ |
| | Off current (pA) | 0.05 | 0.1 | 0.1 | 0.05 | 0.05 | 0.05 |
| | Gate leakage current (pA) | 0.05 | 0.1 | 0.1 | 0.05 | 0.05 | 0.05 |
| | S value | 0.3 | 0.4 | 0.3 | 0.3 | 0.3 | 0.3 |
| | Vth(V) | 0.5 | 0.5 | 0.5 | 0.5 | 0.5 | 0.5 |
| | Hysteresis | Slight | Slight | Slight | Slight | Slight | Slight |
| Stress test | Shift in threshold voltage | 0.4 | 0.4 | 0.4 | 0.4 | 0.4 | 0.4 |
| | ΔVth(V) | | | | | | |

| | | Examples | | | |
|---|---|---|---|---|---|
| | | 16 | 17 | 18 | 19 |
| Method and conditions for | Sputtering method | DC | DC | DC | DC |
| forming channel part | Total pressure (Pa) | 0.2 | 0.2 | 0.2 | 0.2 |
| | Atmospheric gas | Ar: 99.5% | Ar: 99.5% | Ar: 95% | Ar: 99.5% |
| | | O₂: 0.5% | O₂: 0.5% | O₂: 5% | O₂: 0.5% |
| Composition (atomic ratio) of | In/(In + Zn + X) | 0.40 | 0.37 | 0.34 | 0.94 |
| channel part | Zn/(In + Zn + X) | 0.20 | 0.50 | 0.33 | 0.06 |
| | X/(In + Zn + X) | 0.40 | 0.13 | 0.33 | 0.00 |
| | Element X | Ga | Ga | Ga | — |
| State of channel part | Temperature | Non- | Non- | Non- | Non- |
| | characteristics of | degenerate | degenerate | degenerate | degenerate |
| | conductivity | | | | |
| | Carrier density (cm⁻³) | 9 × 10¹⁴ | 2 × 10¹⁶ | 6 × 10¹⁵ | 3 × 10¹⁵ |
| | Specific resistance (Ω cm) | 4 × 10⁴ | 1 × 10² | 4 × 10³ | 8 × 10³ |
| | XRD | Amorphous | Amorphous | Amorphous | Crystalline |
| Method and conditions for | Sputtering method | DC | DC | DC | DC |
| forming source/drain parts | Total Pressure (Pa) | 0.2 | 0.2 | 0.2 | 0.2 |
| | Atmospheric gas | Ar: 99.5% | Ar: 99.5% | Ar: 99.5% | Ar: 99.5% |
| | | O₂: 0.5% | O₂: 0.5% | O₂: 0.5% | O₂: 0.5% |
| Composition (atomic ratio) of | In/(In + Zn + X) | 0.78 | 0.78 | 0.78 | 0.80 |
| source/drain parts | Zn/(In + Zn + X) | 0.20 | 0.20 | 0.20 | 0.20 |
| | X/(In + Zn + X) | 0.02 | 0.02 | 0.02 | 0.00 |
| | Element X | Ga | Ga | Ga | — |
| State of source/drain parts | Temperature | Degenerate | Degenerate | Degenerate | Degenerate |
| | characteristics of | | | | |
| | conductivity | | | | |
| | Carrier density (cm⁻³) | 9 × 10¹⁹ | 9 × 10¹⁹ | 9 × 10¹⁹ | 3 × 10²⁰ |
| | Specific resistance (Ω cm) | 1.5 × 10⁻³ | 1.5 × 10⁻³ | 1.5 × 10⁻³ | 6 × 10⁻⁴ |
| | XRD | Amorphous | Amorphous | Amorphous | Amorphous |
| Heat treatment | | Under N₂ | Under N₂ | None | In atmosphere |
| | | 300° C. 1 Hr | 300° C. 1 Hr | | 300° C. 2 Hr |
| Transistor properties | Mobility (cm²/Vs) | 19 | 25 | 18 | 22 |
| | On off ratio | 10¹⁰ | 10¹⁰ | 10¹⁰ | 10¹⁰ |
| | Off current (pA) | 0.05 | 0.05 | 0.1 | 0.05 |
| | Gate leakage current (pA) | 0.05 | 0.05 | 0.1 | 0.05 |
| | S value | 0.3 | 0.3 | 0.5 | 0.3 |
| | Vth(V) | 0.5 | 0.5 | 0.8 | 0.5 |
| | Hysteresis | Slight | Slight | Slight | Slight |
| Stress test | Shift in threshold voltage | 0.4 | 0.4 | 3.1 | 0.3 |
| | ΔVth(V) | | | | |

TABLE 4

| | | Examples | | | | |
|---|---|---|---|---|---|---|
| | | 20 | 21 | 22 | 23 | 24 |
| Method and conditions for | Sputtering method | DC | RF | DC | DC | DC |
| forming channel part | Total pressure (Pa) | 0.2 | 0.2 | 0.2 | 0.2 | 0.2 |
| | Atmospheric gas | Ar: 99.5% | Ar: 100% | Ar: 99.5% | Ar: 95% | Ar: 99.5% |
| | | O₂: 0.5% | | O₂: 0.5% | O₂: 5% | O₂: 0.5% |
| Composition (atomic ratio) of | In/(In + Zn + X) | 0.65 | 0.34 | 0.34 | 0.34 | 0.43 |
| channel part | Zn/(In + Zn + X) | 0.13 | 0.33 | 0.33 | 0.33 | 0.43 |
| | X/(In + Zn + X) | 0.22 | 0.33 | 0.33 | 0.33 | 0.14 |
| | Element X | Ga | Ga | Ga | Sn | Al |
| State of channel part | Temperature | Non- | Non- | Non- | Non- | Non- |
| | characteristics of | degenerate | degenerate | degenerate | degenerate | degenerate |
| | conductivity | | | | | |
| | Carruer density (cm⁻³) | 1 × 10¹⁷ | 3 × 10¹⁵ | 5 × 10¹⁵ | 5 × 10¹⁵ | 6 × 10¹⁵ |
| | Specific resistance (Ω cm) | 1 × 10² | 8 × 10³ | 5 × 10³ | 5 × 10³ | 6 × 10³ |
| | XRD | Amorphous | Amorphous | Amorphous | Amorphous | Amorphous |
| Method and conditions for | Sputtering method | DC | RF | DC | DC | DC |
| forming source/drain parts | Total pressure (Pa) | 0.2 | 0.2 | 0.2 | 0.2 | 0.2 |
| | Atmospheric pressure | Ar: 99.5% | Ar: 100% | Ar: 99.5% | Ar: 99.5% | Ar: 99.5% |
| | | O₂: 0.5% | | O₂: 0.5% | O₂: 0.5% | O₂: 0.5% |
| Composition (atomic ratio) of | In/(In + Zn + X) | 0.78 | 0.78 | 0.78 | 0.78 | 0.78 |
| source/drain parts | Zn/(In + Zn + X) | 0.20 | 0.20 | 0.20 | 0.20 | 0.20 |
| | X/(In + Zn + X) | 0.02 | 0.02 | 0.02 | 0.02 | 0.02 |
| | Element X | Ga | Ga | Ga | Sn | Al |
| State of source/drain parts | Temperature | Degenerate | Degenerate | Degenerate | Degenerate | Degenerate |
| | characteristics of | | | | | |
| | conductivity | | | | | |
| | Carrier density (cm⁻³) | 9 × 10¹⁹ | 5 × 10¹⁹ | 9 × 10¹⁹ | 1.1 × 10²⁰ | 9 × 10¹⁹ |
| | Specific resistance (Ω cm) | 1.5 × 10⁻³ | 4 × 10⁻³ | 1.5 × 10⁻³ | 1.3 × 10⁻³ | 1.5 × 10⁻³ |
| | XRD | Amorphous | Amorphous | Amorphous | Amorphous | Amorphous |
| Heat treatment | | Under N₂ | Under N₂ | Under N₂ | Under N₂ | Under N₂ |
| | | 300° C. 1 Hr | 300° C. 1 Hr | 300° C. 1 Hr | 300° C. 1 Hr | 300° C. 1 Hr |
| Transistor properties | Mobility (cm²/Vs) | 21 | 23 | 21 | 17 | 19 |
| | On off ratio | 10⁹ | 10¹⁰ | 10¹⁰ | 10⁸ | 10¹⁰ |
| | Off current (pA) | 0.15 | 0.1 | 0.05 | 0.1 | 0.05 |
| | Gate leakage current (pA) | 0.1 | 0.1 | 0.05 | 0.1 | 0.05 |
| | S value | 0.4 | 0.4 | 0.2 | 0.5 | 0.1 |
| | Vth(V) | −0.2 | 0.2 | 0.1 | 0.5 | 0.4 |
| | Hysteresis | Slight | Slight | Slight | Slight | Slight |
| Stress test | Shift in threshold voltage | 0.3 | 0.4 | 0.2 | 0.4 | 0.1 |
| | ΔVth(V) | | | | | |

| | | Examples | | | |
|---|---|---|---|---|---|
| | | 25 | 26 | 27 | 28 |
| Method and conditions for | Sputtering method | DC | DC | DC | DC |
| forming channel part | Total pressure (Pa) | 0.2 | 0.2 | 0.2 | 0.2 |
| | | Ar: 99.5% | Ar: 99.5% | Ar: 99.5% | Ar: 99.5% |
| | Atmospheric gas | O₂: 0.5% | O₂: 0.5% | O₂: 0.5% | O₂: 0.5% |
| Composition (atomic ratio) of | In/(In + Zn + X) | 0.43 | 0.43 | 0.43 | 0.43 |
| channel part | Zn/(In + Zn + X) | 0.43 | 0.43 | 0.43 | 0.43 |
| | X/(In + Zn + X) | 0.14 | 0.14 | 0.14 | 0.14 |
| | Element X | Zr | Hf | Ti | Ce |
| State of channel part | Temperature | Non- | Non- | Non- | Non- |
| | characteristics of | degenerate | degenerate | degenerate | degenerate |
| | conductivity | | | | |
| | Carruer density (cm⁻³) | 5 × 10¹⁵ | 5 × 10¹⁵ | 6 × 10¹⁵ | 4 × 10¹⁵ |
| | Specific resistance (Ω cm) | 5 × 10³ | 5 × 10³ | 6 × 10³ | 6 × 10³ |
| | XRD | Amorphous | Amorphous | Amorphous | Amorphous |
| Method and conditions for | Sputtering method | DC | DC | DC | DC |
| forming source/drain parts | Total pressure (Pa) | 0.2 | 0.2 | 0.2 | 0.2 |
| | | Ar: 99.5% | Ar: 99.5% | Ar: 99.5% | Ar: 99.5% |
| | Atmospheric pressure | O₂: 0.5% | O₂: 0.5% | O₂: 0.5% | O₂: 0.5% |
| Composition (atomic ratio) of | In/(In + Zn + X) | 0.78 | 0.78 | 0.78 | 0.78 |
| source/drain parts | Zn/(In + Zn + X) | 0.20 | 0.20 | 0.20 | 0.20 |
| | X/(In + Zn + X) | 0.02 | 0.02 | 0.02 | 0.02 |
| | Element X | Zr | Hf | Ti | Ce |
| State of source/drain parts | Temperature | Degenerate | Degenerate | Degenerate | Degenerate |
| | characteristics of | | | | |
| | conductivity | | | | |
| | Carrier density (cm⁻³) | 9 × 10¹⁹ | 9 × 10¹⁹ | 9 × 10¹⁹ | 9 × 10¹⁹ |
| | Specific resistance (Ω cm) | 1.5 × 10⁻³ | 1.5 × 10⁻³ | 1.5 × 10⁻³ | 1.5 × 10⁻³ |
| | XRD | Amorphous | Amorphous | Amorphous | Amorphous |
| Heat treatment | | Under N₂ | Under N₂ | Under N₂ | Under N₂ |
| | | 300° C. 1 Hr | 300° C. 1 Hr | 300° C. 1 Hr | 300° C. 1 Hr |
| Transistor properties | Mobility (cm²/Vs) | 23 | 21 | 22 | 22 |
| | On off ratio | 10¹⁰ | 10¹⁰ | 10¹⁰ | 10¹⁰ |
| | Off current (pA) | 0.05 | 0.05 | 0.05 | 0.05 |
| | Gate leakage current (pA) | 0.05 | 0.05 | 0.05 | 0.05 |
| | S value | 0.1 | 0.1 | 0.3 | 0.3 |
| | Vth(V) | 0.3 | 0.3 | 0.4 | 0.4 |
| | Hysteresis | Slight | Slight | Slight | Slight |
| Stress test | Shift in threshold voltage | 0.1 | 0.1 | 0.3 | 0.3 |
| | ΔVth(V) | | | | |

TABLE 5
Comparative Examples

| | | 3 | 4 | 5 | 6 | 7 |
|---|---|---|---|---|---|---|
| Method and conditions for | Sputtering method | DC | DC | DC | DC | DC |
| forming channel part | Total pressure (Pa) | 0.2 | 0.2 | 0.2 | 0.2 | 0.2 |
| | Atmospheric gas | Ar: 99.5% | Ar: 99.5% | Ar: 99.5% | Ar: 99.5% | Ar: 95% |
| Composition (atomic ratio) of | | O₂: 0.5% | O₂: 0.5% | O₂: 0.5% | O₂: 0.5% | O₂: 5% |
| channel part | In/(In + Zn + X) | 0.34 | 0.78 | 0.78 | 0.34 | 0.34 |
| | Zn/(In + Zn + X) | 0.33 | 0.20 | 0.20 | 0.33 | 0.33 |
| | X/(In + Zn + X) | 0.33 | 0.02 | 0.02 | 0.33 | 0.33 |
| | Element X | Ga | Ga | Ga | Ga | Ga |
| State of channel part | Temperature | Non- | Degenerate | Degenerate | Non- | Non- |
| | characteristics of | degenerate | | | degenerate | degenerate |
| | conductivity | | | | | |
| | Carrier density (cm⁻³) | 5 × 10¹⁵ | 9 × 10¹⁹ | 9 × 10¹⁹ | 5 × 10¹⁵ | 5 × 10¹⁵ |
| | Specific resistance (Ω cm) | 5 × 10³ | 1.5 × 10⁻³ | 1.5 × 10⁻³ | 5 × 10³ | 5 × 10³ |
| | XRD | Amorphous | Amorphous | Amorphous | Amorphous | Amorphous |
| Method and conditions for | Sputtering method | DC | DC | DC | DC | DC |
| forming source/drain parts | Total pressure (Pa) | 0.2 | 0.2 | 0.2 | 0.2 | 0.2 |
| | | Ar: 99.5% | Ar: 99.5% | Ar: 99.5% | Ar: 99.5% | Ar: 95% |
| | Atmospheric gas | O₂: 0.5% | O₂: 0.5% | O₂: 0.5% | O₂: 0.5% | O₂: 5% |
| Composition (atomic ratio) of | In/(In + Zn + X) | 0.34 | 0.78 | 0.34 | 0.16 | 0.34 |
| source/drain parts | Zn/(In + Zn + X) | 0.33 | 0.20 | 0.33 | 0.42 | 0.33 |
| | X/(In + Zn + X) | 0.33 | 0.02 | 0.33 | 0.42 | 0.33 |
| | Element X | Ga | Ga | Ga | Ga | Ga |
| State of source/drain parts | Temperature | Non- | Degenerate | Non- | Non- | Non- |
| | characteristics of | degenerate | | degenerate | degenerate | degenerate |
| | conductivity | | | | | |
| | Carrier density (cm⁻³) | 5 × 10¹⁵ | 9 × 10¹⁹ | 5 × 10¹⁵ | 7 × 10¹⁴ | 5 × 10¹⁵ |
| | Specific resistance (Ω cm) | 5 × 10³ | 1.5 × 10⁻³ | 5 × 10³ | 4 × 10⁷ | 5 × 10³ |
| | XRD | Amorphous | Amorphous | Amorphous | Amorphous | Amorphous |
| Heat treatment | | Under N₂ | Under N₂ | Under N₂ | Under N₂ | None |
| | | 300° C. 1 Hr | 300° C. 1 Hr | 300° C. 1 Hr | 300° C. 1 Hr | |
| Transistor properties | Mobility (cm²/Vs) | 16 | 19 | 17 | 3 | 2 |
| | On off ratio | 10⁸ | 10⁶ | 10⁶ | 10⁶ | 10⁶ |
| | Off current (pA) | 0.1 | 20 | 20 | 0.05 | 1.2 |
| | Gate leakage current (pA) | 0.1 | 0.2 | 0.2 | 0.05 | 1.3 |
| | S value | 0.3 | 1.2 | 1.8 | 3 | 2.1 |
| | Vth(V) | 1.2 | −5.5 | −6.8 | 5.5 | 2.7 |
| | Hysteresis | Slight | Slight | Slight | Slight | Slight |
| Stress test | Shift in threshold voltage | 0.7 | 0.7 | 0.7 | 0.7 | 4.2 |
| | ΔVth(V) | | | | | |

### [Evaluation of Dependency of Channel Length (Evaluation of Effective S/D Serial Resistance)]

In Example 10, field effect transistors were prepared by changing the channel length (L) to 10, 20, 30, 40 and 50 μm, and the mobility thereof was measured. As a result, almost no dependency of the mobility on the channel length was confirmed, and it was found that the effective S/D serial resistance (R_{SD}) was small. R_{SD} was 35 Ωcm. The effective S/D serial resistance (R_{SD}) similarly measured in Examples 11 to 28 and Examples 1 to 9 was 100 Ωcm or less.

On the other hand, in Comparative Example 3, field effect transistors were prepared by changing the channel length (L) in the same way as mentioned above, and the mobility thereof was measured. As a result, as compared with Example 10, a large dependency of mobility on the channel length (that is, the mobility lowers as the channel length decreases) was confirmed, and also it was confirmed that the effective S/D serial resistance was large. RSD was 230 Ωcm. The effective S/D serial resistance (R_{SD}) similarly measured in Comparative Examples 2, 5, 6 and 7 exceeded 100 Ωcm.

### INDUSTRIAL APPLICABILITY

The field effect transistor of the invention has transistor properties suitable for displays such as flat displays.

The semiconductor device of the invention can be applied to an integrated circuit such as a logical circuit, a memory circuit, a differential amplification circuit. In particular, the semiconductor device of the invention can be preferably used as a switching element for driving a liquid crystal display or an organic EL display.

The documents described in the specification are incorporated herein by reference in its entirety.

1. A field effect transistor which comprises an oxide film as a semiconductor layer,
the oxide film has a channel part, a source part and a drain part, and
the channel part, the source part and the drain part have substantially the same composition except oxygen and an inert gas.

2. The field effect transistor according to claim 1, wherein the oxygen concentration of each of the source part and the drain part is lower than the oxygen concentration of the channel part.

3. The field effect transistor according to claim 1, wherein the source part and the drain part are self-aligned with the gate electrode.

4. The field effect transistor according to claim 1, wherein the oxide film comprises an oxide which comprises one or more elements selected from the group consisting of In, Zn, Ga and Sn.

5. The field effect transistor according to claim 1, wherein the oxide film is an amorphous film of a composite oxide which comprises In and Zn.

6. The field effect transistor according to claim 1, wherein the oxide film is an amorphous film of a composite oxide which comprises In, Zn and Ga or an amorphous film of a composite oxide which comprises In, Zn and Al.

7. The field effect transistor according to claim 1, wherein the oxide film is an amorphous film of a composite oxide which comprises one or more elements selected from the group consisting of Zr, Hf, Ge, Si, Ti, Mn, W, Mo, V, Nb, B, Sc, Y and lanthanoid elements, In and Zn.

8. A display using the field effect transistor according to claim 1.

9. A method for producing a field effect transistor comprising the steps of:
forming an oxide film and
lowering the resistance of part of the oxide film to form a source part and a drain part, wherein
the oxide film has a channel part and the source part and the drain part.

10. The method for producing a field effect transistor according to claim 9, wherein the resistance of part of the oxide film is lowered by irradiating light with a short wavelength in a low oxygen partial pressure environment.

11. The method for producing a field effect transistor according to claims 9, wherein the resistance of part of the oxide film is lowered by an inert gas plasma treatment.

12. A method for producing a field effect transistor comprising the steps of:
forming an oxide film and
increasing the resistance of part of the oxide film to form a channel part, wherein
the oxide film has the channel part and a source part and a drain part.

13. The method for producing a field effect transistor according to claim 12, wherein the resistance of part of the oxide film is increased by an oxygen plasma treatment or an ozone treatment.

14. A method for producing a field effect transistor comprising the steps of:
forming an oxide film,
coating the oxide film by an insulating film, and
forming a gate electrode on the insulating film and heating the gate electrode to increase the resistance of part of the oxide film, thereby to form a channel part, wherein
the oxide film has the channel part and a source part and a drain part.

15. A semiconductor device wherein an oxide semiconductor, which is a non-degenerate semiconductor, is connected to a conductor with an oxide semiconductor, which is a degenerate semiconductor, therebetween.

16. A field effect transistor comprising a channel part which comprises an oxide semiconductor and a source part and a drain part which each comprises an oxide semiconductor,
the channel part being a non-degenerate semiconductor and at least one of the source part and the drain part being a degenerate semiconductor, and
the channel part being connected to a source electrode and a drain electrode with the source part and the drain part therebetween.

17. The field effect transistor according to claim 16, wherein at least one of the source part and the drain part has a composition different from the composition of the channel part.

18. The field effect transistor according to claim 16, wherein each of the channel part, the source part and the drain part is an oxide which comprises In.

19. The field effect transistor according to claim 16, wherein each of the channel part, the source part and the drain part is an oxide which comprises In, Zn and another element X, and
the amount ratio of the element X in all elements except oxygen is higher in the channel part than in the source part and the drain part.

20. The field effect transistor according to claim 16, wherein each of the channel part, the source part and the drain part is an oxide which comprises In, Zn and the element X, and the composition of the channel part satisfies the atomic ratio in the following region 1, 2 or 3, and the composition of each of the source part and the drain part satisfies the atomic ratio in the following region 4:
In/(In+Zn+X)=0.20 to 0.55
Zn/(In+Zn+X)=0.00 to 0.80
X/(In+Zn+X)=0.00 to 0.80 Region 1
In/(In+Zn+X)=0.55 to 0.90
Zn/(In+Zn+X)=0.00 to 0.35
X/(In+Zn+X)=0.10 to 0.45 Region 2
In/(In+Zn+X)=0.90 to 1.00
Zn/(In+Zn+X)=0.00 to 0.10
X/(In+Zn+X)=0.00 to 0.10 Region 3
In/(In+Zn+X)=0.55 to 0.90
Zn/(In+Zn+X)=0.00 to 0.45
X/(In+Zn+X)=0.00 to 0.10 Region 4

21. The field effect transistor according to claim 19, wherein the element X is an element selected from the group consisting of Ga, Al, B, Sc, Y and lanthanoids (La, Ce, Pr, Nd, Sm, Eu, Gd, Tb, Dy, Ho, Er, Tm, Yb, Lu), Zr, Hf, Ge, Si, Ti, Mn, W, Mo, V, Cu, Ni, Co, Fe, Cr and Nb.

22. The field effect transistor according to claim 16, wherein the channel part is an oxide which comprises In, Zn and the element X,
each of the source part and the drain part is an oxide which comprises In, Zn and an element Y, each of the element X and the element Y being an element selected from the group consisting of Ga, Al, B, Sc, Y, lanthanoids (La, Ce, Pr, Nd, Sm, Eu, Gd, Tb, Dy, Ho, Er, Tm, Yb, Lu), Zr, Hf, Ge, Si, Ti, Mn, W, Mo, V, Cu, Ni, Co, Fe, Cr, Nb and Sn, and
the element X and the element Y are different from each other.

23. The field effect transistor according to claim 16, wherein the channel part comprises a crystalline oxide which comprises In and one or more positive divalent elements.

24. The field effect transistor according to claim 16, wherein an etching selection ratio of the source part and the drain part to the channel part is 5 or more.

25. A field effect transistor according to claim 16, wherein at least one of the source electrode, the drain electrode and the gate electrode comprises a metal selected from the group consisting of Ti, Pt, Cr, W, Al, Ni, Cu, Mo, Ta, Au and Nb or an alloy which comprises one or more of these metals.

26. A method for producing a field effect transistor according to claim 16, which comprises the steps of:
forming a film as a channel part,
forming a film as a source part and a drain part, and
after the above-mentioned two film-forming steps, conducting a heat treatment at a temperature higher than the film-forming temperature.

27. The method for producing a field effect transistor according to claim 26, wherein, between the step of forming a channel part and the step of forming a source part and a drain part, an object to be treated is not exposed to air.

28. The method for producing a field effect transistor according to claim 26, wherein the channel part, and the source part and drain part are formed by sputtering targets which differ in composition or composition ratio.
